(19) United States
(12) Patent Application Publication
(10) Pub. No.: US 2022/0368149 A1
(43) Pub. Date: Nov. 17, 2022

(54) POWER STORAGE DEVICE AND OPERATION METHOD OF POWER STORAGE DEVICE

(71) Applicant: SEMICONDUCTOR ENERGY LABORATORY CO., LTD., ATSUGI-SHI, KANAGAWA-KEN (JP)

(72) Inventors: Haruki KATAGIRI, Atsugi, Kanagawa (JP); Kyoichi MUKAO, Odawara, Kanagawa (JP); Motohiro ENDO, Meguro, Tokyo (JP)

(21) Appl. No.: 17/771,970

(22) PCT Filed: Oct. 19, 2020
(86) PCT No.: PCT/IB2020/059795

§ 371 Date: Apr. 26, 2022

(30) Foreign Application Priority Data
Nov. 1, 2019 (JP) 2019-200251

(51) Int. Cl. H02J 7/00; H02J 7/34; H02M 1/10

(52) U.S. Cl. CPC H02J 7/007182; H02J 7/00714; H02J 7/34; H02M 1/10

(57) ABSTRACT

Power consumption of a power storage device is reduced. A highly safe power storage device is provided. Safety of a battery monitored by a semiconductor device is improved. Power consumption is reduced; for example, power in a resting state is reduced. Time needed to perform processing for transition from a resting state to a normal state is shortened or energy is reduced. A power storage device includes a battery, a control circuit, and a converter circuit. The converter circuit has a function of supplying a voltage to the battery; and the control circuit has a function of measuring data of a voltage of the battery and a function of retaining the data of the voltage of the battery.

### TECHNICAL FIELD

One embodiment of the present invention relates to a power storage device. Another embodiment of the present invention relates to a semiconductor device included in a power storage device.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter.

Note that in this specification and the like, a power storage device includes a battery, for example. In this specification and the like, a power storage device includes a device that stores power, for example. In this specification and the like, a semiconductor device generally means a device that can function by utilizing semiconductor characteristics. Thus, a semiconductor element such as a transistor or a diode and a circuit including a semiconductor element are semiconductor devices. A display device, a light-emitting device, a lighting device, an electro-optical device, a communication device, an electronic device, and the like may include a semiconductor element or a semiconductor circuit. Therefore, a display device, a light-emitting device, a lighting device, an electro-optical device, an imaging device, a communication device, an electronic device, and the like are referred to as a semiconductor device in some cases.

### BACKGROUND ART

With the widespread use of a variety of electronic devices, power consumption has been recently showing an increasing tendency. Patent Document 1 discloses a control mode of an uninterruptible power supply, in which the duration of a battery is predicted so that a system is stopped safely.

A CAAC (c-axis aligned crystalline) structure and an nc (nanocrystalline) structure, which are neither single crystal nor amorphous, have been found in an oxide semiconductor (see Non-Patent Document 1 and Non-Patent Document 2).

Non-Patent Document 1 and Non-Patent Document 2 each disclose a technique for forming a transistor with the use of an oxide semiconductor having a CAAC structure.

As techniques for reducing the power consumption of semiconductor devices, power gating (PG), clock gating (CG), and voltage scaling are known, for example. Patent Document 2 discloses a technique for effectively reducing power consumption among DVFS (Dynamic Voltage and Frequency Scaling) techniques and PG techniques, for example.

### REFERENCE

### Patent Document

[Patent Document 1] Japanese Published Patent Application No. H09-44274
[Patent Document 2] PCT International Publication No. 2009/078081

### Non-Patent Document

[Non-Patent Document 1] S. Yamazaki et al., “SID Symposium Digest of Technical Papers”, 2012, volume 43, issue 1, p. 183-186
[Non-Patent Document 2] S. Yamazaki et al., “Japanese Journal of Applied Physics”, 2014, volume 53, Number 4S, p. 04ED18-1-04ED18-10

### SUMMARY OF THE INVENTION

### Problems to be Solved by the Invention

An object of one embodiment of the present invention is to provide a novel semiconductor device or an operation method of a novel semiconductor device. Another object of one embodiment of the present invention is to reduce power consumption of a power storage device. Another object of one embodiment of the present invention is to provide a highly safe power storage device. Another object of one embodiment of the present invention is to improve safety of a battery monitored by a semiconductor device. Another object of one embodiment of the present invention is to reduce power consumption, for example, reduce power in a resting state. Another object of one embodiment of the present invention is to shorten time needed to perform processing for transition from a resting state to a normal state or reduce energy needed to perform the processing.

Note that the description of a plurality of objects does not preclude the existence of each object. One embodiment of the present invention does not necessarily achieve all of these objects. Objects other than those listed above will be apparent from the description of the specification, the drawings, the claims, and the like, and such objects could be objects of one embodiment of the present invention.

### Means for Solving the Problems

One embodiment of the present invention is a power storage device including a battery, a control circuit, and a converter circuit. The converter circuit has a function of supplying a voltage to the battery; and the control circuit has a function of measuring data of a voltage of the battery and a function of retaining the data of the voltage of the battery. Another embodiment of the present invention is a power storage device including a battery, a control circuit, and a converter circuit. The converter circuit has a function of selecting and converting a first voltage or a second voltage and supplying the converted voltage to the battery; the first voltage is an AC voltage; the second voltage is a DC voltage; the control circuit includes a transistor including an oxide semiconductor in a channel formation region; and the control circuit has a function of measuring data of a voltage of the battery and a function of retaining the data of the voltage of the battery.

In the above structure, it is preferable that the control circuit include a transistor including an oxide semiconductor in a channel formation region; the control circuit include a processor core; the processor core have a function of supplying a signal to a gate of the transistor; and power supply to the processor core be stopped in a period of retaining data of the first voltage.

In the above structure, it is preferable that the converter circuit have a function of converting one or more of a magnitude and a frequency of a voltage.

In the above structure, it is preferable that the second voltage be a voltage generated by a solar cell.

Another embodiment of the present invention is a power storage device including a battery, a control circuit, and a converter circuit. The converter circuit has a function of selecting and converting a first voltage or a second voltage and supplying the converted voltage to the battery; the first voltage is an AC voltage; the second voltage is a DC voltage; the control circuit includes a first sample-and-hold circuit and a second sample-and-hold circuit; the first sample-and-hold circuit has a function of measuring and retaining data of a voltage of the battery; the second sample-and-hold circuit has a function of converting data of a current of the battery into a voltage, and measuring and retaining the voltage; the first sample-and-hold circuit includes a first transistor; the second sample-and-hold circuit includes a second transistor; the first sample-and-hold circuit has a function of measuring the data of the voltage of the battery when the first transistor is in an on state, and a function of retaining the data of the voltage of the battery when the first transistor is in an off state; and the second sample-and-hold circuit has a function of measuring the data of the current of the battery when the second transistor is in an on state, and a function of retaining the data of the current of the battery when the second transistor is in an off state.

In the above structure, it is preferable that the first transistor and the second transistor each include an oxide semiconductor in a channel formation region.

In the above structure, it is preferable that the power storage device have a function of calculating a remaining capacity of the battery with use of the data of the voltage of the battery retained in the first sample-and-hold circuit and the data of the current of the battery retained in the second sample-and-hold circuit.

In the above structure, it is preferable that the converter circuit have a function of converting one or more of a magnitude and a frequency of a voltage.

In the above structure, it is preferable that the second voltage be a voltage generated by a solar cell.

Another embodiment of the present invention is an operation method of a power storage device including a battery, a control circuit, and a converter circuit. The control circuit includes a processing unit including a processor core, and a first sample-and-hold circuit and a second sample-and-hold circuit; the first sample-and-hold circuit includes a first transistor; the second sample-and-hold circuit includes a second transistor; the processing unit is electrically connected to a gate of the first transistor and a gate of the second transistor; the processing unit supplies signals to the gate of the first transistor and the gate of the second transistor to turn on the first transistor and the second transistor; the converter circuit supplies a voltage to the battery; data of a voltage of the battery is supplied to one of a source and a drain of the first transistor, and data of a current of the battery is converted into a voltage and the voltage is supplied to one of a source and a drain of the second transistor; and the processing unit supplies signals to the gate of the first transistor and the gate of the second transistor to turn off the first transistor and the second transistor.

In the above structure, it is preferable that a second processing unit be included; the data of the voltage of the battery and the data obtained by converting the data of the current of the battery into the voltage be converted from analog values into digital values and then supplied to the second processing unit; power supply to the processor core be stopped; and the second processing unit calculate a remaining capacity of the battery.

In the above structure, it is preferable that the converter circuit have a function of converting one or more of magnitudes and frequencies of a first voltage and a second voltage; the first voltage be an AC voltage; the second voltage be a DC voltage; and the converter circuit select and convert the first voltage or the second voltage and supply the converted voltage to the battery.

In the above structure, it is preferable that the second voltage be a voltage generated by a solar cell.

### Effect of the Invention

According to one embodiment of the present invention, a novel semiconductor device or an operation method of a novel semiconductor device can be provided. According to one embodiment of the present invention, power consumption of a power storage device can be reduced. According to one embodiment of the present invention, a highly safe power storage device can be provided. According to one embodiment of the present invention, safety of a battery monitored by a semiconductor device can be improved. According to one embodiment of the present invention, power consumption can be reduced; for example, power in a resting state can be reduced. According to one embodiment of the present invention, time needed to perform processing for transition from a resting state to a normal state can be shortened or energy needed to perform the processing can be reduced.

Note that the description of these effects does not preclude the existence of other effects. In addition, one embodiment of the present invention does not necessarily achieve all the effects described as examples. In one embodiment of the present invention, other objects, effects, and novel features are apparent from the description of this specification and the drawings.

### BRIEF DESCRIPTION OF THE DRAWINGS

FIG. 1 is a block diagram illustrating an example of a power storage device.

FIG. 2 is a circuit diagram illustrating part of a structure of a power storage device.

FIG. 3 is a circuit diagram illustrating an example of a control circuit.

FIG. 4A and FIG. 4B are diagrams illustrating an example of a secondary battery.

FIG. 5A and FIG. 5B are diagrams illustrating an example of a power storage device.

FIG. 6A and FIG. 6B are diagrams illustrating an example of a secondary battery.

FIG. 7A and FIG. 7B are block diagrams illustrating a structure example of a semiconductor device.

FIG. 8A to FIG. 8D are timing charts showing power management operation examples of a semiconductor device.

FIG. 9 is a flow chart showing a structure example of a semiconductor device.

FIG. 10A and FIG. 10B are block diagrams illustrating a structure example of a semiconductor device.

FIG. 11 is a block diagram showing a structure example of a processor core.

FIG. 12 is a circuit diagram showing a structure example of a memory circuit.

FIG. 13 is a timing chart illustrating an operation example of a memory circuit.

FIG. 14 is a circuit diagram showing a structure example of a cache memory cell.

FIG. 15 is a timing chart illustrating an operation example of a memory cell.

FIG. 16A is a functional block diagram showing a structure example of a NOSRAM. FIG. 16B is a circuit diagram showing a structure example of a memory cell.

FIG. 17A is a circuit diagram showing a structure example of a memory cell array. FIG. 17B and FIG. 17C are circuit diagrams showing structure examples of memory cells.

FIG. 18A is a circuit diagram showing a structure example of a memory cell of a DOSRAM. FIG. 18B is a diagram showing a stacked-layer structure example of the DOSRAM.

FIG. 19 is a diagram showing a structure example of a semiconductor device.

FIG. 20 is a diagram showing a structure example of a semiconductor device.

FIG. 21A to FIG. 21C are diagrams showing a structure example of a transistor.

FIG. 22A to FIG. 22C are diagrams showing a structure example of a transistor.

FIG. 23A to FIG. 23C are diagrams showing a structure example of a transistor.

FIG. 24A is a table showing classifications of crystal structures of IGZO. FIG. 24B is a diagram showing an XRD spectrum of a CAAC-IGZO film. FIG. 24C is a diagram showing a nanobeam electron diffraction pattern of the CAAC-IGZO film.

FIG. 25 is a diagram illustrating an example of an uninterruptible power supply.

FIG. 26 is a diagram illustrating examples of electronic devices.

FIG. 27A, FIG. 27B, and FIG. 27C are diagrams illustrating examples of vehicles.

FIG. 28A is a diagram illustrating an example of a vehicle. FIG. 28B is a diagram illustrating an example of a power storage device.

### MODE FOR CARRYING OUT THE INVENTION

Embodiments are described in detail with reference to the drawings. However, the present invention is not limited to the following description, and it is readily appreciated by those skilled in the art that modes and details can be modified in various ways without departing from the spirit and the scope of the present invention. Thus, the present invention should not be construed as being limited to the description in the following embodiments. Note that in the structures of the invention described below, the same portions or portions having similar functions are denoted by the same reference numerals in different drawings, and description thereof is not repeated.

In addition, the position, size, range, and the like of each component illustrated in the drawings and the like do not represent the actual position, size, range, and the like in some cases for easy understanding of the invention. Therefore, the disclosed invention is not necessarily limited to the position, size, range, or the like disclosed in drawings and the like. For example, in an actual manufacturing process, a resist mask or the like might be unintentionally reduced in size by treatment such as etching, which might not be reflected in the drawings for easy understanding.

Furthermore, in a top view (also referred to as a “plan view”), a perspective view, or the like, the description of some components might be omitted for easy understanding of the drawings.

In addition, in this specification and the like, the term “electrode” or “wiring” does not functionally limit a component. For example, an “electrode” is sometimes used as part of a “wiring”, and vice versa. Furthermore, the term “electrode” or “wiring” can also mean the case where a plurality of “electrodes” or “wirings” are formed in an integrated manner.

In this specification and the like, a “terminal” in an electric circuit refers to a portion that inputs or outputs a current or a voltage or receives or transmits a signal. Accordingly, part of a wiring or an electrode functions as a terminal in some cases.

Note that the term “over” or “under” in this specification and the like does not necessarily mean that a component is placed directly over and in contact with or directly under and in contact with another component. For example, the expression “an electrode B over an insulating layer A” does not necessarily mean that the electrode B is formed on and in direct contact with the insulating layer A and does not exclude the case where another component is provided between the insulating layer A and the electrode B.

In addition, functions of a source and a drain are interchanged with each other depending on operation conditions and the like, for example, when a transistor of different polarity is employed or when the current direction is changed in a circuit operation; therefore, it is difficult to define which is the source or the drain. Thus, the terms “source” and “drain” can be interchangeably used in this specification.

In this specification and the like, the expression “electrically connected” includes the case where components are directly connected to each other and the case where components are connected through an “object having any electric function”. Here, there is no particular limitation on the “object having any electric function” as long as electric signals can be transmitted and received between components that are connected through the object. Thus, even when the expression “electrically connected” is used, there is a case where no physical connection portion is made and a wiring is just extended in an actual circuit.

Furthermore, in this specification and the like, “parallel” indicates a state where two straight lines are placed at an angle of greater than or equal to −10° and less than or equal to 10°, for example. Accordingly, the case where the angle is greater than or equal to −5° and less than or equal to 5° is also included. Moreover, “perpendicular” and “orthogonal” indicate a state where two straight lines are placed at an angle of greater than or equal to 80° and less than or equal to 100°, for example. Accordingly, the case where the angle is greater than or equal to 85° and less than or equal to 95° is also included.

In this specification and the like, the terms “identical”, “same”, “equal”, “uniform”, and the like used in describing calculation values and measurement values allow for a margin of error of ±20% unless otherwise specified.

In addition, a voltage refers to a potential difference between a certain potential and a reference potential (e.g., a ground potential or a source potential) in many cases. Therefore, the terms “voltage” and “potential” can be replaced with each other in many cases. In this specification and the like, the terms “voltage” and “potential” can be replaced with each other unless otherwise specified.

Note that even a “semiconductor” has characteristics of an “insulator” when conductivity is sufficiently low, for example. Thus, a “semiconductor” can be replaced with an “insulator”. In that case, a “semiconductor” and an “insulator” cannot be strictly distinguished from each other because a border therebetween is not clear. Accordingly, a “semiconductor” and an “insulator” described in this specification can be replaced with each other in some cases.

Furthermore, a “semiconductor” has characteristics of a “conductor” when conductivity is sufficiently high, for example. Thus, a “semiconductor” can be replaced with a “conductor”. In that case, a “semiconductor” and a “conductor” cannot be strictly distinguished from each other because a border therebetween is not clear. Accordingly, a “semiconductor” and a “conductor” described in this specification can be replaced with each other in some cases.

Note that ordinal numbers such as “first” and “second” in this specification and the like are used in order to avoid confusion among components and do not denote the priority or the order such as the order of steps or the stacking order. A term without an ordinal number in this specification and the like might be provided with an ordinal number in the scope of claims in order to avoid confusion among components. Furthermore, a term with an ordinal number in this specification and the like might be provided with a different ordinal number in the scope of claims. Furthermore, even when a term is provided with an ordinal number in this specification and the like, the ordinal number might be omitted in the scope of claims and the like.

Note that in this specification and the like, an “on state” of a transistor refers to a state in which a source and a drain of the transistor are electrically short-circuited (also referred to as a “conduction state”). Furthermore, an “off state” of the transistor refers to a state in which the source and the drain of the transistor are electrically disconnected (also referred to as a “non-conduction state”).

In addition, in this specification and the like, an “on-state current” sometimes refers to a current that flows between a source and a drain when a transistor is in an on state. Furthermore, an “off-state current” sometimes refers to a current that flows between a source and a drain when a transistor is in an off state.

In this specification and the like, a high power supply potential VDD (hereinafter, also simply referred to as “VDD”, “H potential”, or “H”) is a power supply potential higher than a low power supply potential VSS (hereinafter, also simply referred to as “VSS,” “L potential,” or “L”). VSS refers to a power supply potential at a potential lower than VDD. A ground potential (hereinafter, also simply referred to as “GND” or “GND potential”) can be used as VDD or VSS. For example, in the case where VDD is a ground potential, VSS is a potential lower than the ground potential, and in the case where VSS is a ground potential, VDD is a potential higher than the ground potential.

In addition, in this specification and the like, a gate refers to part or the whole of a gate electrode and a gate wiring. A gate wiring refers to a wiring for electrically connecting at least one gate electrode of a transistor to another electrode or another wiring.

Furthermore, in this specification and the like, a source refers to part or all of a source region, a source electrode, or a source wiring. A source region refers to a region in a semiconductor layer, where the resistivity is lower than or equal to a given value. A source electrode refers to part of a conductive layer that is connected to a source region. A source wiring refers to a wiring for electrically connecting at least one source electrode of a transistor to another electrode or another wiring.

Moreover, in this specification and the like, a drain refers to part or all of a drain region, a drain electrode, or a drain wiring. A drain region refers to a region in a semiconductor layer, where the resistivity is lower than or equal to a given value. A drain electrode refers to part of a conductive layer that is connected to a drain region. A drain wiring refers to a wiring for electrically connecting at least one drain electrode of a transistor to another electrode or another wiring.

In the drawings and the like, for easy understanding of the potentials of a wiring, an electrode, and the like, “H” representing an H potential or “L” representing an L potential is sometimes written near the wiring, the electrode, and the like. In addition, enclosed “H” or “L” is sometimes written near a wiring, an electrode, and the like whose potential has changed. Moreover, a symbol “×” is sometimes written on a transistor in an off state.

Note that a terminal may refer to a group of a plurality of terminals. Each terminal included in a group of a plurality of terminals is supplied with an independent signal, for example, and each terminal is electrically connected to one or more wirings.

A transistor includes three terminals (nodes) called a gate, a source, and a drain. The gate is a terminal that functions as a control terminal for controlling the conduction state of the transistor. Depending on the type of the transistor and the levels of potentials supplied to each terminal (node), one of a pair of input/output terminals (nodes) functions as a source and the other functions as a drain. In general, in an n-channel transistor, a node to which a lower potential is supplied is called a source, and a node to which a higher potential is supplied is called a drain. In contrast, in a p-channel transistor, a node to which a lower potential is supplied is called a drain, and a node to which a higher potential is supplied is called a source. In this specification, two terminals (nodes) except a gate are referred to as a first terminal (node) and a second terminal (node) in some cases.

In this specification, for easy understanding of a circuit structure and its operation, description is sometimes made on the case where one of two input/output terminals (nodes) of a transistor is fixed as a source and the other is fixed as a drain. It is needless to say that, depending on a driving method, the magnitude relationship between potentials applied to three terminals of the transistor might be changed, and the source and the drain might be interchanged with each other. Thus, in one embodiment of the present invention, the distinction between the source and the drain of the transistor is not limited to that described in this specification and the drawings.

Note that in this specification and the like, it might be possible for those skilled in the art to constitute one embodiment of the invention even when portions to which all the terminals of an active element (e.g., a transistor or a diode), a passive element (e.g., a capacitor or a resistor), or the like are connected are not specified. In other words, one embodiment of the invention can be clear even when connection portions are not specified. Furthermore, in the case where a connection portion is disclosed in this specification and the like, it can be determined that one embodiment of the invention in which a connection portion is not specified is disclosed in this specification and the like, in some cases. In particular, in the case where the number of portions to which the terminal is connected is more than one, it is not necessary to specify the portions to which the terminal is connected. Therefore, it might be possible to constitute one embodiment of the invention by specifying only portions to which some of terminals of an active element (e.g., a transistor or a diode), a passive element (e.g., a capacitor or a resistor), or the like are connected.

In this specification and the like, it might be possible for those skilled in the art to specify the invention when at least the connection portion of a circuit is specified. Alternatively, it might be possible for those skilled in the art to specify the invention when at least a function of a circuit is specified. In other words, when a function is specified, an embodiment of the present invention can be clear. Furthermore, it can be determined that one embodiment of the present invention whose function is specified is disclosed in this specification and the like. Therefore, when a connection portion of a circuit is specified, the circuit is disclosed as one embodiment of the invention even when a function is not specified, and one embodiment of the invention can be constituted. Alternatively, when a function of a circuit is specified, the circuit is disclosed as one embodiment of the invention even when a connection portion is not specified, and one embodiment of the invention can be constituted.

### Embodiment 1

In this embodiment, a power storage device of one embodiment of the present invention will be described.

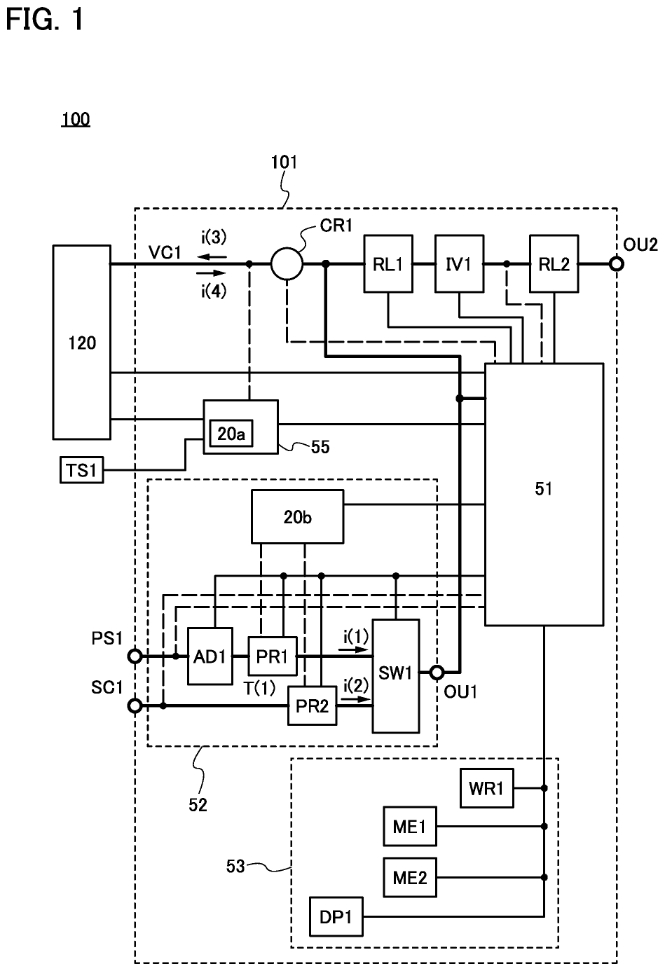

FIG. 1 illustrates a power storage device of one embodiment of the present invention.

A power storage device 100 illustrated in FIG. 1 includes a semiconductor device 101, an assembled battery 120, and a temperature sensor TS1. The assembled battery 120 includes one or a plurality of battery cells.

The semiconductor device 101 includes a processing unit 51, a converter circuit 52, a circuit 53, a control circuit 55, a relay circuit RL1, a relay circuit RL2, an inverter circuit IV1, an ammeter CR1, a terminal PS1, a terminal SC1, and a terminal OU2.

The terminal PS1 and the terminal SC1 are each supplied with a signal such as a voltage or a current. For example, the terminal PS1 and the terminal SC1 are supplied with an AC signal and a DC signal, respectively.

The AC signal supplied to the terminal PS1 is commercial AC power, for example.

The DC signal supplied to the terminal SC1 is DC power from a solar cell, for example.

The converter circuit 52 includes a converter circuit AD1, a protection circuit PR1, a control circuit PR2, a control circuit SW1, and a terminal OU1.

The signal from the terminal PS1 is supplied to the control circuit SW1 through the converter circuit AD1 and the protection circuit PR1. The signal from the terminal SC1 is supplied to the control circuit SW1 through the control circuit PR2. The control circuit SW1 has a function of selecting the signal from the protection circuit PR1 or the signal from the control circuit PR2 and outputting the selected signal to the terminal OU1. Alternatively, the control circuit SW1 may mix the two signals and output a signal obtained by the mixing. The signal output from the terminal OU1 is supplied to the assembled battery 120. The assembled battery 120 can be charged using the signal output from the terminal OU1.

The converter circuit AD1 has a function of converting an AC signal into a DC signal.

The protection circuit PR1 has a function of controlling a current flowing between the converter circuit AD1 and the control circuit SW1 (hereinafter, referred to as a current i(1)). The protection circuit PR1 may have a function of controlling a voltage supplied from the terminal PS1 to the control circuit SW1 through the converter circuit AD1.

The protection circuit PR1 has a function of inhibiting backflow of a current from the control circuit SW1 to the converter circuit AD1. For example, a diode is provided between the control circuit SW1 and the converter circuit AD1 in the protection circuit PR1, so that backflow of a current from the control circuit SW1 to the converter circuit AD1 is inhibited.

The control circuit PR2 has a function of controlling a current flowing between the terminal SC1 and the control circuit SW1 (hereinafter, referred to as a current i(2)). The control circuit PR2 may have a function of controlling a voltage supplied from the terminal SC1 to the control circuit SW1. The control circuit PR2 has a function of inhibiting backflow of a current from the control circuit SW1 to the terminal SC1. For example, a diode is provided between the control circuit SW1 and the terminal SC1 in the control circuit PR2, so that backflow of a current from the control circuit SW1 to the terminal SC1.

A processing unit 20b is electrically connected to the protection circuit PR1 and the control circuit PR2. The processing unit 20b has a function of, for example, monitoring and storing the current i(1) and the current i(2). The processing unit 20b may supply a signal for controlling the current i(1) and a signal for controlling the current i(2) to the protection circuit PR1 and the control circuit PR2, respectively.

In the case where the protection circuit PR1 includes the diode, the processing unit 20b preferably has a function of measuring a temperature T(1). The temperature T(1) is the temperature of the diode or the temperature around a region where the diode is placed. The processing unit 20b preferably has a function of making a determination on the basis of the temperature T(1), controlling the current i(1) on the basis of the determination result, and controlling the temperature T(1) to be lower than or equal to a predetermined temperature. By controlling the temperature T(1) to be lower than or equal to a predetermined temperature, a breakdown and a deterioration of the diode can be inhibited.

In a period during which signals are not input to the terminal PS1 and the terminal SC1, the processing unit 20b can be in a standby state. The processing unit 20b includes a transistor including an oxide semiconductor (OS), which is one kind of metal oxide, in a semiconductor layer where a channel is formed (such a transistor is also referred to as an “OS transistor” or “OS-FET”). The processing unit 20b including an OS transistor has a feature of extremely low power consumption in the standby state. In the processing unit 20b, the structure of a processing unit 20 or a processing unit 21 described later can be employed. When the processing unit 20b is in the standby state, a circuit block included in the processing unit 20b, e.g., a processor core is brought into a resting state, so that power consumption can be reduced.

The control circuit 55 is electrically connected to the assembled battery 120 and the temperature sensor TS1.

The ammeter CR1 has a function of measuring a charging current supplied to the assembled battery 120 (hereinafter, a current i(3)) and a current supplied from the assembled battery 120 to the terminal OU2 through the relay circuit RL1, the inverter circuit IV1, and the relay circuit RL2 (hereinafter, a current i(4)). Data measured by the ammeter CR1 is supplied to the processing unit 51. Alternatively, data measured by the ammeter CR1 may be supplied to the control circuit 55.

The relay circuit RL1 has a function of supplying a signal from the assembled battery 120 to the inverter circuit IV1 when supplied with a desired signal from the processing unit 51. The relay circuit RL2 has a function of supplying a signal from the inverter circuit IV1 to the terminal OU2 when supplied with a desired signal from the processing unit 51. The inverter circuit IV1 has a function of converting a DC signal supplied from the assembled battery 120 into an AC signal.

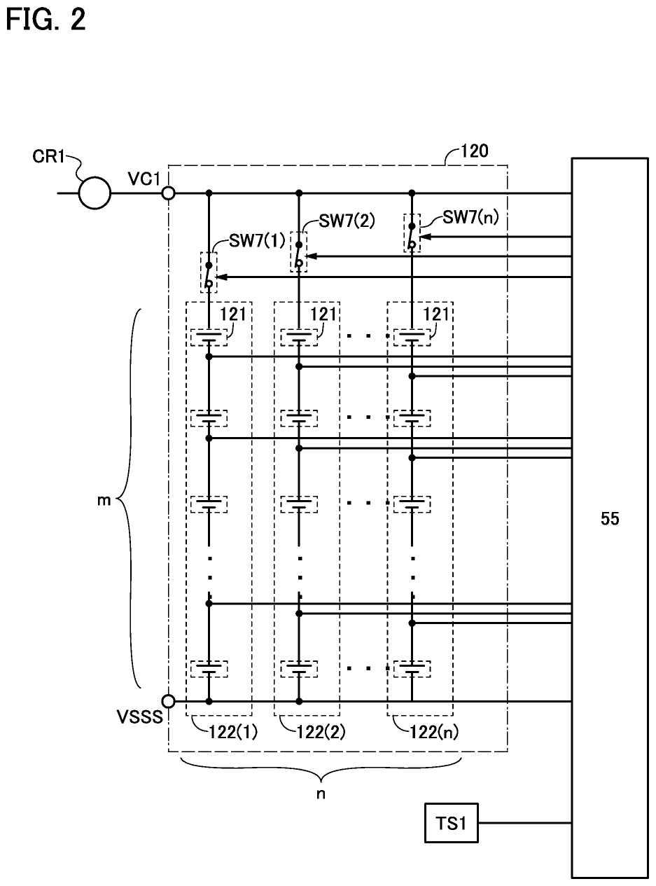

FIG. 2 shows an example of electrical connection between the control circuit 55, the assembled battery 120, the ammeter CR1, and the temperature sensor TS1. The assembled battery 120 includes a terminal VC1 and a terminal VSSS.

The temperature sensor TS1 includes a sensor element, and the sensor element has a function of measuring temperature. The sensor element is placed near the assembled battery 120. The temperature sensor TS1 has a function of supplying temperature data measured by the sensor element to the control circuit 55.

The control circuit 55 includes a processing unit 20a.

The ammeter CR1 is electrically connected to the terminal VC1 of the assembled battery 120. Alternatively, the ammeter CR1 may be connected to the terminal VSSS side of the assembled battery 120.

FIG. 2 shows an example in which n assembled batteries 122(k) (k is an integer greater than or equal to 1 and less than or equal to n), in each of which m battery cells 121 are connected in series, are connected in parallel. The assembled batteries 122(k) are arranged between the terminal VC1 and the terminal VSSS. In the assembled battery 122(k), the first battery cell to the m-th battery cell are connected in series in order.

The terminal VC1 has a function of being electrically connected to a positive electrode of the battery cell 121 through a switch SE7(k), and electrical connection between the positive electrode of the battery cell 121 and the terminal VC1 is controlled by opening and closing the switch SW7(k). The switch SW7(k) is controlled to open and close by the control circuit 55, specifically, the processing unit 20a included in the control circuit 55, for example.

A negative electrode of the m-th battery cell of the assembled battery 122(k) is electrically connected to the terminal VSSS.

The control circuit 55 has a function of measuring the voltages of both ends of the assembled battery 120.

The control circuit 55 preferably has a function of measuring the voltages of both ends (the voltage between the positive electrode and the negative electrode) of each of the battery cells 121 included in the assembled battery 120. The control circuit 55 can determine the charging condition of the assembled battery 120 with use of the measured voltage. The control circuit 55 controls charging of the assembled battery 122(k) by opening and closing the switch SW7(k) on the basis of the determined charging condition, for example.

When the control circuit 55 determines the charging condition, the charging condition of the assembled battery 120 may be controlled using temperature data supplied from the temperature sensor TS1, in addition to the voltages of the both ends of the assembled battery 120, the voltages of the both ends of each of the battery cells 121 included in the assembled battery 120, and the like.

The voltages of the both ends of the assembled battery 120 and the voltages of the both ends of each of the battery cells 121 included in the assembled battery 120, which are measured by the control circuit 55, the temperature data measured in the temperature sensor TS1, and the like may be supplied to the processing unit 51 and the charging condition of the assembled battery 120 may be determined in the processing unit 51.

In addition to the values of the voltages such as the voltage of the assembled battery 120, the voltages of the both ends of each of the battery cells 121 included in the assembled battery 120, and the like, the remaining capacity of the assembled battery 120 is preferably measured. The measurement of the remaining capacity of the assembled battery 120 will be described later.

The processing unit 51 has a function of controlling the charging condition of the assembled battery 120.

To the processing unit 51, a current measured by the ammeter CR1, a current between the inverter circuit IV1 and the relay circuit RL2, a current between the terminal PS1 and the converter circuit AD1, and a current between the terminal SC1 and the control circuit PR2 are preferably supplied.

The processing unit 51 has a function of controlling a signal such as the current i(3) or a voltage supplied to the assembled battery 120 by controlling the protection circuit PR1, the control circuit PR2, the control circuit SW1, or the like by supply of a signal.

The protection circuit PR1 may be controlled by supplying a signal from the processing unit 51 to the processing unit 20b and supplying the signal from the processing unit 20b to the protection circuit PR1. Data such as a current stored in the protection circuit PR1 is preferably supplied to the processing unit 51. In the processing unit 51, the data can be used for, for example, determination of the charging condition of the assembled battery 120 and control of the charging condition.

The processing unit 51 has a function of supplying signals to the relay circuit RL1, the inverter circuit IV1, and the relay circuit RL2 to control the current i(4), a voltage supplied to the terminal OU2, or the like.

Data measured by the processing unit 20b, for example, data such as the current i(1), the current i(2), and the temperature T(1) may be supplied to the processing unit 51. The processing unit 51 can supply a determination result based on the measured temperature T(1) to the processing unit 20b.

The processing unit 51 performs determination by comparing data of a voltage value or a current value stored in a memory ME1, a memory ME2, or the like described later and a voltage and a current related to the assembled battery 120, for example. For example, in the case where the voltage related to the assembled battery 120 exceeds a predetermined value, the assembled battery 120 is determined to be overcharged. For example, in the case where the voltage related to the assembled battery 120 falls below a predetermined value, the assembled battery 120 is determined to be overdischarged. For example, in the case where the current related to the assembled battery 120 exceeds a predetermined value, the assembled battery 120 is determined to be overcharged. The processing unit 51 has a function of protecting the assembled battery 120 by controlling the charging condition, stopping charging, controlling the discharging condition, or stopping discharging on the basis of the determination result.

To the processing unit 51, power from the assembled battery 120 or power from the terminal OU1 of the converter circuit 52 can be supplied. The processing unit 51 can distribute the supplied power to another circuit such as the converter circuit 52, the circuit 53, the control circuit 55, the relay circuit RL1, the inverter circuit IV1, or the relay circuit RL2.

The power storage device 100 has a function of measuring the remaining capacity of the assembled battery 120 with use of the current i(3) and the current i(4). By also measuring the voltage of the assembled battery 120 at the time of measuring the remaining capacity, the measurement accuracy can be increased. In the measurement of the remaining capacity of the assembled battery 120, the amount of charge supplied to the assembled battery 120 and the amount of charge released from the assembled battery 120 are calculated with use of the current and the voltage.

A change in the capacity of the assembled battery 120 can be obtained by calculating the amount of charge consumed in charging or discharging with use of the charging current or the discharging current of the assembled battery 120 and the time during which the current flows. However, an error might be accumulated along with repetitive measurements.

By evaluating the relation between the voltage and the capacity of the assembled battery 120 beforehand and storing it in the memory ME1, the memory ME2, or the like described later, the remaining capacity of the assembled battery 120 can be measured with use of the voltage of the assembled battery 120. Note that in a region where a change in the voltage is small in a capacity-voltage curve of the assembled battery 120, a measurement error might occur.

When the remaining capacity of the assembled battery 120 is measured by calculation of the amount of charge with use of the current and calculation of the capacity with use of the voltage, the accuracy of measuring the remaining capacity can be increased. For example, in a region where the change in the voltage is large in the capacity-voltage curve, the remaining capacity may be measured with use of the voltage, and in the region where the change is small, the remaining capacity may be measured with use of the current value and the time during which the current flows.

In the power storage device 100, arithmetic operation for measuring the remaining capacity of the assembled battery 120 can be performed in the processing unit 51. For example, the processing unit 51 can perform the arithmetic operation for measuring the remaining capacity of the assembled battery 120 with use of the current i(3) and the current i(4) measured by the ammeter CR1 and the voltage value measured by the control circuit 55.

Alternatively, the provision of a sample-and-hold circuit using an OS transistor in the control circuit 55 can increase the accuracy of measuring the remaining capacity.

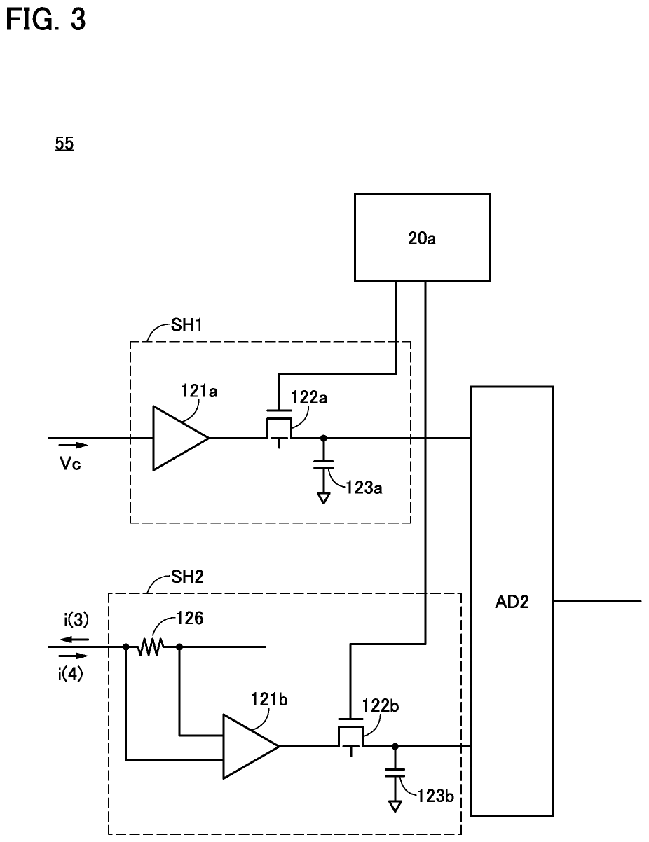

The control circuit 55 illustrated in FIG. 3 includes the processing unit 20a, a sample-and-hold circuit SH1, a sample-and-hold circuit SH2, and an analog-digital converter circuit AD2.

The sample-and-hold circuit SH1 includes an amplifier circuit 121a, a transistor 122a, and a capacitor 123a. The sample-and-hold circuit SH1 is supplied with a voltage Vc. The voltage Vc is the voltage of the assembled battery 120, for example. Alternatively, the voltage Vc is the voltage of each of the battery cells 121 included in the assembled battery 120, for example. The voltage Vc is supplied to the amplifier circuit 121a of the sample-and-hold circuit SH1. The amplifier circuit 121a has a function of amplifying analog data such as the voltage Vc input to the sample-and-hold circuit SH1 and outputting the amplified analog data. Note that the amplifier circuit 121a may be provided on the gate side of the transistor 122a.

An OS transistor is preferably used as the transistor 122a. The OS transistor has an extremely low off-state current, and the capacitor 123a has a function of retaining charge corresponding to the voltage Vc when the transistor 122a is turned off.

The sample-and-hold circuit SH2 includes a resistor 126, an amplifier circuit 121b, a transistor 122b, and a capacitor 123b. The sample-and-hold circuit SH2 is supplied with the current i(3) or the current i(4). The current i(3) or the current i(4) flows through the resistor 126. The voltages of both ends of the resistor 126 are supplied to the amplifier circuit 121b of the sample-and-hold circuit SH2. The amplifier circuit 121b has a function of amplifying a difference between the voltages of the both ends of the resistor 126 and outputting the amplified difference.

An OS transistor is preferably used as the transistor 122b. The OS transistor has an extremely low off-state current, and the capacitor 123b has a function of retaining charge corresponding to the difference between the voltages of the both ends of the resistor 126 when the transistor 122b is turned off.

The values retained in the sample-and-hold circuit SH1 and the sample-and-hold circuit SH2 are converted by the analog-digital converter circuit AD2 and then supplied to the processing unit 51. Alternatively, a memory may be provided in the control circuit 55 and the retained values may be stored in the memory.

Timing of turning on or off the transistor 122a and the transistor 122b is controlled by potentials supplied to terminals electrically connected to gates of the transistors. The gates of the transistors are supplied with signals from the processing unit 20a. By synchronizing the times when the transistor 122a and the transistor 122b are turned on or off, values of the voltage and the current related to the assembled battery 120 at substantially the same time can be obtained.

Due to the impedance characteristics of the assembled battery 120, the voltage changes depending on the amount of current flowing through the assembled battery 120. Thus, in the case where the remaining capacity is measured with use of the voltage of the assembled battery 120, it is preferable that the amount of current flowing through the assembled battery 120 be also measured and the influence of the change in the voltage due to the impedance be corrected. By obtaining the voltage and the current at substantially the same time, the influence of the change in the voltage due to the impedance can be corrected more accurately and the remaining capacity can be calculated more accurately.

Measurement of the voltage and the current for calculating the remaining capacity is not always necessary and may be performed at certain intervals. In the case where the change rate of the voltage or the current is high, the interval may be shortened, and in the case where the change rate is low, the interval may be lengthened.

In the control circuit 55, the processing unit 20a included in the control circuit 55 can be in a standby state in a period during which the voltage, the current, and the temperature are not measured, for example, whereby power consumption can be reduced.

When data for calculating the remaining capacity of the assembled battery 120 is measured and retained in the control circuit 55, the number of tasks of the processing unit 51 can be reduced compared to that of the case where the data for calculating the remaining capacity of the assembled battery 120 is directly supplied to the processing unit 51 and arithmetic operation is performed. In addition, since the control circuit 55 can retain the data, the data can be transmitted at desired timing. Thus, the arithmetic operation in the processing unit 51 can be performed efficiently.

The power storage device 100 illustrated in FIG. 1 includes the circuit 53. The circuit 53 includes a circuit WR1, the memory ME1, the memory ME2, and a display device DP1.

The circuit WR1 includes a circuit group for wireless communication and for example includes a modulation circuit, a demodulation circuit, a rectifier circuit, and an antenna. The power storage device 100 can transmit and receive data by wireless communication.

The memory ME1 and the memory ME2 are memories for storing data. As the memory ME1, for example, a volatile memory such as a DRAM (dynamic random access memory) or an SRAM (static random access memory) can be used. Alternatively, a DOSRAM, a NOSRAM, or the like described later can be used as the memory ME1. In the memory ME1, for example, data used for arithmetic operation in the processing unit 51 is stored. As the memory ME2, for example, a nonvolatile memory such as a flash memory can be used. Alternatively, the DOSRAM, the NOSRAM, or the like described later can be used as the memory ME2. The memory ME2 stores, for example, data of voltage-capacitance characteristics and data such as the upper limit and the lower limit of the voltage and the current of the assembled battery 120 that are used for measuring the remaining capacity of the assembled battery 120, and time-series data of the voltage and the current as the record of the usage history of the assembled battery 120. In the case where the data stored in the memory ME2 is used for arithmetic operation, for example, the data is read out to the memory ME1 and then the arithmetic operation is performed.

Alternatively, the memory ME1 and the memory ME2 may store data received by the circuit WR1 by wireless communication.

The memory ME1 and the memory ME2 store, for example, data used for determination of the charging condition by the power storage device 100. The data can be rewritten to data received by wireless communication at any time.

The display device DP1 includes a display portion and a driver circuit. The display portion can display, for example, the remaining capacity of the assembled battery 120 or the status of the power storage device 100 (in charging, in discharging, in standby, a charging mode, or the like). In charging, the terminal (either the terminal PS1 or the terminal SC1 or both of them) through which charging is performed is preferably indicated as a status.

This embodiment can be implemented in appropriate combination with the other embodiments.

### Embodiment 2

In this embodiment, an example of a battery cell included in a power storage device of one embodiment of the present invention is described.

As the battery cell, a secondary battery is preferably used, for example. Examples of the secondary battery include a secondary battery that utilizes an electrochemical reaction, such as a lithium ion battery, an electrochemical capacitor such as an electric double-layer capacitor or a redox capacitor, an air battery, a fuel battery, and the like.

### [Positive Electrode Active Material]

As a positive electrode material of the secondary battery, a material including an element A, an element X, and oxygen can be used, for example. The element A is preferably one or more selected from the Group 1 elements and the Group 2 elements. As the Group 1 element, for example, an alkali metal such as lithium, sodium, or potassium can be used. As the Group 2 element, for example, calcium, beryllium, magnesium, or the like can be used. As the element X, for example, one or more selected from metal elements, silicon, and phosphorus can be used. The element X is preferably one or more selected from cobalt, nickel, manganese, iron, and vanadium.

Examples of a positive electrode active material include a lithium-containing composite oxide with an olivine crystal structure, a lithium-containing composite oxide with a layered rock-salt crystal structure, and a lithium-containing composite oxide with a spinel crystal structure.

As the lithium-containing composite oxide with an olivine crystal structure, for example, a composite oxide represented by a general formula LiMPO₄ (M is one or more of Fe(II), Mn(II), Co(II), and Ni(II))) can be given. Typical examples of the general formula LiMPO₄ include LiFePO₄, LiNiPO₄, LiCoPO₄, LiMnPO₄, LiFeₐNi_{b}PO₄, LiFeₐCo_{b}PO₄, LiFeₐMn_{b}PO₄, LiNiₐCo_{b}PO₄, LiNiₐMn_{b}PO₄ (a+b≤1, 0<a<1, and 0<b<1), LiFe_{c}Ni_{d}CoₑPO₄, LiFe_{c}Ni_{d}MnₑPO₄, LiNi_{c}Co_{d}MnₑPO₄ (c+d+e≤1, 0<c<1, 0<d<1, and 0<e<1), and LiFe_{f}Ni_{g}CoₕMnᵢPO₄ (f+g+h+i≤1, 0<f<1, 0<g<1, 0<h<1, and 0<i<1).

Examples of the lithium-containing composite oxide with a layered rock-salt crystal structure include lithium cobalt oxide (LiCoO₂), LiNiO₂, LiMnO₂, Li₂MnO₃, a NiCo-containing material (general formula: LiNiₓCo₁₋ₓO₂ (0<x<1)) such as LiNi_{0.8}Co_{0.2}O₂, a NiMn-containing material (general formula: LiNiₓMn₁₋ₓO₂ (0<x<1)) such as LiNi_{0.5}Mn_{0.5}O₂, a NiMnCo-containing material (also referred to as NMC; general formula: LiNiₓMn_{y}Co_{1-x-y}O₂ (x>0, y>0, x+y<1)) such as LiNi_{1/3}Mn_{1/3}Co_{1/3}O₂. Moreover, Li(Ni_{0.8}Co_{0.15}Al_{0.05})O₂, Li₂MnO₃—LiMO₂ (M=Co, Ni, or Mn), and the like can be given.

Examples of the lithium-containing composite oxide with a spinel crystal structure include LiMn₂O₄, Li₁₊ₓMn₂₋ₓO₄, LiMn₂₋ₓAlₓO₄, and LiMn_{1.5}Ni_{0.5}O₄.

### [Electrolyte Solution]

The electrolyte solution contains a solvent and an electrolyte. As the solvent of the electrolyte solution, an aprotic organic solvent is preferably used. For example, one of ethylene carbonate (EC), propylene carbonate (PC), butylene carbonate, chloroethylene carbonate, vinylene carbonate, γ-butyrolactone, γ-valerolactone, dimethyl carbonate (DMC), diethyl carbonate (DEC), ethyl methyl carbonate (EMC), methyl formate, methyl acetate, ethyl acetate, methyl propionate, ethyl propionate, propyl propionate, methyl butyrate, 1,3-dioxane, 1,4-dioxane, dimethoxyethane (DME), dimethyl sulfoxide, diethyl ether, methyl diglyme, acetonitrile, benzonitrile, tetrahydrofuran, sulfolane, and sultone can be used, or two or more of these solvents can be used in an appropriate combination in an appropriate ratio.

Alternatively, the use of one or more ionic liquids (room temperature molten salts) that are less likely to burn and volatize as the solvent of the electrolyte solution can prevent a secondary battery from exploding or catching fire even when the secondary battery internally shorts out or the internal temperature increases owing to overcharge or the like. An ionic liquid contains a cation and an anion, specifically, an organic cation and an anion. Examples of the organic cation used for the electrolyte solution include aliphatic onium cations such as a quaternary ammonium cation, a tertiary sulfonium cation, and a quaternary phosphonium cation, and aromatic cations such as an imidazolium cation and a pyridinium cation. Examples of the anion used for the electrolyte solution include a monovalent amide-based anion, a monovalent methide-based anion, a fluorosulfonate anion, a perfluoroalkylsulfonate anion, a tetrafluoroborate anion, a perfluoroalkylborate anion, a hexafluorophosphate anion, and a perfluoroalkylphosphate anion.

As an electrolyte dissolved in the above-described solvent, a salt containing the element A can be used, for example.

Alternatively, a polymer gelled electrolyte obtained in such a manner that a polymer is swelled with an electrolyte solution may be used. When a polymer gel electrolyte is used, safety against liquid leakage and the like is improved. Furthermore, a secondary battery can be thinner and more lightweight.

Instead of the electrolyte solution, a solid electrolyte including an inorganic material such as a sulfide-based inorganic material or an oxide-based inorganic material, or a solid electrolyte including a high-molecular material such as a PEO (polyethylene oxide)-based high-molecular material may alternatively be used. When the solid electrolyte is used, a separator and a spacer are not necessary. Furthermore, the battery can be entirely solidified; therefore, there is no possibility of liquid leakage and thus the safety is dramatically increased.

Examples of the sulfide-based solid electrolyte include a thio-silicon-based material (e.g., Li₁₀GeP₂S₁₂ and Li_{3.25}Ge_{0.25}P_{0.75}S₄), sulfide glass (e.g., 70Li₂S.30P₂S₅, 30Li₂S.26B₂S₃.44LiI, 63Li₂S.38SiS₂.1Li₃PO₄, 57Li₂S.38SiS₂.5Li₄SiO₄, and 50Li₂S.50GeS₂), and sulfide-based crystallized glass (e.g., Li₇P₃S₁₁ and Li_{3.25}P_{0.95}S₄). Examples of the oxide-based solid electrolyte include a material with a perovskite crystal structure (e.g., La_{2/3-x}Li₃ₓTiO₃), a material with a NASICON crystal structure (e.g., Li_{1-X}Al_{X}Ti_{2-X}(PO₄)₃), a material with a garnet crystal structure (e.g., Li₇La₃Zr₂O₁₂), a material with a LISICON crystal structure (e.g., Li₁₄ZnGe₄O₁₆), LLZO (Li₇La₃Zr₂O₁₂), oxide glass (e.g., Li₃PO₄—Li₄SiO₄ and 50Li₄SiO₄.50Li₃BO₃), and oxide-based crystallized glass (e.g., Li_{1.07}Al_{0.69}Ti_{1.46}(PO₄)₃ and Li_{1.5}Al_{0.5}Ge_{1.5}(PO₄)₃). Examples of the halide-based solid electrolyte include LiAlCl₄, Li₃InBr₆, LiF, LiCl, LiBr, and LiI. In addition, Li₁₊ₓAlₓTi₂₋ₓ(PO₄)₃ (0<x<1) with a NASICON crystal structure (hereinafter, LATP) is preferable because LATP contains aluminum and titanium, each of which is the element the positive electrode active material used for the secondary battery of one embodiment of the present invention is allowed to contain, and thus a synergistic effect of improving the cycle performance is expected. Moreover, higher productivity due to the reduction in the number of steps is expected. Note that in this specification and the like, a material with a NASICON crystal structure refers to a compound that is represented by M₂(XO₄)₃ (M: transition metal; X: S, P, As, Mo, W, or the like) and has a structure in which MO₆ octahedra and XO₄ tetrahedra that share common corners are arranged three-dimensionally.

### [Separator]

The secondary battery preferably includes a separator. As the separator, for example, paper; nonwoven fabric; glass fiber; ceramics; or synthetic fiber containing nylon (polyamide), vinylon (polyvinyl alcohol-based fiber), polyester, acrylic, polyolefin, or polyurethane can be used.

### [Negative Electrode Active Material]

In the case where a material containing the element A, the element X, and oxygen is used as a positive electrode active material, a material that enables charge and discharge reactions by insertion and extraction of ions of the element A, a material that enables charge and discharge reactions by alloying and dealloying reactions with the element A, or the like can be used as a negative electrode active material of the secondary battery.

As the negative electrode active material, a carbon-based material such as graphite, graphitizing carbon (soft carbon), non-graphitizing carbon (hard carbon), a carbon nanotube, graphene, or carbon black can be used.

Examples of the negative electrode active material include a material containing at least one of Al, Si, Ge, Sn, Pb, Sb, Bi, Ag, Zn, Cd, In, Ga, and the like. Such elements have higher capacity than carbon, and in particular, silicon has a significantly high theoretical capacity of 4200 mAh/g. For this reason, silicon is preferably used as the negative electrode active material. As an alloy-based material using such elements, for example, an alloy-based material such as Mg₂Si, Mg₂Ge, Mg₂Sn, SnS₂, V₂Sn₃, FeSn₂, CoSn₂, Ni₃Sn₂, Cu₆Sn₅, Ag₃Sn, Ag₃Sb, Ni₂MnSb, CeSb₃, LaSn₃, La₃Co₂Sn₇, CoSb₃, InSb, or SbSn can be used.

This embodiment can be implemented in appropriate combination with the other embodiments.

### Embodiment 3

In this embodiment, examples of a power storage device of one embodiment of the present invention and a battery cell and an assembled battery that are included in the power storage device are described.

As a battery cell of one embodiment of the present invention, a battery cell with any of a variety of shapes such as a rectangular shape, a cylindrical shape, a coin-type shape, and a flexible laminated shape can be used.

### [Cylindrical Secondary Battery]

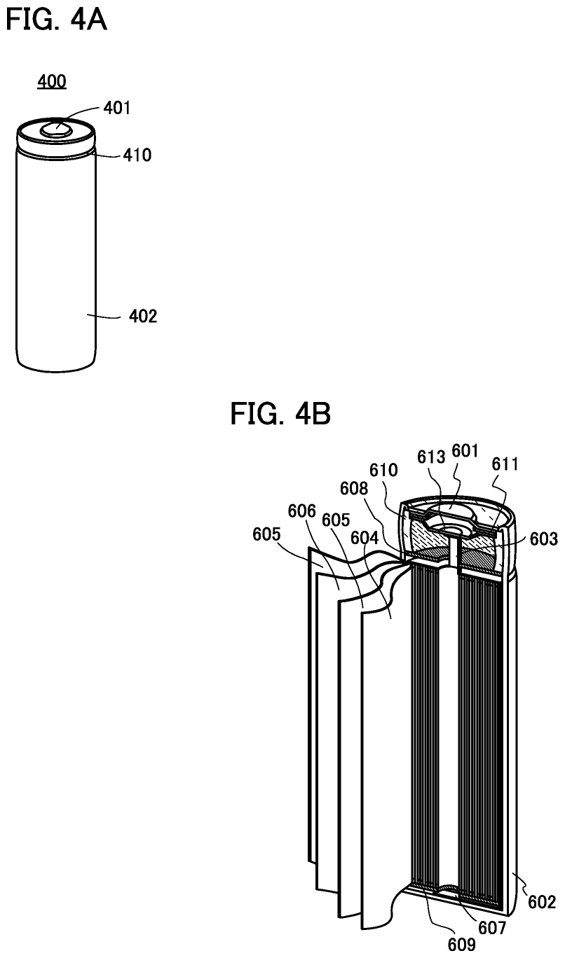

An example in which a cylindrical secondary battery is used as the battery cell of one embodiment of the present invention is described below with reference to FIG. 4A. A cylindrical secondary battery 400 includes, as illustrated in FIG. 4A, a positive electrode cap (battery lid) 401 on a top surface and a battery can (outer can) 402 on a side surface and a bottom surface. The positive electrode cap 401 and the battery can (outer can) 402 are insulated from each other by a gasket (insulating packing) 410.

FIG. 4B is a diagram schematically showing a cross-section of the cylindrical secondary battery. The cylindrical secondary battery illustrated in FIG. 4B includes a positive electrode cap (battery lid) 601 on a top surface and a battery can (outer can) 602 on a side surface and a bottom surface. The positive electrode cap and the battery can (outer can) 602 are insulated from each other by a gasket (insulating gasket) 610.

Inside the battery can 602 having a hollow cylindrical shape, a battery element in which a strip-like positive electrode 604 and a strip-like negative electrode 606 are wound with a separator 605 located therebetween is provided. In the positive electrode 604, for example, a layer containing a positive electrode active material (hereinafter, referred to as a positive electrode active material layer) is formed on both surfaces or one surface of a current collector. In the negative electrode 606, for example, a layer containing a negative electrode active material (hereinafter, referred to as a negative electrode active material layer) is formed on both surfaces or one surface of a current collector.

The active material layer preferably includes a conductor in addition to the active material. As the conductor, a sheet-like compound, a fibrous compound, or the like may be used. The sheet-like compound and the fibrous compound can form a three-dimensional conduction path, for example. When the sheet-like compound is placed to be in contact with a plurality of active materials, conductivity can be imparted to the plurality of active materials. Moreover, when the sheet-like compound is placed to wrap the surfaces of the active materials, the compound can make surface contact with the active materials, whereby the conductivity of the active material layer can be increased. A plurality of fibrous compounds can be in contact with each other in the thickness direction of the active material layer, for example, whereby a conduction path can be formed. Thus, the conductivity of the active material layer can be increased. As the sheet-like conductor, graphene can be used, for example. Graphene may be rounded like a carbon nanofiber. The conductors may form an aggregation. Formation of the aggregation by the conductors may increase the conductivity of the active material layer.

When a sheet-like carbon-containing compound or a fibrous carbon-containing compound is used as the conductor, the conductivity of the active material layer can be increased, so that a secondary battery suitable for rapid charging, rapid discharging, and the like can be provided.

Although not illustrated, the battery element is wound around a center pin. One end of the battery can 602 is closed and the other end thereof is opened. For the battery can 602, a metal having corrosion resistance to an electrolyte solution, such as nickel, aluminum, or titanium, an alloy of such a metal, or an alloy of such a metal and another metal (e.g., stainless steel) can be used. The battery can 602 is preferably covered with nickel, aluminum, or the like in order to prevent corrosion due to the electrolyte solution. Inside the battery can 602, the battery element in which the positive electrode, the negative electrode, and the separator are wound is provided between a pair of insulating plates 608 and 609 that face each other. Furthermore, a nonaqueous electrolyte solution (not illustrated) is injected inside the battery can 602 provided with the battery element.

A positive electrode and a negative electrode that are used for a cylindrical storage battery are wound, and thus preferably have a structure in which active materials are formed on both surfaces of a current collector. A positive electrode terminal (positive electrode current collecting lead) 603 is connected to the positive electrode 604, and a negative electrode terminal (negative electrode current collecting lead) 607 is connected to the negative electrode 606. Both the positive electrode terminal 603 and the negative electrode terminal 607 can be formed using a metal material such as aluminum. The positive electrode terminal 603 and the negative electrode terminal 607 are resistance-welded to a safety valve mechanism 613 and the bottom of the battery can 602, respectively. The safety valve mechanism 613 is electrically connected to the positive electrode cap 601 through a PTC element (Positive Temperature Coefficient) 611. The safety valve mechanism 613 cuts off electrical connection between the positive electrode cap 601 and the positive electrode 604 when the internal pressure of the battery exceeds a predetermined threshold. In addition, the PTC element 611 is a thermally sensitive resistor whose resistance increases as temperature rises, and limits the amount of current by increasing the resistance to prevent abnormal heat generation. Barium titanate (BaTiO₃)-based semiconductor ceramics or the like can be used for the PTC element.

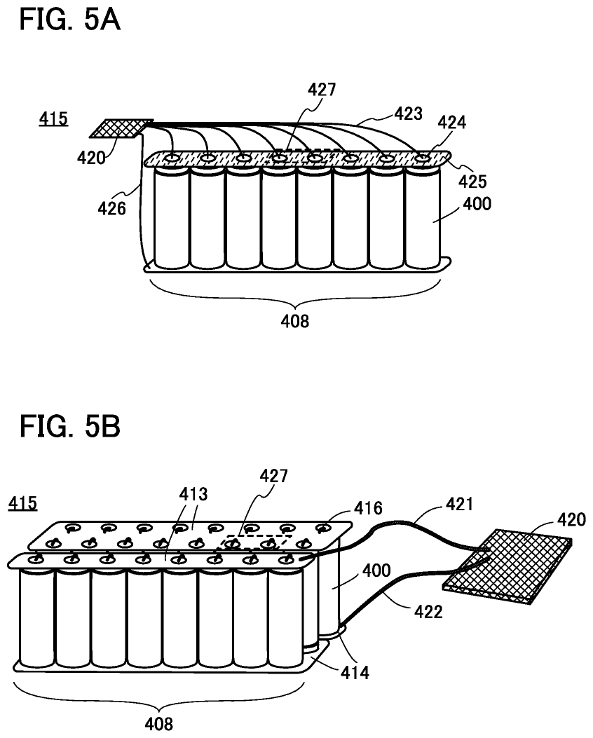

FIG. 5A shows an example of a power storage device 415. The power storage device 415 includes an assembled battery 408, a temperature sensor 427, and a semiconductor device 420.

For the assembled battery 408, the description of the assembled battery 120 described in the above embodiment can be referred to. For the temperature sensor 427, the description of the temperature sensor TS1 described in the above embodiment can be referred to. For the semiconductor device 420, the description of the semiconductor device 101 described in the above embodiment can be referred to.

The assembled battery 408 includes a plurality of secondary batteries 400. Positive electrodes of the secondary batteries are in contact with and electrically connected to conductors 424 isolated by an insulator 425. The conductor 424 is electrically connected to the semiconductor device 420 through a wiring 423. Negative electrodes of the secondary batteries are electrically connected to the semiconductor device 420 through a wiring 426.

FIG. 5B shows an example of the power storage device 415. The power storage device 415 includes the assembled battery 408, the temperature sensor 427, and the semiconductor device 420.

For the assembled battery 408, the description of the assembled battery 120 described in the above embodiment can be referred to. For the temperature sensor 427, the description of the temperature sensor TS1 described in the above embodiment can be referred to. For the semiconductor device 420, the description of the semiconductor device 101 described in the above embodiment can be referred to.

The assembled battery 408 includes a plurality of secondary batteries 400, and the plurality of secondary batteries 400 are sandwiched between a conductive plate 413 and a conductive plate 414. The plurality of secondary batteries 400 are electrically connected to the conductive plate 413 and the conductive plate 414 through a wiring 416. The plurality of secondary batteries 400 may be connected in parallel or in series, or the secondary batteries may be connected in parallel and then sets of the parallel-connected secondary batteries may be further connected in series. With the power storage device 415 including the plurality of secondary batteries 400, large power can be extracted.

The plurality of secondary batteries 400 may be connected in parallel and then further connected in series.

A temperature control device may be provided between the plurality of secondary batteries 400. When the secondary batteries 400 are heated excessively, the temperature control device can cool them, and when the secondary batteries 400 get too cold, the temperature control device can heat them. Thus, the performance of the power storage device 415 is not easily influenced by the outside temperature.

In FIG. 5B, the power storage device 415 is electrically connected to the semiconductor device 420 through a wiring 421 and a wiring 422. The wiring 421 is electrically connected to the positive electrodes of the plurality of secondary batteries 400 through the conductive plate 413. The wiring 422 is electrically connected to the negative electrodes of the plurality of secondary batteries 400 through the conductive plate 414.

### [Rectangular Secondary Battery]

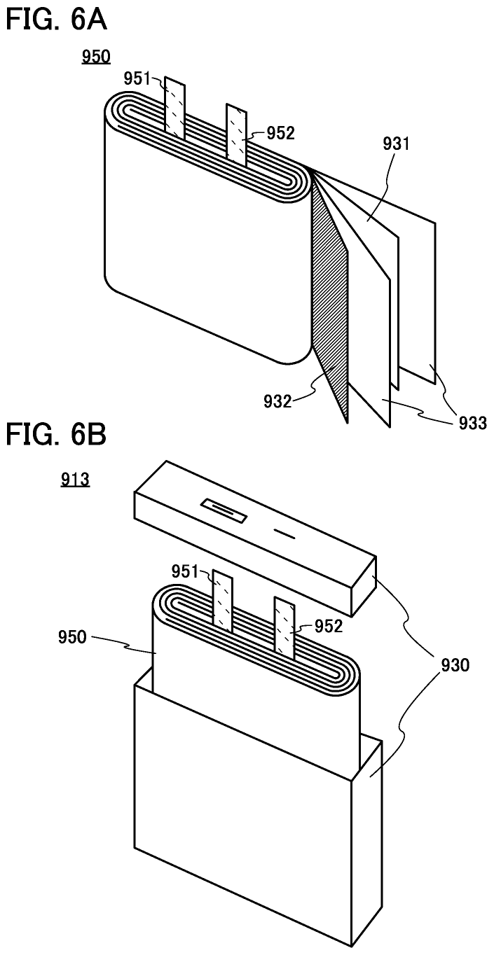

An example of a secondary battery that can be used for the battery cell included in the power storage device of one embodiment of the present invention is described with reference to FIG. 6.

A wound body 950 illustrated in FIG. 6A includes a negative electrode 931, a positive electrode 932, and separators 933. The wound body 950 is obtained by winding a sheet of a stack in which the negative electrode 931 overlaps with the positive electrode 932 with the separator 933 provided therebetween. Note that a plurality of stacks of the negative electrode 931, the positive electrode 932, and the separator 933 may be further overlaid. Note that the number of stacks including the negative electrode 931, the positive electrode 932, and the separator 933 is designed as appropriate depending on required capacity and element volume. The terminal 951 and the terminal 952 are a positive electrode lead electrode and a negative electrode lead electrode, respectively.

As illustrated in FIG. 6B, a rectangular case can be used as a housing 930. The housing 930 is filled with an electrolyte solution. In FIG. 6B, the housing 930 that has been divided is illustrated for convenience; however, in reality, the wound body 950 is covered with the housing 930, and the terminal 951 and the terminal 952 extend to the outside of the housing 930. For the housing 930, a metal material (e.g., aluminum) or a resin material can be used.

This embodiment can be implemented in appropriate combination with the other embodiments.

### Embodiment 4

In this embodiment, an example of a processing unit or the like that can be used in one embodiment of the present invention will be described.

### <Structure Example 1 of Processing Unit>

A processing unit capable of power gating, a power management mechanism thereof, and the like are described below.

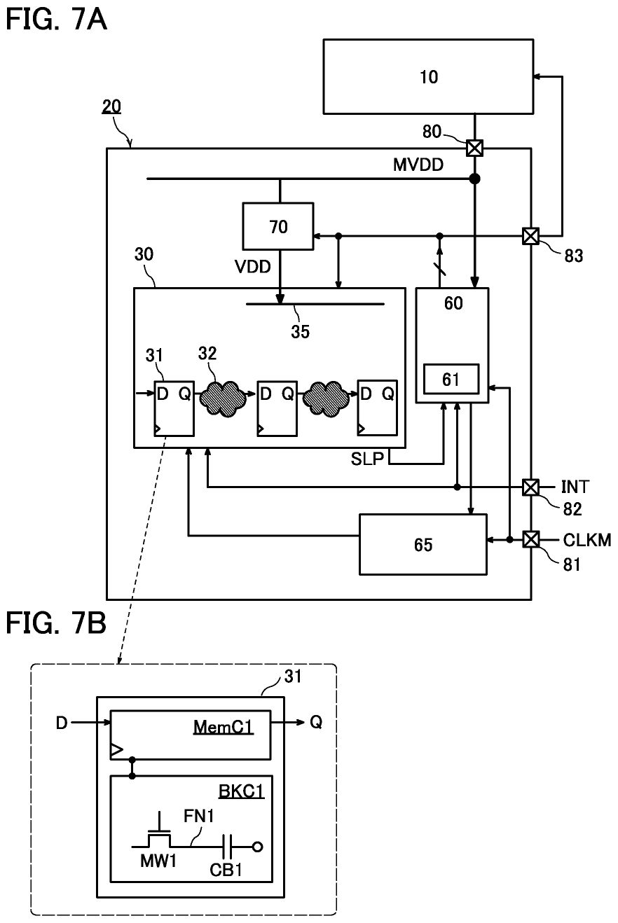

A semiconductor device and power management thereof will be described with reference to FIG. 7. The semiconductor device illustrated in FIG. 7A includes a power supply circuit 10 and a processing unit (PU) 20. The PU 20 is a circuit having a function of executing an instruction. The PU 20 includes a plurality of functional circuits integrated over one chip. The PU 20 includes a processor core 30, a power management unit (PMU) 60, a clock control circuit 65, a power switch (PSW) 70, and a terminal 80 to a terminal 83. FIG. 7A shows an example in which the power supply circuit 10 is provided over a chip different from a chip over which the PU 20 is provided. A power supply potential MVDD is input from the power supply circuit 10 to the terminal 80. A reference clock signal CLKM is input from the outside to the terminal 81. A signal INT is input from the outside to the terminal 82. The signal INT is an interrupt signal for requesting interrupt processing. The signal INT is input to the PU 20 and the PMU 60. A control signal generated in the PMU 60 is output to the terminal 83, and the terminal 83 is electrically connected to the power supply circuit 10.

In the semiconductor device of one embodiment of the present invention, the number of bits that the processing unit can process in an arithmetic circuit or the like can be 8, 16, 32, or 64, for example.

### <Processor Core 30 and Memory Circuit 31>

The processor core 30 is a circuit having a function of processing an instruction and can be referred to as an arithmetic processing circuit. The processor core 30 includes a memory circuit 31, a plurality of combinational circuits 32, and the like, and a variety of functional circuits are formed using these circuits. For example, the memory circuit 31 is included in a register.

As illustrated in FIG. 7B, the memory circuit 31 includes a circuit MemC1 and a circuit BKC1. The circuit MemC1 has a function of retaining data generated in the processor core 30, and can be formed using a flip-flop circuit (FF) or a latch circuit, for example. The circuit BKC1 can function as a backup circuit of the circuit MemC1, and can retain data for a long time even when power supply is stopped or supply of a clock signal is stopped. Including such a memory circuit 31 enables power gating of the processor core 30. This is because the state of the processor core 30 at the time of power-off can be retained by saving data of the circuit MemC1 to the circuit BKC1 in the memory circuit 31 before power-off. When the power supply is restarted, data retained in the circuit BKC1 is written to the circuit MemC1; thus, the state of the processor core 30 at the time of power-off can be restored. Consequently, the PU 20 can perform normal processing immediately after the power supply is restarted.

The circuit BKC1 includes at least a retention circuit including one transistor (MW1) and one capacitor (CB1). The retention circuit illustrated in FIG. 7B has a circuit structure similar to a 1T1C (one transistor and one capacitor) memory cell structure of a standard DRAM (dynamic random access memory), and can perform writing and reading operations in a similar manner. By control of the conduction state of the transistor MW1, charging and discharging of the capacitor CB1 are controlled. When the transistor MW1 is turned off, a node FN1 is brought into an electrically floating state. Fluctuation in the potential of the node FN1 can be inhibited by a significant reduction in the drain current of the transistor MW1 in an off state (off-state current); thus, the data retention time of the circuit BKC1 can be made longer. The data retention time of the circuit BKC1 is determined by the leakage current of the transistor MW1, the capacitance of the capacitor CB1, and the like. The use of the transistor MW1 having an extremely low off-state current eliminates the necessity of refreshing the circuit BKC1 while the PU 20 operates. Thus, the circuit BKC1 can be used as a nonvolatile memory circuit.

An OS transistor is preferably used as the transistor MW1. An oxide semiconductor has a band gap of 2 eV or more and thus has an extremely low off-state current. In an OS transistor, a normalized off-state current per micrometer of channel width at a source-drain voltage of 10 V can be less than or equal to 10×10⁻²¹ A (10 zeptoampere). When the transistor MW1 is an OS transistor, the circuit BKC1 can substantially function as a nonvolatile storage circuit while the PU 20 operates. In Embodiment 2, OS transistors are described.

An oxide semiconductor film used for a semiconductor layer where a channel is formed may be formed of a single oxide semiconductor film or stacked oxide semiconductor films. An oxide semiconductor included in the semiconductor layer where a channel is formed is preferably an oxide containing at least one or more elements selected from In, Ga, Sn, and Zn. As such an oxide, an In—Sn—Ga—Zn oxide, an In—Ga—Zn oxide, an In—Sn—Zn oxide, an In—Al—Zn oxide, a Sn—Ga—Zn oxide, an Al—Ga—Zn oxide, a Sn—Al—Zn oxide, an In—Zn oxide, a Sn—Zn oxide, an Al—Zn oxide, a Zn—Mg oxide, a Sn—Mg oxide, an In—Mg oxide, an In—Ga oxide, an In oxide, a Sn oxide, a Zn oxide, or the like can be used.

Data is written with voltage in the circuit BKC1; thus, the write power of the circuit BKC1 can be lower than that of an MRAM (magnetoresistive RAM) in which writing is performed with current. Furthermore, unlike in a flash memory, the number of data rewriting times is not limited because data is retained by the load capacitance of the node FN1.

In the circuit BKC1, energy required for data writing corresponds to energy required for charging and discharging of charge in the capacitor CB1. By contrast, in a memory circuit including a two-terminal memory element such as an MRAM, energy required for data writing corresponds to energy consumed when current flows to the memory element. In the MRAM, energy required for data writing is high because current continuously flows during a data writing period. As compared with such an MRAM, the circuit BKC1 can reduce energy consumed by data writing. Thus, as compared with a memory circuit in which a backup circuit is formed using an MRAM, the memory circuit 31 can frequently perform voltage scaling and power gating for reducing consumed energy, which leads to a reduction in the power consumption of the PU 20.

### <Power Management>

The PMU 60 has a function of controlling a power gating operation, a clock gating operation, a voltage scaling operation, and the like. Specifically, the PMU 60 has a function of controlling the power supply circuit 10, a function of controlling the memory circuit 31, a function of controlling the clock control circuit 65, and a function of controlling the PSW 70. Thus, the PMU 60 has a function of generating control signals for controlling these circuits (the power supply circuit 10, the memory circuit 31, the clock control circuit 65, and the PSW 70). The PMU 60 includes a circuit 61. The circuit 61 has a function of measuring time. The PMU 60 has a function of performing power management on the basis of data on time obtained by the circuit 61.

The PSW 70 has a function of controlling supply of a power supply potential MVDD to the PU 20 in response to a control signal of the PMU 60. Here, a power supply potential supplied to the PU 20 through the PSW 70 is referred to as the power supply potential VDD. The processor core 30 may include a plurality of power domains. In that case, supply of power to the plurality of power domains may be controlled independently by the PSW 70. In addition, the processor core 30 may include a power domain that does not require power gating. In that case, a power supply potential may be supplied to this power domain without through the PSW 70.

The reference clock signal CLKM is input to the clock control circuit 65, and the clock control circuit 65 has a function of generating and outputting a gated clock signal. The clock control circuit 65 has a function of stopping supply of a clock signal to the processor core 30 in response to a control signal of the PMU 60. The power supply circuit 10 has a function of changing the magnitude of the power supply potential VDD in response to a control signal of the PMU 60.

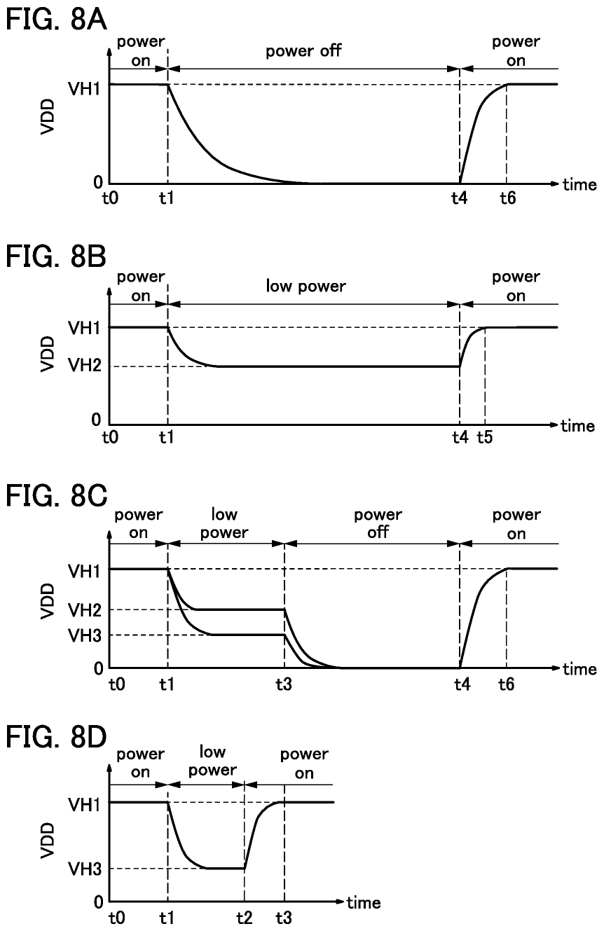

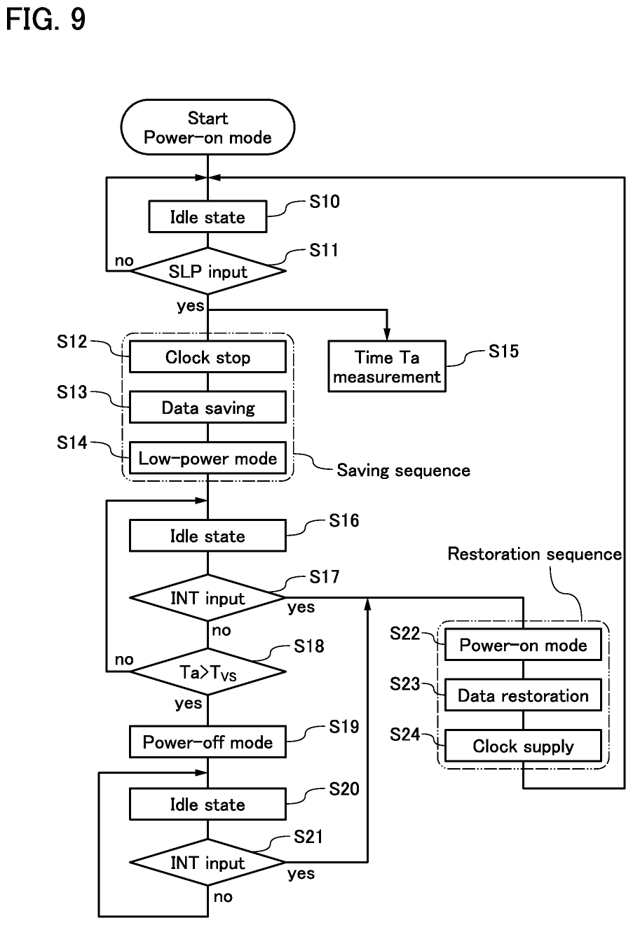

A signal SLP output from the processor core 30 to the PMU 60 is a trigger signal for transferring the processor core 30 to a resting state. When the signal SLP is input to the PMU 60, the PMU 60 generates a control signal for transition to a resting state and outputs the control signal to a functional circuit to be controlled. The power supply circuit 10 makes the power supply potential MVDD lower than that in normal operation in response to a control signal of the PMU 60. After the processor core 30 is in the resting state for a certain period of time, the PMU 60 controls the PSW 70 and stops power supply to the processor core 30. When the processor core 30 is transferred from a normal state to the resting state, the PMU 60 performs a voltage scaling operation for lowering the power supply potential VDD of the processor core 30. When the period of the resting state exceeds the set time, the PMU 60 performs a power gating operation for stopping supply of the power supply potential VDD to the processor core 30 in order to further reduce the power consumption of the processor core 30. Power management of the semiconductor device illustrated in FIG. 7 will be described below with reference to FIG. 8 and FIG. 9.

FIG. 8 schematically shows changes in the potential of a power supply line 35. The power supply potential VDD is supplied to the power supply line 35 through the PSW 70. The horizontal axis in each diagram shows the time elapsing between transition from the normal state to the resting state, and t0, t1, and the like each represent time. FIG. 8A shows an example in which only power gating is executed in the resting state, and FIG. 8B shows an example in which only voltage scaling is executed in the resting state. FIG. 8C and FIG. 8D each show an example in which voltage scaling and power gating are executed. In the normal state, the magnitude of the power supply potential MVDD supplied from the power supply circuit 10 is VH1.

In the following description, the power mode of the PU 20 is divided into three modes: a power-on mode, a power-off mode, and a low-power mode. The power-on mode is a mode in which the power supply potential VDD that enables normal processing is supplied to the PU 20. The power-off mode is a mode in which the supply of the power supply potential VDD is stopped by the PSW 70. The low-power mode is a mode in which the power supply potential VDD lower than that in the power-on mode is supplied.

The example in FIG. 8A is described. At the time t0, processing for transition to the resting state is started in the processor core 30. For example, backup of the memory circuit 31 is performed. The PMU 60 controls the PSW 70 and stops supply of power to the processor core 30 at the time t1. A power supply line 35 is self-discharged and its potential is decreased to 0 V. Consequently, leakage current of the processor core 30 in the resting state can be significantly lowered, so that power consumption in the resting state (hereinafter, referred to as standby power in some cases) can be reduced. In the case where the processor core 30 returns to the normal state in response to an interrupt request or the like from the outside, the PMU 60 controls the PSW 70 and restarts the supply of VDD. Here, at time t4, the supply of VDD is restarted. The potential of the power supply line 35 increases and becomes VH1 at time t6.

In the case of the example in FIG. 8B, voltage scaling is performed; thus, at the time t1, the PMU 60 controls the power supply circuit 10 and lowers the potential of the power supply potential MVDD to VH2. The potential of the power supply line 35 eventually becomes VH2. At the time t4, when the power supply potential MVDD returns from VH2 to VH1, the potential of the power supply line 35 increases and becomes VH1 at time t5.

In the case of the example in FIG. 8A, time taken for the return from the resting state to the normal state (overhead time) is time taken to increase the potential of the power supply line 35 from 0 V to VH1, and an energy overhead required for the return is energy required to charge the load capacitance of the power supply line 35 from 0 V to VH1. When the period of the power-off mode (t1 to t4) is sufficiently long, power gating is effective in reducing standby power of the PU 20. By contrast, when the period (t1 to t4) is short, power required for the return to the normal state is higher than power reduced by power-off; therefore, the effect of power gating cannot be obtained.

In the example of voltage scaling shown in FIG. 8B, the potential of the power supply line 35 is VH2 in the resting state; thus, the amount of standby power reduction is smaller than that in the example of power gating in FIG. 8A. In the example of FIG. 8B, fluctuation in the potential of the power supply line 35 is small; therefore, time taken for the return to the normal state is shorter and energy required for the return is lower than those in the example of FIG. 8A. Accordingly, the semiconductor device illustrated in FIG. 7 can perform power management in which power gating and voltage scaling are combined to efficiently reduce the standby power of the PU 20. FIG. 8C and FIG. 8D each show a power management example.

As shown in FIG. 8C, first, a voltage scaling operation is performed in the resting state and the mode is transferred from the power-on mode to the low-power mode. As in FIG. 8B, at the time t1, the PMU 60 controls the power supply circuit 10 and lowers the potential of the power supply potential MVDD to VH2; thus, the potential of the power supply line 35 eventually becomes VH2. After a certain period of time from transition to the low-power mode (t1 to t3), the PMU 60 controls the PSW 70 and transfers the mode to the power-off mode. In the period (t3 to t4), power reduced by powering off the PU 20 by power gating, which includes power consumed by returning to the normal state, is higher than power reduced by supplying VH2 to the PU 20.

For example, the potential VH2 is a power supply potential high enough to retain data in the circuit MemC1 of the memory circuit 31, and a potential VH3 is a potential at which data of the circuit MemC1 is lost. In the PU 20 of FIG. 7A, the circuit BKC1 can retain data even while power supply is stopped. When data of the memory circuit 31 is saved to the circuit BKC1 in the period (t0 to t1), VDD can be lowered to the potential VH3 at which data of the circuit MemC1 is lost in the low-power mode. Thus, the standby power of the PU 20 can be further reduced.

The PMU 60 has a function of returning the PU 20 to the normal state in response to an interrupt request or the like. The PMU 60 controls the power supply circuit 10 to increase the magnitude of MVDD to VH1 and controls the PSW 70 to restart the supply of VDD from the PU 20. After the time t4, the power-on mode continues. In the case where the potential of the power supply line 35 is stabilized at the time t6, the PU 20 can perform a normal operation after the time t6.

FIG. 8D shows an example in which an interrupt request for the return to a normal operation is input before the time t3. After the time t2, the power-on mode continues. At the time t2, the PMU 60 controls the power supply circuit 10 to change the magnitude of MVDD to the potential VH1 in the power-on mode. At the time t3, the potential of the power supply line 35 increases to VH1.

As shown in FIG. 8C and FIG. 8D, time required to restore the potential of the power supply line 35 to VH1 in the resting state is longer when the mode returns from the power-off mode to the power-on mode than when the mode returns from the low-power mode to the power-on mode. Thus, the PMU 60 has a function of adjusting timing of returning the processor core 30 from the resting state to the normal state depending on the power mode. Accordingly, the processor core 30 can return from the resting state to the normal state in the minimum time.

In the resting state, transition time from the low-power mode to the power-off mode can be measured by the circuit 61 provided in the PMU 60. When the signal SLP is input from the PU 20, the PMU 60 starts time measurement in the circuit 61. After a certain period of time from transition to the low-power mode, the PMU 60 is transferred to the power-off mode. The PSW 70 is turned off by a control signal of the PMU 60, and the supply of VDD is stopped. In this manner, the PMU 60 can be transferred from the low-power mode to the power-off mode in response to an interrupt request based on measurement data of the circuit 61. A power management operation example of the PMU 60 will be described below with reference to FIG. 9.

The PU 20 performs a normal operation. The power mode is a power-on mode and the PMU 60 is in an idle state (Step S10). The PMU 60 is in the idle state until the signal SLP is input, and a saving sequence is executed with input of the signal SLP as a trigger (Step S11). In the saving sequence example of FIG. 9, first, the PMU 60 outputs a control signal to the clock control circuit 65 and stops output of a clock signal (Step S12). Next, a control signal for data saving is output to the memory circuit 31 (Step S13). In the memory circuit 31, data retained in the circuit MemC1 is saved to the circuit BKC1 in response to a control signal of the PMU 60. Finally, the PMU 60 controls the power supply circuit 10 to lower MVDD. Through these operations, the power mode is transferred to the low-power mode (Step S14). When the signal SLP is input, the PMU 60 controls the circuit 61 included therein and measures time Ta in the low-power mode (Step S15). Timing of operating the circuit 61 may be any timing as long as the saving sequence is executed; for example, the circuit 61 may operate when the signal SLP is input, when a control signal is output to the clock control circuit 65, when data saving is started, when data saving is terminated, or when a control signal is output to the power supply circuit 10.

After the saving sequence is executed, the PMU 60 is set in an idle state (Step S16), and monitors input of the signal INT and the measurement time Ta of the clock control circuit 65. When the signal INT is input, the sequence is transferred to a restoration sequence (Step S17). Whether the time Ta exceeds set time Tᵥₛ is determined (Step S18). When the time Ta exceeds the time Tᵥₛ, the PMU 60 transfers the power mode to the power-off mode (Step S19). When the time Ta does not exceed the time Tᵥₛ, the PMU 60 remains in the idle state (Step S16). The time Tᵥₛ is set such that the standby power of the processor core 30 in the power-off mode can be lower than that in the low-power mode.

In Step S19, the PMU 60 outputs, to the PSW 70, a control signal for stopping supply of power to the processor core 30. After the mode is transferred to the power-off mode, the PMU 60 is set in the idle state again (Step S20), and input of the signal INT is monitored (Step S21). When the signal INT is input, the PMU 60 executes the restoration sequence.

In the restoration sequence, first, the PMU 60 is transferred from the power-off mode to the power-on mode (Step S22). The PMU 60 controls the power supply circuit 10 to output a power supply potential in a normal operation. In addition, the PMU 60 controls the PSW 70 to restart the supply of VDD to the processor core 30. Next, a control signal is output to the memory circuit 31 and data of the memory circuit 31 is restored (Step S23). In the memory circuit 31, data retained in the circuit BKC1 is restored to the circuit MemC1 in response to a control signal of the PMU 60. The PMU 60 outputs a control signal for outputting a clock signal to the clock control circuit 65 (Step S24). The clock control circuit 65 restarts the output of a clock signal in response to a control signal of the PMU 60.

As compared with the case where the restoration sequence is executed in accordance with determination in Step S21, the potential of the power supply line 35 can be quickly stabilized in the case where the restoration sequence is executed in accordance with determination in Step S17 because the power mode returns from the low-power mode to the power-on mode. Thus, in the PMU 60, timing of executing Step S23 when the restoration sequence is executed in accordance with Step S17 is faster than that when the restoration sequence is executed in accordance with Step S21. Consequently, time taken to return the processor core 30 from the resting state to the normal state can be shortened.

As described above, in power management of the semiconductor device illustrated in FIG. 7, when the PU 20 is set in the resting state, first, time and energy overheads due to the return from the resting state to the normal state are suppressed while leakage current is reduced by lowering a power supply potential supplied to the processor core 30 with a voltage scaling operation. When the PU 20 is in the resting state for a certain period of time, a power gating operation is performed to reduce the leakage current of the processor core 30 as much as possible. Thus, the power consumption of the PU 20 in the resting state can be reduced without a decrease in the processing performance of the PU 20.

### <<Structure Example 2 of Processing Unit>>

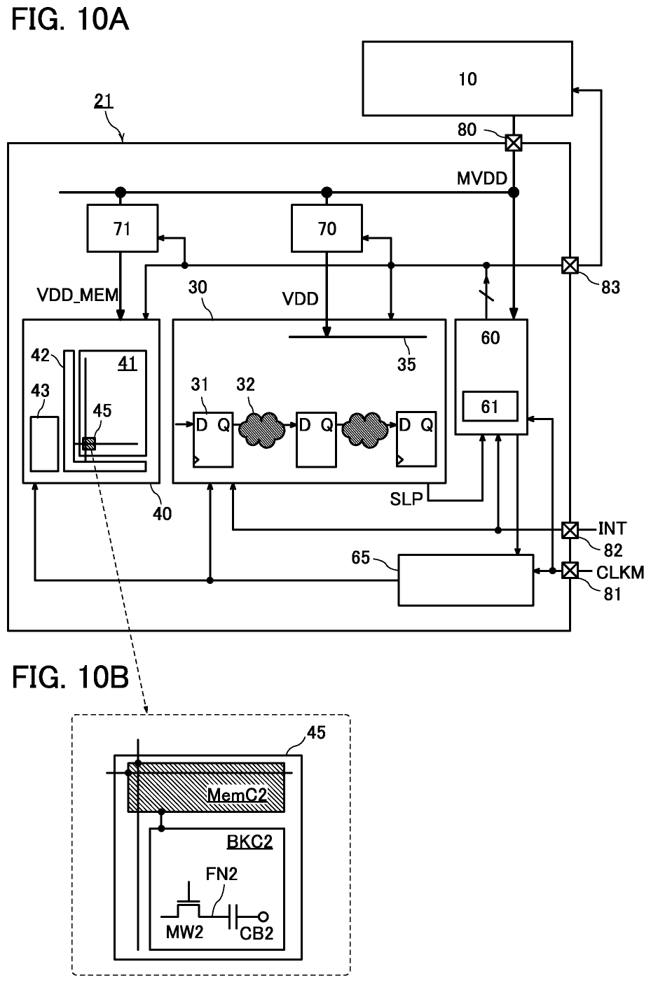

FIG. 10A shows a modification example of the processing unit in FIG. 7A. A processing unit (PU) 21 illustrated in FIG. 10A is obtained by addition of a cache 40 and a power switch (PSW) 71 to the PU 20. The cache 40 can perform power gating and voltage scaling as in the PU 20, and the power mode of the cache 40 changes along with the power mode of the PU 21. The PSW 71 controls supply of the power supply potential MVDD to the cache 40 and is controlled by the PMU 60. Here, a power supply potential input to the cache 40 through the PSW 71 is VDD_MEM. As in the processor core 30, a control signal from the PMU 60 and a gated clock signal from the clock control circuit 65 are input to the cache 40.

### <Cache 40>

The cache 40 is a memory device having a function of temporarily storing frequently used data. The cache 40 includes a memory array 41, a peripheral circuit 42, and a control circuit 43. The memory array 41 includes a plurality of memory cells 45. The control circuit 43 controls the operation of the cache 40 in response to a request from the processor core 30. For example, a writing operation and a reading operation of the memory array 41 are controlled. The peripheral circuit 42 has a function of generating a signal for driving the memory array 41 in response to a control signal from the control circuit 43. The memory array 41 includes the memory cells 45 for retaining data.

As illustrated in FIG. 10B, the memory cells 45 each include a circuit MemC2 and a circuit BKC2. The circuit MemC2 is a memory cell to be accessed in a normal operation. For example, an SRAM (static random access memory) cell is used. The circuit BKC2 can function as a backup circuit of the circuit MemC2, and can retain data for a long time even while power supply is stopped or supply of a clock signal is stopped. When such memory cells 45 are provided, power gating of the cache 40 can be performed. Before the power supply is stopped, data of the circuit MemC2 is saved to BKC2 in each of the memory cells 45. After the power supply is restarted, data retained in the circuit BKC2 is restored to the circuit MemC2, so that the PU 21 can quickly return to the state before the power supply is stopped.

Like the circuit BKC1 in FIG. 7B, the circuit BKC2 in each of the memory cells 45 includes at least a retention circuit including one transistor (MW2) and one capacitor (CB2). In other words, the circuit BKC2 also includes a retention circuit having a structure similar to that of a 1T1C memory cell of a standard DRAM. The transistor MW2 has an extremely low off-state current. As in the transistor MW1, an OS transistor is used as the transistor MW2. Such a structure can suppress fluctuation in the potential of a node FN2 that is electrically floating also in the circuit BKC2; thus, the circuit BKC2 can retain data for a long time. The data retention time of the circuit BKC2 is determined by the leakage current of the transistor MW2, the capacitance of the capacitor CB2, and the like. When the transistor MW2 has an extremely low off-state current, the circuit BKC2 can be used as a nonvolatile memory circuit that does not need a refresh operation.

As in the PU 20, the PMU 60 performs power management (see FIG. 9) in the PU 21 illustrated in FIG. 10A. In Step S13 shown in FIG. 9, a data saving operation of the memory circuit 31 and the cache 40 is performed. In Step S19, the PSW 70 and the PSW 71 are controlled to stop supply of power to the processor core 30 and the cache 40. In Step S22, the PSW 70 and the PSW 71 are controlled to restart the supply of power to the processor core 30 and the cache 40. In Step S23, a data restoration operation of the memory circuit 31 and the cache 40 is performed.

Thus, like the semiconductor device illustrated in FIG. 7, the semiconductor device illustrated in FIG. 10 can reduce power in the resting state of the PU 21 without a decrease in processing performance of the PU 21 by power management in which voltage scaling and power gating are combined.

### <<Processor Core Structure Example>>

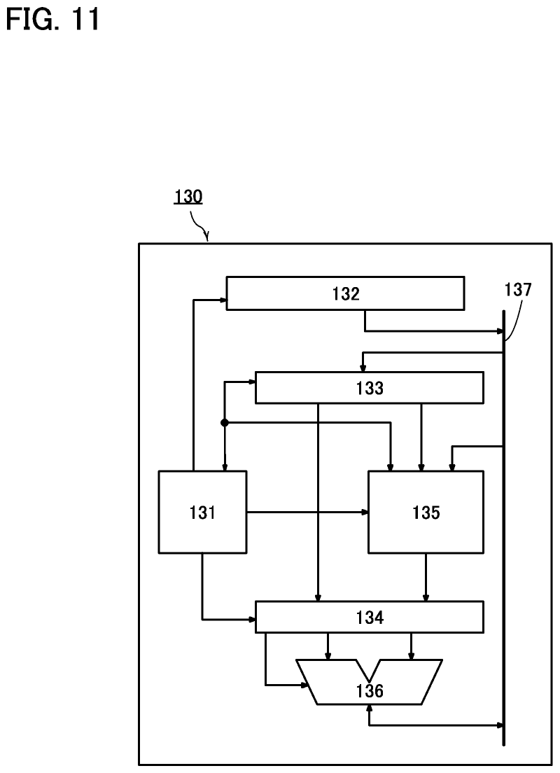

FIG. 11 shows a structure example of a processor core. A processor core 130 illustrated in FIG. 11 includes a control device 131, a program counter 132, a pipeline register 133, a pipeline register 134, a register file 135, an arithmetic logic unit (ALU) 136, and a data bus 137. Data is transmitted between the processor core 130 and a peripheral circuit such as a PMU or a cache through the data bus 137.

The control device 131 has a function of decoding and executing instructions contained in a program such as input applications by controlling the overall operations of the program counter 132, the pipeline register 133, the pipeline register 134, the register file 135, the ALU 136, and the data bus 137. The ALU 136 has a function of performing a variety of arithmetic operations such as four arithmetic operations and logic operations. The program counter 132 is a register having a function of storing the address of an instruction to be executed next.

The pipeline register 133 has a function of temporarily storing instruction data. The register file 135 includes a plurality of registers including a general-purpose register and can store data read out from a main memory, data obtained as a result of arithmetic operations in the ALU 136, or the like. The pipeline register 134 has a function of temporarily storing data used for arithmetic operations in the ALU 136, data obtained as a result of arithmetic operations in the ALU 136, or the like.

The memory circuit 31 in FIG. 7B is used as the register included in the processor core 130.

### <Memory Circuit Structure Example>

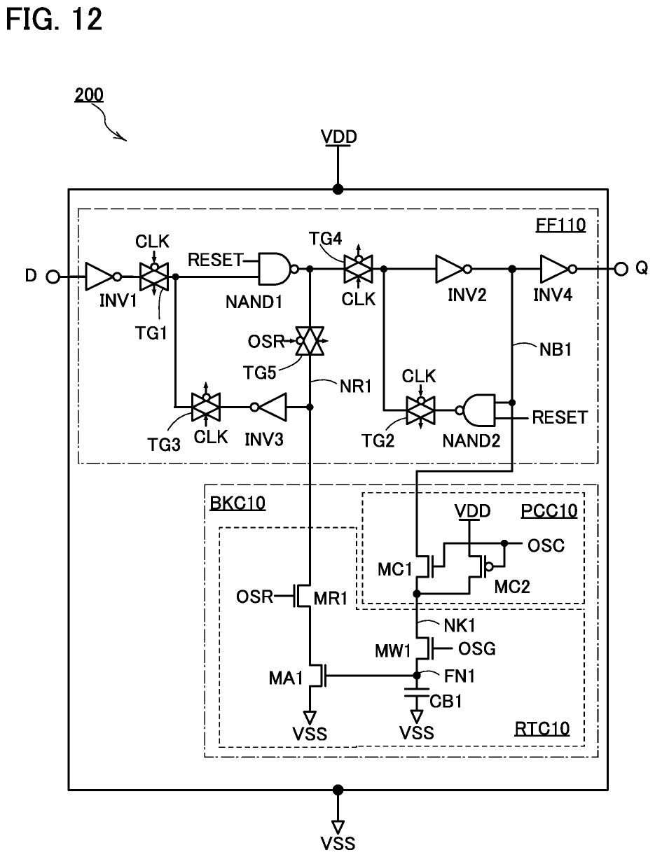

A more specific structure example of the memory circuit 31 illustrated in FIG. 7B is described. FIG. 12 is a circuit diagram showing a memory circuit structure example. A memory circuit 200 illustrated in FIG. 12 functions as a flip-flop circuit.

A standard flip-flop circuit (FF) can be used as the circuit MemC1, and for example, a master slave FF can be used. Such a structure example is illustrated in FIG. 12. An FF 110 includes transmission gates (TG1, TG2, TG3, TG4, and TG5), inverter circuits (INV1 and INV2), and NAND circuits (NAND1 and NAND2). A signal RESET and a signal OSR are control signals output from the PMU 60. The signal OSR and an inverted signal thereof are input to TG5. A clock signal CLK and an inverted signal thereof are input to TG1 to TG4. One clocked inverter circuit may be provided instead of TG1 and INV1. One clocked NAND circuit may be provided instead of TG2 and NAND2. A clocked inverter circuit may be provided instead of TG3 and INV3. TG5 functions as a switch that controls conduction between an output node of NAND1 and a node NR1. A node NB1 is electrically connected to an input node of a circuit BKC10, and the node NR1 is electrically connected to an output node of the circuit BKC10.

The circuit BKC10 illustrated in FIG. 12 functions as a backup circuit of the FF 110. The circuit BKC10 includes a circuit RTC10 and a circuit PCC10. Signals (OSG, OSC, and OSR) input to the circuit BKC10 are control signals output from the PMU 60. A power supply potential VSS is a low power supply potential and, for example, may be a ground potential (GND) or 0 V. As in BKC1, the power supply potential VSS and the power supply potential VDD are input to the FF 110. In the memory circuit 200, supply of VDD is controlled by the PMU 60.

The circuit RTC10 includes the transistor MW1, a transistor MA1, a transistor MR1, the node FN1, and a node NK1. The circuit RTC10 has a function of retaining data, and here, includes a 3T gain-cell memory circuit. The transistor MW1 is an OS transistor serving as a write transistor. The transistor MR1 is a read transistor, and the transistor MA1 functions as an amplifier transistor and a read transistor. The node FN1 retains data. The node NK1 is a data input node. The node NR1 is a data output node of the circuit RTC10.

FIG. 12 shows a structure example in which the circuit BKC10 reads out data of a slave latch circuit in the FF 110 in a saving operation and restores the retained data to a master latch circuit in a restoration operation. Data to be saved may be data of the master latch circuit. In addition, data may be restored to the slave latch circuit. In that case, TG5 is provided in the slave latch circuit.

The transistor MR1 and the transistor MA1 in the circuit RTC10 may be either n-channel transistors or p-channel transistors, and the levels of the potential of the signal OSR and a power supply potential supplied to the transistor MA1 may be changed depending on the conductivity types of the transistor MR1 and the transistor MA1. In addition, a logic circuit of the FF 110 may be set as appropriate. For example, in the case where the transistor MR1 and the transistor MA1 are p-channel transistors, NAND1 and INV3 are replaced with each other in the master latch circuit and INV2 and NAND2 are replaced with each other in the slave latch circuit. Furthermore, VDD is input to the transistor MA1 instead of VSS.

Data is written with voltage in the circuit BKC10; thus, the write power of the circuit BKC10 can be lower than that of an MRAM in which writing is performed with current. Furthermore, unlike in a flash memory, the number of data rewriting times is not limited because data is retained by the load capacitance of the node FN1.

In the circuit RTC10, energy required for data writing corresponds to energy required for charging and discharging of charge in the capacitor CB1. By contrast, in a memory circuit including a two-terminal memory element such as an MRAM, energy required for data writing corresponds to energy consumed when current flows to the memory element. Thus, as compared with an MRAM or the like in which current continuously flows during a data writing period, the circuit BKC10 can reduce energy consumed by data saving. Accordingly, as compared with the case of providing an MRAM, BET (Break Even Time) can be shortened in the case of providing the circuit BKC10 as a backup circuit. Consequently, opportunities of performing power gating by which energy consumption can be reduced are increased, so that the power consumption of the semiconductor device can be reduced.

The circuit PCC10 includes a transistor MC1 and a transistor MC2. The circuit PCC10 has a function of precharging the node FN1. The circuit PCC10 is not necessarily provided. As described later, the data saving time of the circuit BKC10 can be shortened by provision of the circuit PCC10.

### <Operation Example of Memory Circuit>

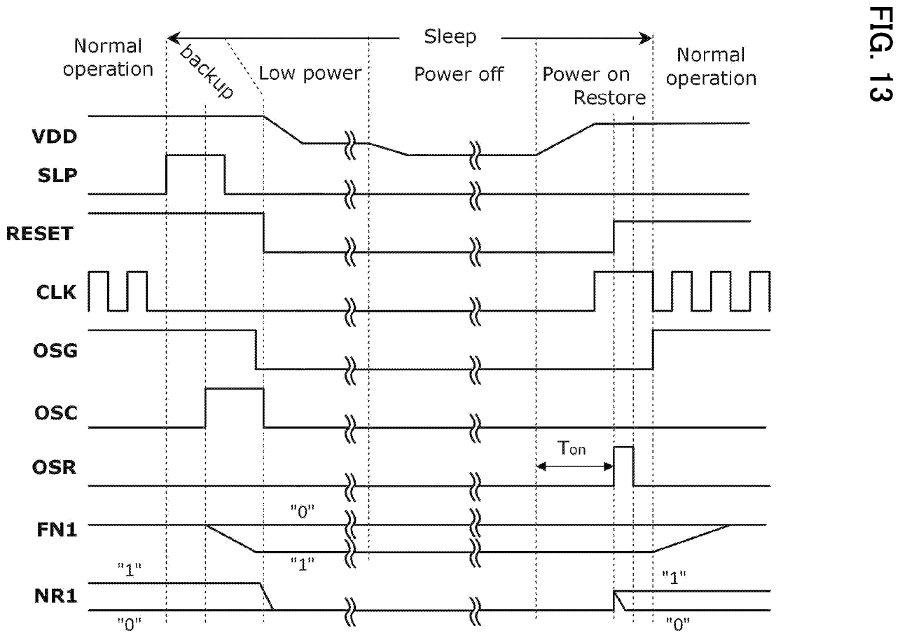

FIG. 13 is a timing chart showing an operation example of the memory circuit 200, and shows changes in waveforms of control signals (the signal SLP, the signal RESET, the clock signal CLK, the signal OSG, and the signal OSR) and changes in the potentials of the power supply potential VDD, the node FN1, and the node NR1.

### [Normal Operation]

A period of “Normal operation” is described. The power supply potential VDD and the clock signal CLK are supplied to the memory circuit 200. The FF 110 functions as a sequential circuit. The signal RESET is kept at a high level; thus, NAND1 and NAND2 function as inverter circuits. In the circuit BKC1, the transistor MC1 is in an off state and the transistor MC2 and the transistor MW1 are in an on state, so that the potential of the node FN1 is precharged to a high level.

### [Data Saving]

Next, a period of “Back up” is described. First, supply of the clock signal CLK is stopped. Thus, data rewriting of the node NB1 is stopped. In the example of FIG. 13, the potential level of the node NB1 is at a low level (“0”) when the potential of the node NR1 is at a high level (“1”), and the potential level of the node NB1 is at the high level (“1”) when the potential of the node NR1 is at the low level (“0”). While the signal OSC is at a high level, data of the node NB1 is saved to the node FN1. Specifically, since the transistor MC1 and the transistor MW1 are in an on state, the node FN1 is electrically connected to the node NB1. When the signal OSG is set at a low level to turn off the transistor MW1, the node FN1 is brought into an electrically floating state and the circuit BKC10 retains data. The potential of the node FN1 is at a high level when the node NR1 is at the low level (“0”), and the potential of the node FN1 is at a low level when the node NR1 is at the high level (“1”).

Data saving is terminated by setting the signal OSG at a low level; thus, a voltage scaling operation of the PU 20 can be performed immediately after the signal OSG is set at a low level. In addition, since the node FN1 is precharged to the high level by the transistor MC2 in the normal operation, charge transfer of the node FN1 does not occur in a data saving operation in which the node FN1 is set at the high level. Thus, the circuit BKC10 can complete a saving operation in a short time.

In the data saving operation, the clock signal CLK is inactive. Although the potential of the clock signal CLK is at a low level in the example of FIG. 13, the potential of the signal CLK may be ata high level.

### [Voltage Scaling in Low-Power Mode]

Next, a period of “Low power” is described. The PMU 60 performs a voltage scaling operation along with the signal OSC falling. Thus, the memory circuit 200 is transferred to the low-power mode.

### [Power Gating in Power-Off Mode]

Next, a period of “Power off” is described. After a certain period of time from transition to the low-power mode, the PMU 60 performs a power gating operation and the memory circuit 200 is transferred to the power-off mode.

### [Power-On Mode]

Next, a period of “Power on” is described. The PMU 60 returns the memory circuit 200 to the power-on mode in response to an interrupt request. In the example of FIG. 13, when the potential of a power supply line for supplying VDD is stabilized, the clock signal CLK is set at a high level. Note that in FIG. 13, the four periods of backup, Low power, Power off, and Power on are collectively represented as a period of “Sleep”.

### [Data Restoration]

While the signal OSR is at a high level, a data restoration operation is performed. When the signal RESET is set at a high level, the potential of the node NR1 is precharged to the high level (“1”). When the signal OSR is set at a high level, TG5 has high impedance and the transistor MR1 is turned on. The conduction state of the transistor MA1 is determined by the potential of the node FN1. When the node FN1 is at a high level, the transistor MA1 is in a conduction state; thus, the potential of the node NR1 is decreased to the low level (“0”). When the node FN1 is at a low level, the potential of the node NR1 is kept at the high level. In other words, the FF 110 returns to the state before transition to the resting state.

As described above, rising of the signal RESET and the signal OSR enables high-level data to be restored to the node NR1 (Restore). Thus, the returning operation period of the memory circuit 200 can be shortened.

FIG. 13 shows an example in which the mode is transferred from the power-off mode to the power-on mode. In the case where the mode is transferred from the low-power mode to the power-on mode, a period Tₒₙ to stabilization of the potential of the power supply line for supplying VDD is shortened. In that case, rising of the signal OSR is preferably made faster than that when the mode is transferred from the power-off mode.

### [Normal Operation]

Next, a period of “Normal operation” is described. By restarting the supply of the clock signal CLK, the memory circuit 200 returns to a state in which a normal operation can be performed. When the signal OSG is set at a high level, the node FN1 is precharged to a high level by the circuit PCC10.

### <<Cache>>

An example in which the cache 40 is formed using an SRAM is described below.

### <Memory Cell Structure Example>

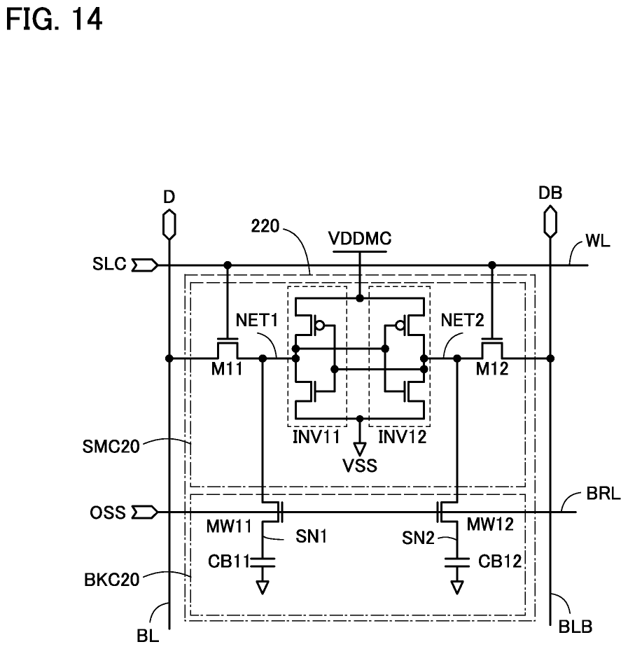

FIG. 14 shows a structure example of a cache memory cell. A memory cell 220 illustrated in FIG. 14 includes a circuit SMC20 and a circuit BKC20. The circuit SMC20 has a circuit structure similar to that of a standard SRAM memory cell. The circuit SMC20 illustrated in FIG. 14 includes an inverter circuit INV11, an inverter circuit INV12, a transistor M11, and a transistor M12.

The circuit BKC20 functions as a backup circuit of the circuit SMC20. The circuit BKC20 includes a transistor MW11, a transistor MW12, a capacitor CB11, and a capacitor CB12. The transistors MW11 and MW12 are OS transistors. The circuit SMC20 includes two 1T1C retention circuits, and a node SN1 and a node SN2 each retain data. A retention circuit formed using the transistor MW11 and the capacitor CB11 has a function of backing up data of a node NET1. A retention circuit formed using the transistor MW12 and the capacitor CB12 has a function of backing up data of a node NET2.

Power supply potentials VDDMC and VSS are supplied to the memory cell 220. The memory cell 220 is electrically connected to wirings (WL, BL, BLB, and BRL). A signal SLC is input to the wiring WL. A data signal D and a data signal DB are input to the wiring BL and the wiring BLB at the time of data writing. Data is read out by detection of the potentials of the wiring BL and the wiring BLB. A signal OSS is input to the wiring BRL. The signal OSS is a signal input from the PMU 60.

### <Operation Example of Memory Cell>

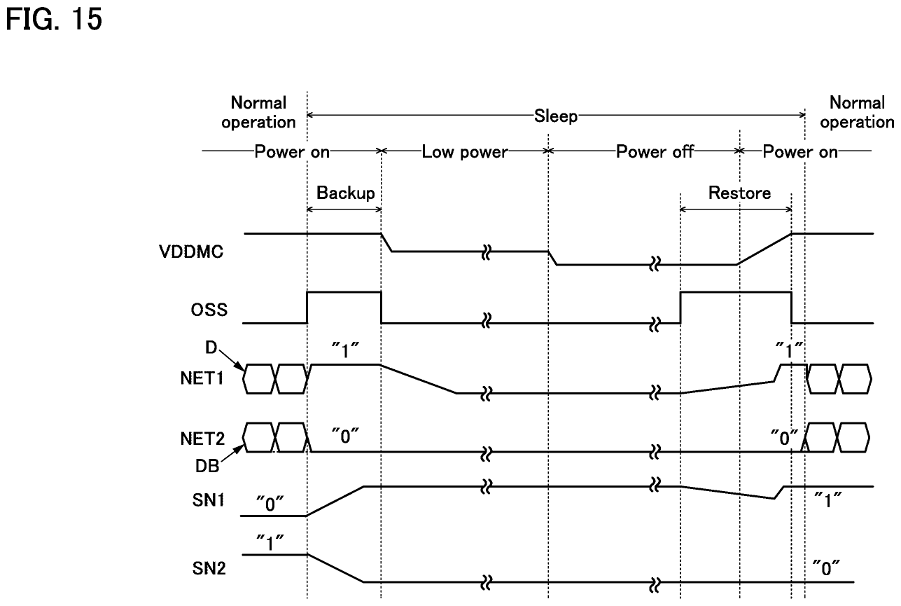

An operation example of the memory cell 220 is described. FIG. 15 is an example of a timing chart for the memory cell 220.

### [Normal Operation]

An access request is input to the circuit SMC20, and data is written and read out. In the circuit BKC20, the signal OSS is at a low level; thus, the node SN1 and the node SN2 are electrically floating and data is retained. In the example of FIG. 15, the potential of the node SN1 is at a low level (“0”) and the potential of the node SN2, which is another node, is at a high level (“1”).

### [Data Saving]

When the signal OSS is at a high level, the transistors MW11 and MW12 are turned on and the nodes SN1 and SN2 have the same potential levels as the nodes NET1 and NET2, respectively. In the example of FIG. 15, the potentials of the nodes SN1 and SN2 are set at a high level and a low level, respectively. The signal OSS is set at a low level and the circuit BKC20 retains data, so that a data saving operation is terminated.

### [Voltage Scaling in Low-Power Mode]

The PMU 60 performs a voltage scaling operation along with the signal OSS falling. Thus, the cache 40 is transferred to the low-power mode.

### [Power Gating in Power-Off Mode]

After a certain period of time from transition to the low-power mode, the PMU 60 performs a power gating operation and the cache 40 is transferred to the power-off mode.

### [Data Restoration in Power-On Mode]

The PMU 60 returns the cache 40 to a normal state in response to an interrupt request. The signal OSS is set at a high level to restore data retained in the circuit BKC20 to the circuit SMC20. While the signal OSS is at the high level, the PMU 60 performs a voltage scaling operation and a power gating operation and returns the memory circuit 200 to the power-on mode. In the example of FIG. 13, when the potential of the power supply line for supplying VDD is stabilized, the clock signal CLK is set at a high level. When the potential of a power supply line for supplying VDDMC is stabilized, the signal OSS is set at a low level to terminate a data restoration operation. The nodes SN1 and SN2 return to the states immediately before the resting states.

### [Normal Operation]

When the supply of VDDMC is restarted, the circuit SMC20 returns to a normal mode in which a normal operation can be performed.

As described above, with the use of an OS transistor, a backup circuit capable of retaining data for a long time even when power supply is stopped can be formed. This backup circuit enables power gating of a processor core and a cache. In addition, when power management in which voltage scaling is combined with power gating is performed in a resting state, energy and time overheads due to the return from the resting state to a normal state can be reduced. Thus, power can be reduced efficiently without a decrease in the processing performance of a processing unit.

### <Example of Memory>

An example of a memory using the OS transistor of one embodiment of the present invention is described below.

The power storage device included in one embodiment of the present invention preferably includes a memory. As the memory, a memory device using an OS transistor can be used. For example, a NOSRAM (registered trademark) or a DOSRAM (registered trademark) which are described below can be used.

A NOSRAM is a gain cell DRAM in which a write transistor of a memory cell is an OS transistor. A NOSRAM is an abbreviation for Nonvolatile Oxide Semiconductor RAM. A structure example of a NOSRAM is described below.

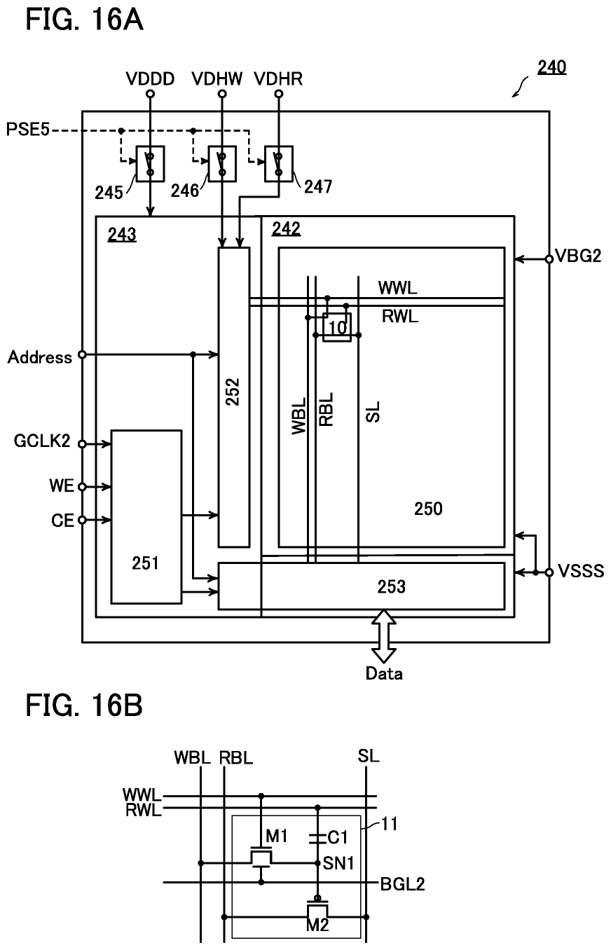

FIG. 16A is a block diagram showing a structure example of a NOSRAM. In a NOSRAM 240, power domains 242 and 243 and power switches 245 to 247 are provided. A memory cell array 250 is provided in the power domain 242, and a peripheral circuit of the NOSRAM 240 is provided in the power domain 243. The peripheral circuit includes a control circuit 251, a row circuit 252, and a column circuit 253.

A voltage VDDD, a voltage VSSS, a voltage VDHW, a voltage VDHR, a voltage VBG2, a clock signal GCLK2, an address signal, a signal CE, a signal WE, and a signal PSES are input to the NOSRAM 240 from the outside. The signal CE and the signal WE are a chip enable signal and a write enable signal, respectively. The signal PSES controls the on/off of the power switches 245 to 247. The power switches 245 to 247 control the input of the voltage VDDD, the voltage VDHW, and the voltage VDHR, respectively, to the power domain 243.

Note that the voltages, signals, and the like input to the NOSRAM 240 are appropriately selected in accordance with the circuit structure and operation method of the NOSRAM 240. For example, the NOSRAM 240 may be provided with a power domain which is not power gated, and a power gating control circuit that generates the signal PSES may be provided.

The memory cell array 250 includes a memory cell 11, a write word line WWL, a read word line RWL, a write bit line WBL, a read bit line RBL, and a source line SL.

As illustrated in FIG. 16B, the memory cell 11 is a 2T1C (two transistors and one capacitor) gain cell, which includes a node SN1, transistors M1 and M2, and a capacitor C1. The transistor M1 is a write transistor, which is an OS transistor having a back gate. The back gate of the transistor M1 is electrically connected to a wiring BGL2 for supplying the voltage VBG2. The transistor M2 is a read transistor, which is a p-channel Si transistor. The capacitor C1 is a storage capacitor for retaining the voltage of the node SN1.

The voltages VDDD and VSSS are voltages representing data “1” and “0”, respectively. Note that the high-level voltage of the write word line WWL and the high-level voltage of the read word line RWL are the voltage VDHW and the voltage VDHR, respectively.

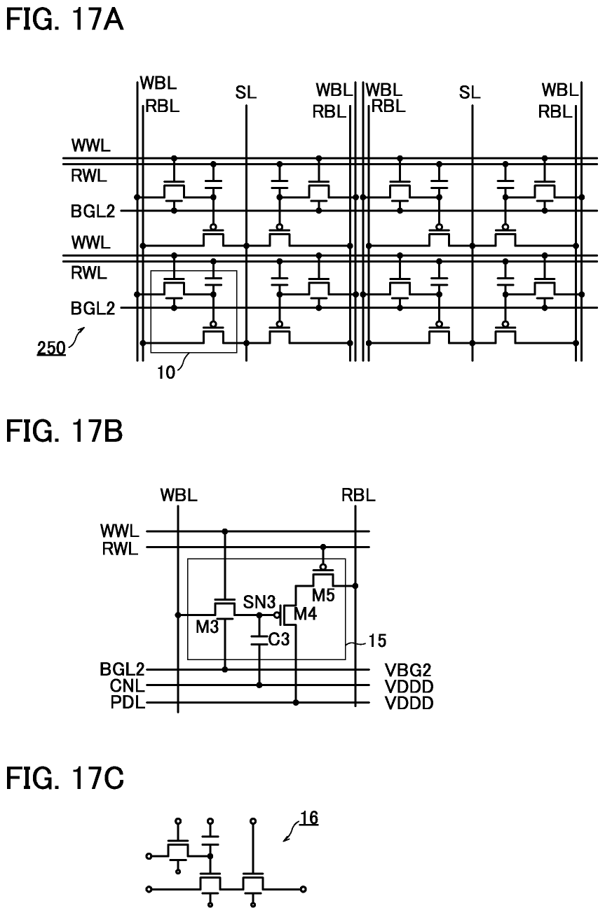

FIG. 17A shows a structure example of the memory cell array 250. In the memory cell array 250 illustrated in FIG. 17, one source line is supplied to the adjacent two rows.

The memory cell 11 does not have a limitation on the number of rewriting times in principle, can perform data rewriting with low energy, and does not consume power in retaining data. Since the transistor M1 is an OS transistor with an extremely low off-state current, the memory cell 11 can retain data for a long time. Thus, when a cache is formed using the NOSRAM 240, the low-power-consumption nonvolatile cache can be obtained.

The circuit structure of the memory cell 11 is not limited to the circuit structure in FIG. 16B. For example, the read transistor M2 may be an OS transistor having a back gate or an n-channel Si transistor. Alternatively, the memory cell 11 may be a 3T gain cell. For example, FIG. 17B and FIG. 17C show examples of a 3T gain cell. A memory cell 15 illustrated in FIG. 17B includes transistors M3 to M5, a capacitor C3, and a node SN3. The transistors M3 to M5 are a write transistor, a read transistor, and a selection transistor, respectively. The transistor M3 is an OS transistor having a back gate, and the transistors M4 and M5 are p-channel Si transistors. The transistors M4 and M5 may each be an n-channel Si transistor or an OS transistor having a back gate. In a memory cell 16 illustrated in FIG. 17C, three transistors are OS transistors each having a back gate.

The node SN3 is a retention node. The capacitor C3 is a storage capacitor for retaining the voltage of the node SN3. The capacitor C3 may be omitted intentionally, and the storage capacitor may be formed using gate capacitance of the transistor M4, or the like. A fixed voltage (e.g., VDDD) is input to a wiring PDL. The wiring PDL is an alternative to the source line SL, and for example, the voltage VDDD is input.

The control circuit 251 has a function of controlling the entire operation of the NOSRAM 240. For example, the control circuit 251 performs a logical operation of the signals CE and WE to determine whether access from the outside is write access or read access.

The row circuit 252 has a function of selecting the write word line WWL and the read word line in the row selected and specified by the address signal. The column circuit 253 has a function of writing data to the write bit line in the column specified by the address signal and a function of reading out data from the read bit line WBL in the column.

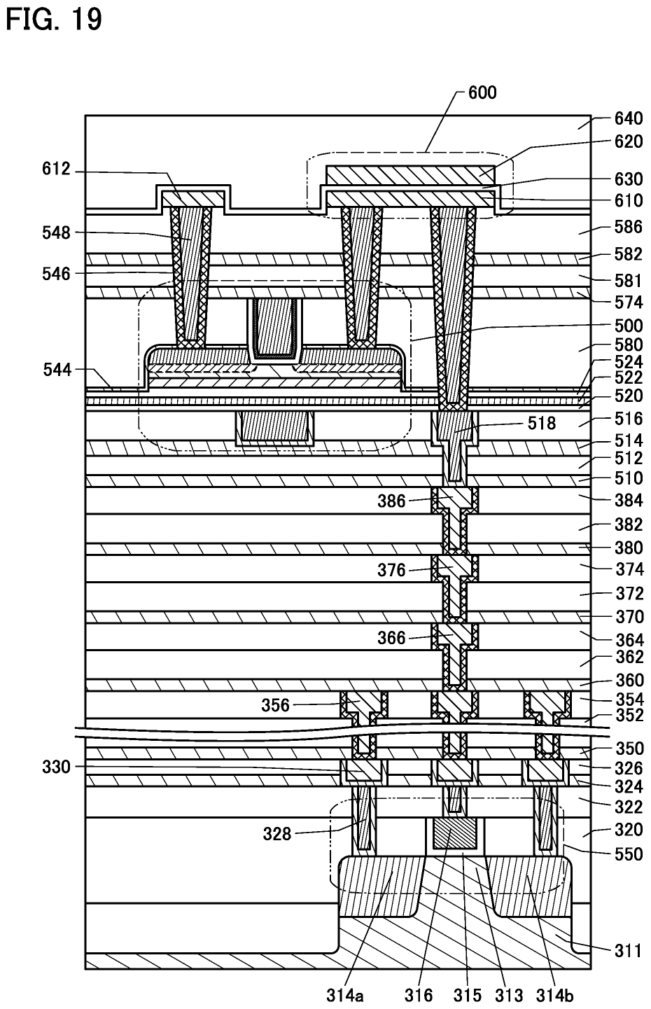

A DOSRAM refers to a RAM including a 1T1C memory cell and is an abbreviation for Dynamic Oxide Semiconductor RAM. A DOSRAM is described below with reference to FIG. 19.

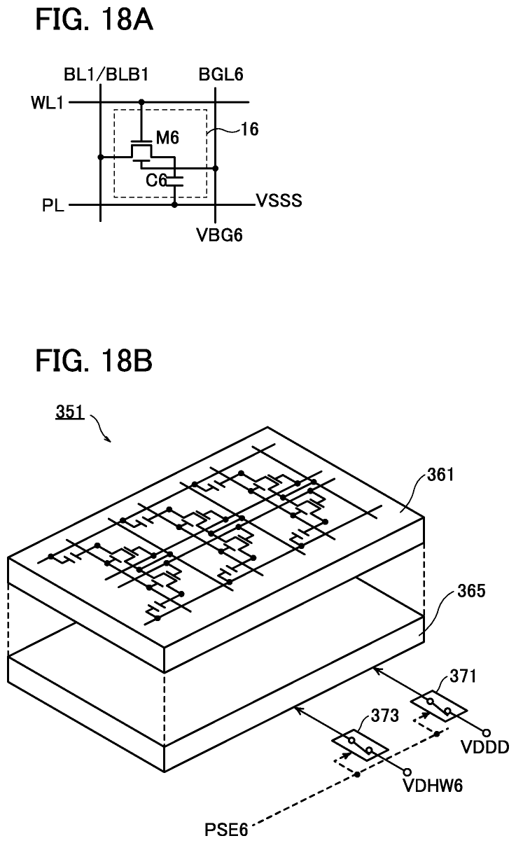

As illustrated in FIG. 18A, the memory cell 16 of a DOSRAM 351 is electrically connected to a bit line BL1 (or BLB1), a word line WL1, a wiring BGL6, and a wiring PL. The bit line BLB1 is an inverted bit line. For example, a voltage VBG6 and a voltage VSSS are input to the wiring BGL6 and the wiring PL, respectively. The memory cell 16 includes a transistor M6 and a capacitor C6. The transistor M6 is an OS transistor having a back gate.

There is no limitation on the number of rewriting operations of the DOSRAM 351 in principle because data is rewritten by charging and discharging of the capacitor C6; and data can be written and read out with low energy. In addition, the memory cell 16 has a simple circuit structure, and thus the capacity can be easily increased. Since the write transistor of the memory cell 16 is an OS transistor, the retention time of the DOSRAM 351 is significantly longer than that of a DRAM. This allows less frequent refresh or makes refresh operations unnecessary; thus, the power needed for refresh operations can be reduced.

As illustrated in FIG. 18B, in the DOSRAM 351, a memory cell array 361 can be stacked over a peripheral circuit 365. This is because the transistor M6 of the memory cell 16 is an OS transistor.

In the memory cell array 361, a plurality of memory cells 16 are arranged in a matrix, and the bit lines BL1 and BLB1, the word line WL1, and the wirings BGL6 and PL are provided according to the arrangement of the memory cells 16. A control circuit, a row circuit, and a column circuit are provided in the peripheral circuit 365. The row circuit selects the word line WL1 that is to be accessed, for example. The column circuit performs writing and reading out of data to and from a bit line pair formed of BL1 and BLB1, for example.

A power switch 371 and a power switch 373 are provided in order to power gate the peripheral circuit 365. The power switch 371 and the power switch 373 control the input of the voltage VDDD and a voltage VDHW6, respectively, to the peripheral circuit 365. Note that the voltage VDHW6 is a high-level voltage for the word line WL1. On/off of the power switch 371 and the power switch 373 is controlled with a signal PSE6.

This embodiment can be implemented in appropriate combination with the other embodiments.

### Embodiment 5

In this embodiment, a structure example of a semiconductor device of one embodiment of the present invention is described.

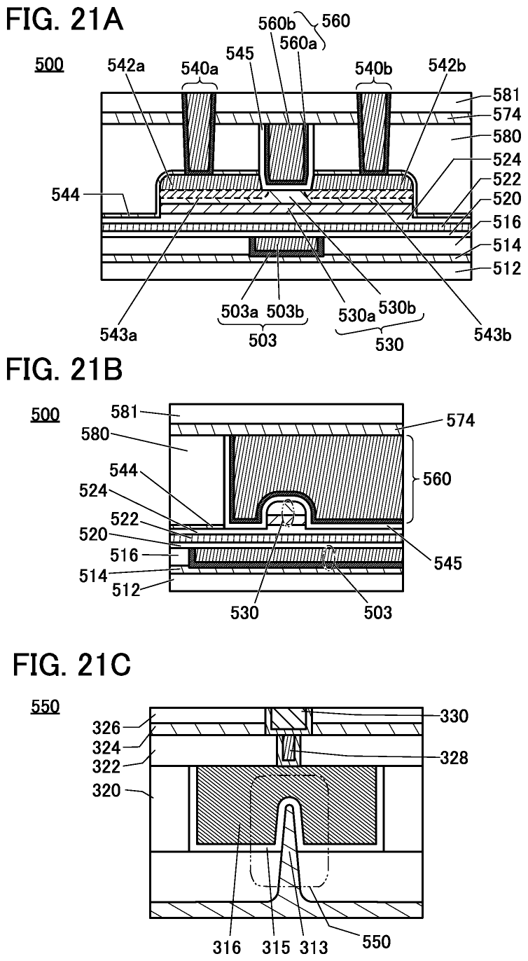

FIG. 19 shows part of a cross-sectional structure of a semiconductor device. A semiconductor device illustrated in FIG. 19 includes a transistor 550, a transistor 500, and a capacitor 600. FIG. 21A is a cross-sectional view of the transistor 500 in the channel length direction, FIG. 21B is a cross-sectional view of the transistor 500 in the channel width direction, and FIG. 21C is a cross-sectional view of the transistor 550 in the channel width direction.

The transistor 500 is an OS transistor. The transistor 500 has an extremely low off-state current. Accordingly, data voltage or charge written to a storage node through the transistor 500 can be retained for a long time. In other words, power consumption of the semiconductor device can be reduced because a storage node has a low frequency of refresh operation or requires no refresh operation.

In FIG. 19, the transistor 500 is provided above the transistor 550, and the capacitor 600 is provided above the transistor 550 and the transistor 500.

The transistor 550 is provided over a substrate 311 and includes a conductor 316, an insulator 315, a semiconductor region 313 that is part of the substrate 311, and a low-resistance region 314a and a low-resistance region 314b each functioning as a source region or a drain region.

As illustrated in FIG. 21C, in the transistor 550, a top surface and a side surface in the channel width direction of the semiconductor region 313 are covered with the conductor 316 with the insulator 315 therebetween. Such a Fin-type transistor 550 can have an increased effective channel width, and thus have improved on-state characteristics. In addition, since contribution of an electric field of a gate electrode can be increased, the off-state characteristics of the transistor 550 can be improved.

Note that the transistor 550 can be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably contain a semiconductor such as a silicon-based semiconductor, and preferably contain single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and changing the lattice spacing is used. Alternatively, the transistor 550 may be a HEMT with GaAs and GaAlAs, or the like.

The low-resistance region 314a and the low-resistance region 314b contain an element which imparts n-type conductivity, such as arsenic or phosphorus, or an element which imparts p-type conductivity, such as boron, in addition to the semiconductor material used for the semiconductor region 313.

For the conductor 316 functioning as a gate electrode, a semiconductor material such as silicon containing the element which imparts n-type conductivity, such as arsenic or phosphorus, or the element which imparts p-type conductivity, such as boron, or a conductive material such as a metal material, an alloy material, or a metal oxide material can be used.

Note that since the work function of a conductor depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

The transistor 550 may be formed using an SOI (Silicon on Insulator) substrate, for example.

As the SOI substrate, the following substrate may be used: an SIMOX (Separation by Implanted Oxygen) substrate which is formed in such a manner that after an oxygen ion is implanted into a mirror-polished wafer, an oxide layer is formed at a certain depth from the surface and defects generated in a surface layer are eliminated by high-temperature annealing; or an SOI substrate formed by using a Smart-Cut method in which a semiconductor substrate is cleaved by utilizing growth of a minute void, which is formed by implantation of a hydrogen ion, due to thermal treatment, by using an ELTRAN method (a registered trademark: Epitaxial Layer Transfer), or the like. A transistor formed using a single crystal substrate contains a single crystal semiconductor in a channel formation region.

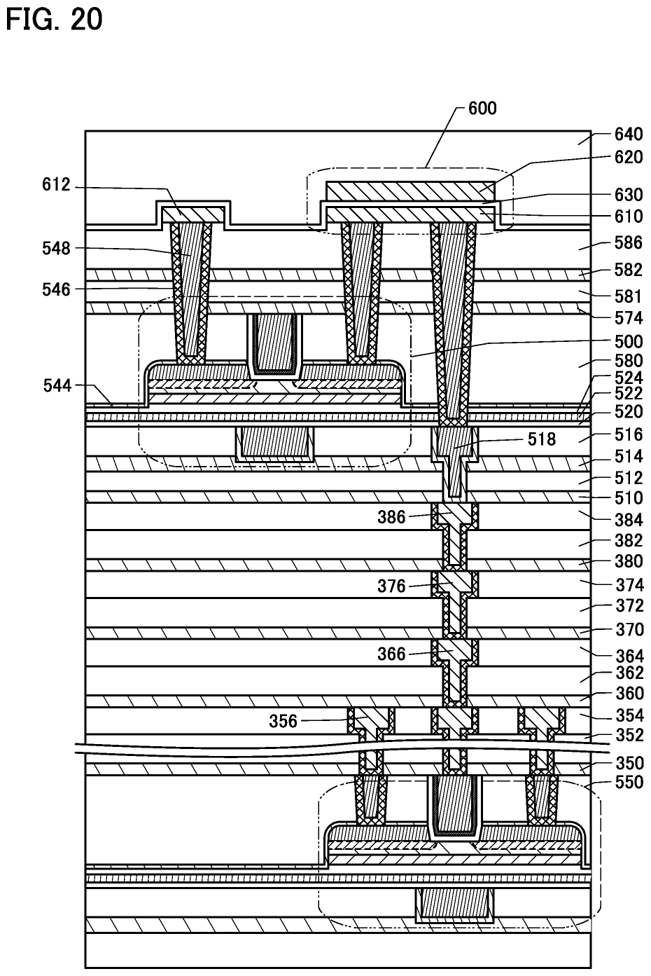

Note that the transistor 550 illustrated in FIG. 19 is an example and the structure is not limited thereto; an appropriate transistor can be used in accordance with a circuit structure or a driving method. For example, when the semiconductor device is a single-polarity circuit using only OS transistors (which represent transistors having the same polarity, e.g., only n-channel transistors), the transistor 550 has a structure similar to the structure of the transistor 500 as illustrated in FIG. 20. Note that the details of the transistor 500 are described later.

An insulator 320, an insulator 322, an insulator 324, and an insulator 326 are stacked sequentially to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that contains oxygen at a higher proportion than nitrogen, and silicon nitride oxide refers to a material that contains nitrogen at a higher proportion than oxygen. Furthermore, in this specification, aluminum oxynitride refers to a material that contains oxygen at a higher proportion than nitrogen, and aluminum nitride oxide refers to a material that contains nitrogen at a higher proportion than oxygen.

The insulator 322 may have a function of a planarization film for eliminating a level difference caused by the transistor 550 or the like provided below the insulator 322. For example, a top surface of the insulator 322 may be planarized by planarization treatment using a chemical mechanical polishing (CMP) method or the like to increase planarity.

In addition, for the insulator 324, it is preferable to use a film having a barrier property that prevents diffusion of hydrogen or impurities from the substrate 311, the transistor 550, or the like into a region where the transistor 500 is provided.

For the film having a barrier property against hydrogen, silicon nitride formed using a CVD method can be used, for example. Here, diffusion of hydrogen to a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. The film that inhibits hydrogen diffusion is specifically a film from which a small amount of hydrogen is released.

The amount of released hydrogen can be analyzed by thermal desorption spectroscopy (TDS) or the like, for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm², in the TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 times or less, further preferably 0.6 times or less the relative permittivity of the insulator 324. When a material with a low permittivity is used for an interlayer film, parasitic capacitance generated between wirings can be reduced.

In addition, a conductor 328, a conductor 330, and the like that are connected to the capacitor 600 or the transistor 500 are embedded in the insulator 320, the insulator 322, the insulator 324, and the insulator 326. Note that the conductor 328 and the conductor 330 each have a function of a plug or a wiring. Furthermore, a plurality of conductors functioning as plugs or wirings are collectively denoted by the same reference numeral in some cases. Moreover, in this specification and the like, a wiring and a plug connected to the wiring may be a single component. That is, there are cases where part of a conductor functions as a wiring and part of a conductor functions as a plug.

As a material for each of the plugs and wirings (the conductor 328, the conductor 330, and the like), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, it is preferable to form the plugs and wirings with a low-resistance conductive material such as aluminum or copper. The use of a low-resistance conductive material can reduce wiring resistance.

A wiring layer may be provided over the insulator 326 and the conductor 330. For example, in FIG. 19, an insulator 350, an insulator 352, and an insulator 354 are provided to be stacked in this order. Furthermore, a conductor 356 is formed in the insulator 350, the insulator 352, and the insulator 354. The conductor 356 has a function of a plug or a wiring that is connected to the transistor 550. Note that the conductor 356 can be provided using a material similar to those for the conductor 328 and the conductor 330.

Note that for example, as the insulator 350, like the insulator 324, an insulator having a barrier property against hydrogen is preferably used. Furthermore, the conductor 356 preferably contains a conductor having a barrier property against hydrogen. In particular, the conductor having a barrier property against hydrogen is formed in an opening of the insulator 350 having a barrier property against hydrogen. With this structure, the transistor 550 and the transistor 500 can be separated by a barrier layer, so that diffusion of hydrogen from the transistor 550 into the transistor 500 can be inhibited.

Note that for the conductor having a barrier property against hydrogen, tantalum nitride is preferably used, for example. In addition, by stacking tantalum nitride and tungsten, which has high conductivity, the diffusion of hydrogen from the transistor 550 can be inhibited while the conductivity as a wiring is kept. In that case, a structure in which a tantalum nitride layer having a barrier property against hydrogen is in contact with the insulator 350 having a barrier property against hydrogen is preferable.

A wiring layer may be provided over the insulator 354 and the conductor 356. For example, in FIG. 19, an insulator 360, an insulator 362, and an insulator 364 are provided to be stacked in this order. Furthermore, a conductor 366 is formed in the insulator 360, the insulator 362, and the insulator 364. The conductor 366 has a function of a plug or a wiring. Note that the conductor 366 can be provided using a material similar to those for the conductor 328 and the conductor 330.

Note that for example, as the insulator 360, like the insulator 324, an insulator having a barrier property against hydrogen is preferably used. Furthermore, the conductor 366 preferably contains a conductor having a barrier property against hydrogen. In particular, the conductor having a barrier property against hydrogen is formed in an opening of the insulator 360 having a barrier property against hydrogen. With this structure, the transistor 550 and the transistor 500 can be separated by a barrier layer, so that diffusion of hydrogen from the transistor 550 into the transistor 500 can be inhibited.

A wiring layer may be provided over the insulator 364 and the conductor 366. For example, in FIG. 19, an insulator 370, an insulator 372, and an insulator 374 are provided to be stacked in this order. Furthermore, a conductor 376 is formed in the insulator 370, the insulator 372, and the insulator 374. The conductor 376 has a function of a plug or a wiring. Note that the conductor 376 can be provided using a material similar to those for the conductor 328 and the conductor 330.

Note that for example, as the insulator 370, like the insulator 324, an insulator having a barrier property against hydrogen is preferably used. Furthermore, the conductor 376 preferably contains a conductor having a barrier property against hydrogen. In particular, the conductor having a barrier property against hydrogen is formed in an opening of the insulator 370 having a barrier property against hydrogen. With this structure, the transistor 550 and the transistor 500 can be separated by a barrier layer, so that diffusion of hydrogen from the transistor 550 into the transistor 500 can be inhibited.

A wiring layer may be provided over the insulator 374 and the conductor 376. For example, in FIG. 19, an insulator 380, an insulator 382, and an insulator 384 are provided to be stacked in this order. Furthermore, a conductor 386 is formed in the insulator 380, the insulator 382, and the insulator 384. The conductor 386 has a function of a plug or a wiring. Note that the conductor 386 can be provided using a material similar to those for the conductor 328 and the conductor 330.

Note that for example, as the insulator 380, like the insulator 324, an insulator having a barrier property against hydrogen is preferably used. Furthermore, the conductor 386 preferably contains a conductor having a barrier property against hydrogen. In particular, the conductor having a barrier property against hydrogen is formed in an opening of the insulator 380 having a barrier property against hydrogen. With this structure, the transistor 550 and the transistor 500 can be separated by a barrier layer, so that diffusion of hydrogen from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device of this embodiment is not limited thereto. Three or less wiring layers that are similar to the wiring layer including the conductor 356 may be provided, or five or more wiring layers that are similar to the wiring layer including the conductor 356 may be provided.

An insulator 510, an insulator 512, an insulator 514, and an insulator 516 are stacked sequentially over the insulator 384. A substance having a barrier property against oxygen or hydrogen is preferably used for any of the insulator 510, the insulator 512, the insulator 514, and the insulator 516.

For example, for the insulator 510 and the insulator 514, it is preferable to use a film having a barrier property against hydrogen or impurities diffused from the substrate 311, a region where the transistor 550 is provided, or the like into the region where the transistor 500 is provided. Therefore, a material similar to that for the insulator 324 can be used.

For the film having a barrier property against hydrogen, silicon nitride formed using a CVD method can be used, for example. Here, diffusion of hydrogen to a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550.

In addition, for the film having a barrier property against hydrogen, a metal oxide such as aluminum oxide, hafnium oxide, or tantalum oxide is preferably used for the insulator 510 and the insulator 514, for example.

In particular, aluminum oxide has an excellent blocking effect that prevents the passage of both oxygen and impurities such as hydrogen or moisture which are factors of change in electrical characteristics of the transistor. Accordingly, aluminum oxide can prevent mixing of impurities such as hydrogen or moisture into the transistor 500 in the manufacturing process and after the manufacturing of the transistor. In addition, release of oxygen from the oxide included in the transistor 500 can be inhibited. Therefore, aluminum oxide is suitably used for the protective film of the transistor 500.

In addition, for the insulator 512 and the insulator 516, a material similar to that for the insulator 320 can be used, for example. Furthermore, when a material with a comparatively low permittivity is used for these insulators, parasitic capacitance generated between wirings can be reduced. A silicon oxide film, a silicon oxynitride film, or the like can be used for the insulator 512 and the insulator 516, for example.

Furthermore, a conductor 518, a conductor included in the transistor 500 (a conductor 503 for example), and the like are embedded in the insulator 510, the insulator 512, the insulator 514, and the insulator 516. Note that the conductor 518 has a function of a plug or a wiring that is connected to the capacitor 600 or the transistor 550. The conductor 518 can be provided using a material similar to those for the conductor 328 and the conductor 330.

In particular, the conductor 518 in a region in contact with the insulator 510 and the insulator 514 is preferably a conductor having a barrier property against oxygen, hydrogen, and water. With this structure, the transistor 550 and the transistor 500 can be separated by a layer having a barrier property against oxygen, hydrogen, and water; thus, diffusion of hydrogen from the transistor 550 into the transistor 500 can be inhibited.

The transistor 500 is provided above the insulator 516.

As illustrated in FIG. 21A and FIG. 21B, the transistor 500 includes the conductor 503 positioned to be embedded in the insulator 514 and the insulator 516; an insulator 520 positioned over the insulator 516 and the conductor 503; an insulator 522 positioned over the insulator 520; an insulator 524 positioned over the insulator 522; an oxide 530a positioned over the insulator 524; an oxide 530b positioned over the oxide 530a; a conductor 542a and a conductor 542b positioned apart from each other over the oxide 530b; an insulator 580 that is positioned over the conductor 542a and the conductor 542b and is provided with an opening formed to overlap with a region between the conductor 542a and the conductor 542b; an insulator 545 positioned on a bottom surface and a side surface of an opening; and a conductor 560 positioned on a formation surface of the insulator 545.

In addition, as illustrated in FIG. 21A and FIG. 21B, an insulator 544 is preferably positioned between the insulator 580 and the oxide 530a, the oxide 530b, the conductor 542a, and the conductor 542b. Furthermore, as illustrated in FIG. 21A and FIG. 21B, the conductor 560 preferably includes a conductor 560a provided on an inner side than the insulator 545 and a conductor 560b provided to be embedded on the inner side of the conductor 560a. Moreover, as illustrated in FIG. 21A and FIG. 21B, an insulator 574 is preferably positioned over the insulator 580, the conductor 560, and the insulator 545.

Note that in this specification and the like, the oxide 530a and the oxide 530b are sometimes collectively referred to as an oxide 530.

Note that although a structure of the transistor 500 in which two layers of the oxide 530a and the oxide 530b are stacked in a region where a channel is formed and its vicinity is illustrated, the present invention is not limited thereto. For example, it is possible to employ a structure in which a single layer of the oxide 530b or a stacked-layer structure of three or more layers is provided.

Furthermore, although the conductor 560 is illustrated to have a stacked-layer structure of two layers in the transistor 500, the present invention is not limited thereto. For example, the conductor 560 may have a single-layer structure or a stacked-layer structure of three or more layers. Note that the transistors 500 illustrated in FIG. 19, FIG. 20, and FIG. 21A are examples, and the structures are not limited thereto; an appropriate transistor can be used in accordance with a circuit structure, a driving method, or the like.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Therefore, the conductor 560 can be formed without an alignment margin, resulting in a reduction in the area occupied by the transistor 500. Accordingly, miniaturization and high integration of the semiconductor device can be achieved.

In addition, since the conductor 560 is formed in the region between the conductor 542a and the conductor 542b in a self-aligned manner, the conductor 560 does not have a region overlapping with the conductor 542a or the conductor 542b. Thus, parasitic capacitance formed between the conductor 560 and each of the conductor 542a and the conductor 542b can be reduced. As a result, the switching speed of the transistor 500 can be improved, and the transistor 500 can have high frequency characteristics.

The conductor 560 functions as a first gate (also referred to as top gate) electrode in some cases. The conductor 503 functions as a second gate (also referred to as bottom gate) electrode in some cases. In that case, the threshold voltage of the transistor 500 can be controlled by changing a potential applied to the conductor 503 independently of a potential applied to the conductor 560. In particular, the threshold voltage of the transistor 500 can be higher and the off-state current can be reduced by applying a negative potential to the conductor 503. Thus, a drain current at the time when a potential applied to the conductor 560 is 0 V can be lower in the case where a negative potential is applied to the conductor 503 than in the case where a negative potential is not applied to the conductor 503.

The conductor 503 is positioned to overlap with the oxide 530 and the conductor 560. Thus, in the case where potentials are applied to the conductor 560 and the conductor 503, an electric field generated from the conductor 560 and an electric field generated from the conductor 503 are connected, so that a channel formation region formed in the oxide 530 can be covered.

In this specification and the like, a transistor structure in which a channel formation region is electrically surrounded by electric fields of a pair of gate electrodes (a first gate electrode and a second gate electrode) is referred to as a surrounded channel (S-channel) structure. The S-channel structure disclosed in this specification and the like is different from a Fin-type structure and a planar structure. With the S-channel structure, resistance to a short-channel effect can be enhanced, that is, a transistor in which a short-channel effect is unlikely to occur can be provided.

In addition, the conductor 503 has a structure similar to that of the conductor 518; a conductor 503a is formed in contact with an inner wall of an opening in the insulator 514 and the insulator 516, and a conductor 503b is formed on the inner side. Note that although the transistor 500 having a structure in which the conductor 503a and the conductor 503b are stacked is illustrated, the present invention is not limited thereto. For example, the conductor 503 may be provided as a single layer or to have a stacked-layer structure of three or more layers.

Here, for the conductor 503a, a conductive material that has a function of inhibiting diffusion of impurities such as a hydrogen atom, a hydrogen molecule, a water molecule, and a copper atom (through which the impurities are unlikely to pass) is preferably used. Alternatively, it is preferable to use a conductive material that has a function of inhibiting diffusion of oxygen (e.g., at least one of an oxygen atom, an oxygen molecule, and the like) (through which oxygen is unlikely to pass). Note that in this specification, a function of inhibiting diffusion of impurities or oxygen means a function of inhibiting diffusion of any one or all of the impurities and oxygen.

For example, when the conductor 503a has a function of inhibiting diffusion of oxygen, a reduction in conductivity of the conductor 503b due to oxidation can be inhibited.

In addition, in the case where the conductor 503 also functions as a wiring, a conductive material with high conductivity that contains tungsten, copper, or aluminum as its main component is preferably used for the conductor 503b. Note that although the conductor 503 is illustrated as a stacked layer of the conductor 503a and the conductor 503b in this embodiment, the conductor 503 may have a single-layer structure.

The insulator 520, the insulator 522, and the insulator 524 have a function of a second gate insulating film.

Here, as the insulator 524 that is in contact with the oxide 530, an insulator that contains oxygen more than oxygen in the stoichiometric composition is preferably used. Such oxygen is easily released from the film by heating. In this specification and the like, oxygen released by heating is sometimes referred to as “excess oxygen”. That is, a region containing excess oxygen (also referred to as an “excess-oxygen region”) is preferably formed in the insulator 524. When such an insulator containing excess oxygen is provided in contact with the oxide 530, oxygen vacancies (V_{O}) in the oxide 530 can be reduced and the reliability of the transistor 500 can be improved. When hydrogen enters the oxygen vacancies in the oxide 530, such defects (hereinafter, referred to as V_{O}H in some cases) serve as donors and generate electrons serving as carriers in some cases. In other cases, bonding of part of hydrogen to oxygen bonded to a metal atom generates electrons serving as carriers. Thus, a transistor including an oxide semiconductor that contains a large amount of hydrogen is likely to have normally-on characteristics. Moreover, hydrogen in an oxide semiconductor is easily transferred by a stress such as heat or an electric field; thus, a large amount of hydrogen in an oxide semiconductor might reduce the reliability of the transistor. In one embodiment of the present invention, V_{O}H in the oxide 530 is preferably reduced as much as possible so that the oxide 530 becomes a highly purified intrinsic or substantially highly purified intrinsic oxide. It is important to remove impurities such as moisture or hydrogen in an oxide semiconductor (sometimes described as “dehydration” or “dehydrogenation treatment”) and to compensate for oxygen vacancies by supplying oxygen to the oxide semiconductor (sometimes described as “oxygen adding treatment”) in order to obtain an oxide semiconductor whose V_{O}H is sufficiently reduced. When an oxide semiconductor with sufficiently reduced impurities such as V_{O}H is used for a channel formation region of a transistor, the transistor can have stable electrical characteristics.

As the insulator including an excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of 100° C. to 700° C., or 100° C. to 400° C.

One or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when a reaction in which a bond of V_{O}H is cut occurs, i.e., a reaction of V_{O}H→V_{O}+H occurs. Part of hydrogen generated at this time is bonded to oxygen to be H₂O, and removed from the oxide 530 or an insulator near the oxide 530 in some cases. Some hydrogen may be gettered into the conductor 542 in some cases.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The pressure in the microwave treatment is higher than or equal to 133 Pa, preferably higher than or equal to 200 Pa, further preferably higher than or equal to 400 Pa. As a gas introduced into an apparatus for performing the microwave treatment, for example, oxygen and argon are used and the oxygen flow rate (O₂/(O₂+Ar)) is lower than or equal to 50%, preferably higher than or equal to 10% and lower than or equal to 30%.

In a manufacturing process of the transistor 500, heat treatment is preferably performed with the surface of the oxide 530 exposed. The heat treatment is performed at higher than or equal to 100° C. and lower than or equal to 450° C., preferably higher than or equal to 350° C. and lower than or equal to 400° C., for example. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 530 to reduce oxygen vacancies (V_{O}). The heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at 10 ppm or more, 1% or more, or 10% or more in order to compensate for released oxygen. Alternatively, the heat treatment may be performed in such a manner that heat treatment is performed in an atmosphere containing an oxidizing gas at 10 ppm or more, 1% or more, or 10% or more, and then another heat treatment is successively performed in a nitrogen gas or inert gas atmosphere.

Note that the oxygen adding treatment performed on the oxide 530 can promote a reaction in which oxygen vacancies in the oxide 530 are filled with supplied oxygen, i.e., a reaction of “V_{O}+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of V_{O}H.

In addition, in the case where the insulator 524 includes an excess-oxygen region, it is preferable that the insulator 522 have a function of inhibiting diffusion of oxygen (e.g., an oxygen atom, an oxygen molecule, or the like) (or that the above oxygen be less likely to pass through the insulator 522).

When the insulator 522 has a function of inhibiting diffusion of oxygen or impurities, oxygen contained in the oxide 530 is not diffused into the insulator 520 side, which is preferable. Furthermore, the conductor 503 can be inhibited from reacting with oxygen contained in the insulator 524 or the oxide 530.

For the insulator 522, a single layer or stacked layers of an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and high integration of transistors progress, a problem such as leakage current might arise because of a thinner gate insulating film. When a high-k material is used for an insulator functioning as the gate insulating film, a gate potential during transistor operation can be reduced while the physical thickness is maintained.

It is particularly preferable to use an insulator containing an oxide of one or both of aluminum and hafnium, which is an insulating material having a function of inhibiting diffusion of impurities, oxygen, and the like (through which oxygen is unlikely to pass). Aluminum oxide, hafnium oxide, an oxide containing aluminum and hafnium (hafnium aluminate), or the like is preferably used as the insulator containing an oxide of one or both of aluminum and hafnium. In the case where the insulator 522 is formed using such a material, the insulator 522 functions as a layer that inhibits release of oxygen from the oxide 530 and mixing of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. The insulator over which silicon oxide, silicon oxynitride, or silicon nitride is stacked may be used.

In addition, it is preferable that the insulator 520 be thermally stable. For example, silicon oxide and silicon oxynitride are suitable because they are thermally stable. Furthermore, the combination of an insulator that is a high-k material and silicon oxide or silicon oxynitride enables the insulator 520 to have a stacked-layer structure that has thermal stability and a high dielectric constant.

Note that in the transistor 500 in FIG. 21A and FIG. 21B, the insulator 520, the insulator 522, and the insulator 524 are illustrated as the second gate insulating film having a stacked-layer structure of three layers; however, the second gate insulating film may be a single layer or may have a stacked-layer structure of two layers or four or more layers. In such cases, without limitation to a stacked-layer structure formed of the same material, a stacked-layer structure formed of different materials may be employed.

In the transistor 500, a metal oxide functioning as an oxide semiconductor is used as the oxide 530 including a channel formation region. For example, as the oxide 530, a metal oxide such as an In-M-Zn oxide (the element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used.

The metal oxide functioning as an oxide semiconductor may be formed by a sputtering method or an ALD (Atomic Layer Deposition) method. Note that the metal oxide functioning as an oxide semiconductor will be described in detail in another embodiment.

The metal oxide functioning as the channel formation region in the oxide 530 has a band gap that is preferably 2 eV or higher, further preferably 2.5 eV or higher. With use of a metal oxide having such a wide band gap, the off-state current of the transistor can be reduced.

When the oxide 530 includes the oxide 530a under the oxide 530b, it is possible to inhibit diffusion of impurities into the oxide 530b from the components formed below the oxide 530a.

Note that the oxide 530 preferably has a stacked-layer structure of a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element M in the metal oxide used as the oxide 530b is preferably higher than the atomic ratio of In to the element M in the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gently changes at a junction portion between the oxide 530a and the oxide 530b. In other words, the energy level of the conduction band minimum at the junction portion between the oxide 530a and the oxide 530b continuously changes or is continuously connected. This can be obtained by decreasing the density of defect states in a mixed layer formed at the interface between the oxide 530a and the oxide 530b.

Specifically, when the oxide 530a and the oxide 530b contain a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like is used as the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing the above metal element; an alloy containing a combination of the above metal element; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

In addition, although the conductor 542a and the conductor 542b each having a single-layer structure are illustrated in FIG. 21A, a stacked-layer structure of two or more layers may be employed. For example, it is preferable to stack a tantalum nitride film and a tungsten film. Alternatively, a titanium film and an aluminum film may be stacked. Alternatively, a two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure where a titanium film or a titanium nitride film is formed, an aluminum film or a copper film is stacked over the titanium film or the titanium nitride film, and a titanium film or a titanium nitride film is formed thereover; and a three-layer structure where a molybdenum film or a molybdenum nitride film is formed, an aluminum film or a copper film is stacked over the molybdenum film or the molybdenum nitride film, and a molybdenum film or a molybdenum nitride film is formed thereover. Note that a transparent conductive material containing indium oxide, tin oxide, or zinc oxide may be used.

In addition, as illustrated in FIG. 21A, a region 543a and a region 543b are sometimes formed as low-resistance regions at an interface between the oxide 530 and the conductor 542a (the conductor 542b) and in the vicinity of the interface. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that contains the metal contained in the conductor 542a (the conductor 542b) and the component of the oxide 530 is sometimes formed in the region 543a (the region 543b). In such a case, the carrier density of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. At this time, the insulator 544 may be provided to cover a side surface of the oxide 530 and to be in contact with the insulator 524.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use an insulator containing an oxide of one or both of aluminum and hafnium, such as aluminum oxide, hafnium oxide, or an oxide containing aluminum and hafnium (hafnium aluminate), as the insulator 544. In particular, hafnium aluminate has higher heat resistance than a hafnium oxide film. Therefore, hafnium aluminate is preferable because it is unlikely to be crystallized by heat treatment in a later step. Note that the insulator 544 is not an essential component when the conductor 542a and the conductor 542b are oxidation-resistant materials or do not significantly lose their conductivity even after absorbing oxygen. Design is appropriately set in consideration of required transistor characteristics.

When the insulator 544 is included, diffusion of impurities such as water and hydrogen contained in the insulator 580 into the oxide 530b through the insulator 545 can be inhibited. Furthermore, oxidation of the conductor 560 due to excess oxygen contained in the insulator 580 can be inhibited.

The insulator 545 functions as a first gate insulating film. Like the insulator 524, the insulator 545 is preferably formed using an insulator that contains excess oxygen and releases oxygen by heating.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable.

When an insulator containing excess oxygen is provided as the insulator 545, oxygen can be effectively supplied from the insulator 545 to the channel formation region of the oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen contained in the insulator 545 to the oxide 530, a metal oxide may be provided between the insulator 545 and the conductor 560. The metal oxide preferably inhibits diffusion of oxygen from the insulator 545 to the conductor 560. Providing the metal oxide that inhibits diffusion of oxygen inhibits diffusion of excess oxygen from the insulator 545 to the conductor 560. That is, reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as leakage current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have a high relative permittivity.

Although the conductor 560 that functions as the first gate electrode and has a two-layer structure is illustrated in FIG. 21A and FIG. 21B, a single-layer structure or a stacked-layer structure of three or more layers may be employed.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation caused by oxygen contained in the insulator 545. As a conductive material having a function of inhibiting diffusion of oxygen, for example, tantalum, tantalum nitride, ruthenium, ruthenium oxide, or the like is preferably used. For the conductor 560a, the oxide semiconductor that can be used as the oxide 530 can be used. In that case, when the conductor 560b is deposited by a sputtering method, the conductor 560a can have a reduced electrical resistance value to be a conductor. Such a conductor can be referred to as an OC (Oxide Conductor) electrode.

In addition, a conductive material containing tungsten, copper, or aluminum as its main component is preferably used for the conductor 560b. Furthermore, the conductor 560b also functions as a wiring and thus a conductor having high conductivity is preferably used as the conductor 560b. For example, a conductive material containing tungsten, copper, or aluminum as its main component can be used. The conductor 560b may have a stacked-layer structure, for example, a stacked-layer structure of any of the above conductive materials and titanium or titanium nitride.

The insulator 580 is provided over the conductor 542a and the conductor 542b with the insulator 544 therebetween. The insulator 580 preferably includes an excess-oxygen region. For example, the insulator 580 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with a top surface of the insulator 580, a top surface of the conductor 560, and a top surface of the insulator 545. When the insulator 574 is deposited using a sputtering method, excess-oxygen regions can be provided in the insulator 545 and the insulator 580. Accordingly, oxygen can be supplied from the excess-oxygen regions to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used for the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

In addition, an insulator 581 functioning as an interlayer film is preferably provided over the insulator 574. As in the insulator 524 or the like, the concentration of impurities such as water or hydrogen in the insulator 581 is preferably reduced.

Furthermore, a conductor 540a and a conductor 540b are positioned in openings formed in the insulator 581, the insulator 574, the insulator 580, and the insulator 544. The conductor 540a and the conductor 540b are provided to face each other with the conductor 560 therebetween. The structures of the conductor 540a and the conductor 540b are similar to a structure of a conductor 546 and a conductor 548 that will be described later.

An insulator 582 is provided over the insulator 581. A substance having a barrier property against oxygen or hydrogen is preferably used for the insulator 582. Therefore, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents the passage of both oxygen and impurities such as hydrogen or moisture which are factors of change in electrical characteristics of the transistor. Accordingly, aluminum oxide can prevent mixing of impurities such as hydrogen or moisture into the transistor 500 in the manufacturing process and after the manufacturing of the transistor. In addition, release of oxygen from the oxide included in the transistor 500 can be inhibited. Therefore, aluminum oxide is suitably used for the protective film of the transistor 500.

In addition, an insulator 586 is provided over the insulator 582. For the insulator 586, a material similar to that for the insulator 320 can be used. Furthermore, when a material with a comparatively low permittivity is used for these insulators, parasitic capacitance generated between wirings can be reduced. A silicon oxide film, a silicon oxynitride film, or the like can be used for the insulator 586, for example.

Furthermore, the conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have functions of plugs or wirings that are connected to the capacitor 600, the transistor 500, or the transistor 550. The conductor 546 and the conductor 548 can be provided using materials similar to those for the conductor 328 and the conductor 330.

After the transistor 500 is formed, an opening may be formed to surround the transistor 500 and an insulator having a high barrier property against hydrogen or water may be formed to cover the opening. Surrounding the transistor 500 with the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, the formation of an opening reaching the insulator 522 or the insulator 514 and the formation of the insulator having a high barrier property in contact with the insulator 522 or the insulator 514 are suitable because these formation steps can also serve as part of the manufacturing steps of the transistor 500. The insulator having a high barrier property against hydrogen or water is formed using a material similar to that for the insulator 522 or the insulator 514, for example.

Next, the capacitor 600 is provided above the transistor 500. The capacitor 600 includes a conductor 610, a conductor 620, and an insulator 630.

In addition, a conductor 612 may be provided over the conductor 546 and the conductor 548. The conductor 612 has a function of a plug or a wiring that is connected to the transistor 500. The conductor 610 has a function of an electrode of the capacitor 600. Note that the conductor 612 and the conductor 610 can be formed at the same time.

For the conductor 612 and the conductor 610, a metal film containing an element selected from molybdenum, titanium, tantalum, tungsten, aluminum, copper, chromium, neodymium, and scandium; a metal nitride film containing the above element as its component (a tantalum nitride film, a titanium nitride film, a molybdenum nitride film, or a tungsten nitride film); or the like can be used. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

Although the conductor 612 and the conductor 610 each having a single-layer structure are described in this embodiment, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap with the conductor 610 with the insulator 630 therebetween. Note that a conductive material such as a metal material, an alloy material, or a metal oxide material can be used for the conductor 620. It is preferable to use a high-melting-point material that has both heat resistance and conductivity, such as tungsten or molybdenum, and it is particularly preferable to use tungsten. In addition, in the case where the conductor 620 is formed concurrently with another component such as a conductor, Cu (copper), Al (aluminum), or the like, which is a low-resistance metal material, is used.

An insulator 640 is provided over the conductor 620 and the insulator 630. The insulator 640 can be provided using a material similar to that for the insulator 320. In addition, the insulator 640 may function as a planarization film that covers an uneven shape therebelow.

With use of this structure, a semiconductor device using a transistor including an oxide semiconductor can be miniaturized or highly integrated.

Examples of a substrate that can be used for the semiconductor device of one embodiment of the present invention include a glass substrate, a quartz substrate, a sapphire substrate, a ceramic substrate, a metal substrate (e.g., a stainless steel substrate, a substrate including stainless steel foil, a tungsten substrate, and a substrate including tungsten foil), a semiconductor substrate (e.g., a single crystal semiconductor substrate, a polycrystalline semiconductor substrate, and a compound semiconductor substrate), and an SOI (Silicon on Insulator) substrate. Alternatively, a plastic substrate having heat resistance to the processing temperature in this embodiment may be used. Examples of a glass substrate include barium borosilicate glass, aluminosilicate glass, aluminoborosilicate glass, and soda lime glass. Alternatively, crystallized glass or the like can be used.

Alternatively, a flexible substrate, an attachment film, paper including a fibrous material, a base film, or the like can be used as the substrate. As examples of the flexible substrate, the attachment film, the base material film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples are polypropylene, polyester, polyvinyl fluoride, and polyvinyl chloride. Other examples are polyamide, polyimide, an aramid resin, an epoxy resin, an inorganic vapor deposition film, paper, and the like. In particular, the use of a semiconductor substrate, a single crystal substrate, an SOI substrate, or the like enables the manufacture of small-sized transistors with a small variation in characteristics, size, shape, or the like and with high current capability. When a circuit is formed with such transistors, lower power consumption of the circuit or higher integration of the circuit can be achieved.

A flexible substrate may be used as the substrate, and a transistor, a resistor, a capacitor, and/or the like may be formed directly over the flexible substrate. Alternatively, a separation layer may be provided between the substrate and the transistor, the resistor, the capacitor, and/or the like. After part or the whole of a semiconductor device is completed over the separation layer, the separation layer can be used for separation from the substrate and transfer to another substrate. In such a case, the transistor, the resistor, the capacitor, and/or the like can be transferred to a substrate having low heat resistance or a flexible substrate. As the separation layer, a stack of inorganic films, namely a tungsten film and a silicon oxide film, an organic resin film of polyimide or the like formed over a substrate, or a silicon film containing hydrogen can be used, for example.

That is, a semiconductor device may be formed over one substrate and then transferred to another substrate. Examples of a substrate to which a semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With use of any of these substrates, a flexible semiconductor device or a highly durable semiconductor device can be manufactured, high heat resistance can be provided, or a reduction in weight or thickness can be achieved.

Providing a semiconductor device over a flexible substrate can suppress an increase in weight and can produce a non-breakable semiconductor device.

### <Modification Example 1 of Transistor>

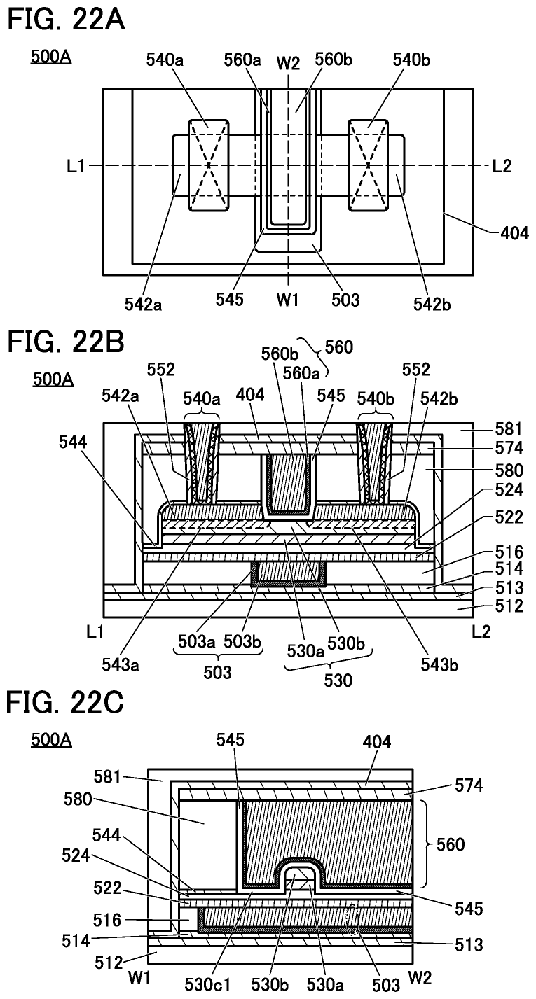

A transistor 500A illustrated in FIG. 22A, FIG. 22B, and FIG. 22C is a modification example of the transistor 500 having the structure illustrated in FIG. 21A and FIG. 21B. FIG. 22A is a top view of the transistor 500A, FIG. 22B is a cross-sectional view of the transistor 500A in the channel length direction, and FIG. 22C is a cross-sectional view of the transistor 500A in the channel width direction. Note that for clarity of the drawing, some components are not illustrated in the top view of FIG. 22A. The structure illustrated in FIG. 22A, FIG. 22B, and FIG. 22C can also be used for other transistors such as the transistor 550 included in the semiconductor device of one embodiment of the present invention.

The transistor 500A having the structure illustrated in FIG. 22A, FIG. 22B, and FIG. 22C is different from the transistor 500 having the structure illustrated in FIG. 21A and FIG. 21B in that an insulator 552, an insulator 513, and an insulator 404 are included. Furthermore, the transistor 500A is different from the transistor 500 having the structure illustrated in FIG. 21A and FIG. 21B in that the insulator 552 is provided in contact with a side surface of the conductor 540a and a side surface of the conductor 540b. Moreover, the transistor 500A is different from the transistor 500 having the structure illustrated in FIG. 21A and FIG. 21B in that the insulator 520 is not included.

In the transistor 500A having the structure illustrated in FIG. 22A, FIG. 22B, and FIG. 22C, the insulator 513 is provided over the insulator 512. The insulator 404 is provided over the insulator 574 and the insulator 513.

In the transistor 500A having the structure illustrated in FIG. 22A, FIG. 22B, and FIG. 22C, the insulator 514, the insulator 516, the insulator 522, the insulator 524, the insulator 544, the insulator 580, and the insulator 574 are patterned and covered with the insulator 404. That is, the insulator 404 is in contact with a top surface of the insulator 574, a side surface of the insulator 574, a side surface of the insulator 580, a side surface of the insulator 544, a side surface of the insulator 524, a side surface of the insulator 522, a side surface of the insulator 516, a side surface of the insulator 514, and a top surface of the insulator 513. Thus, the oxide 530 and the like are isolated from the outside by the insulator 404 and the insulator 513.

The insulator 513 and the insulator 404 preferably have high capability of inhibiting diffusion of hydrogen (e.g., at least one of a hydrogen atom, a hydrogen molecule, and the like) or a water molecule. For example, for the insulator 513 and the insulator 404, silicon nitride or silicon nitride oxide that is a material having a high hydrogen barrier property is preferably used. This can inhibit diffusion of hydrogen or the like into the oxide 530, thereby suppressing the degradation of the characteristics of the transistor 500A. Consequently, the reliability of the semiconductor device of one embodiment of the present invention can be increased.

The insulator 552 is provided in contact with the insulator 581, the insulator 404, the insulator 574, the insulator 580, and the insulator 544. The insulator 552 preferably has a function of inhibiting diffusion of hydrogen or water molecules. For example, as the insulator 552, an insulator such as silicon nitride, aluminum oxide, or silicon nitride oxide that is a material having a high hydrogen barrier property is preferably used. In particular, it is preferable to use silicon nitride as the insulator 552 because of its high hydrogen barrier property. The use of a material having a high hydrogen barrier property for the insulator 552 can inhibit diffusion of impurities such as water or hydrogen from the insulator 580 and the like into the oxide 530 through the conductor 540a and the conductor 540b. Furthermore, oxygen contained in the insulator 580 can be inhibited from being absorbed by the conductor 540a and the conductor 540b. As described above, the reliability of the semiconductor device of one embodiment of the present invention can be increased.

### <Modification Example 2 of Transistor>

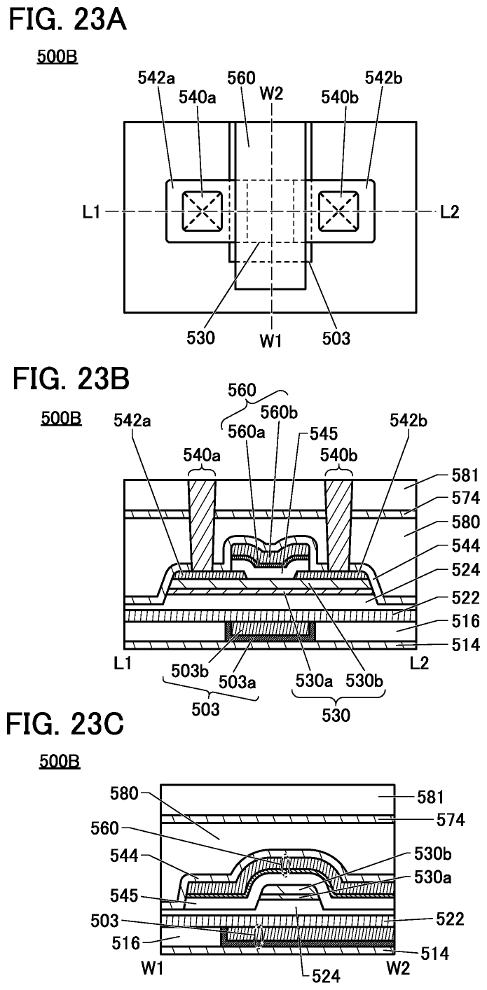

A structure example of a transistor 500B is described with reference to FIG. 23A, FIG. 23B, and FIG. 23C. FIG. 23A is a top view of the transistor 500B. FIG. 23B is a cross-sectional view of a portion indicated by dashed-dotted line L1-L2 in FIG. 23A. FIG. 23C is a cross-sectional view of a portion indicated by a dashed-dotted line W1-W2 in FIG. 23A. Note that for clarity of the drawing, some components are not illustrated in the top view of FIG. 23A.

The transistor 500B is a modification example of the transistor 500 and can be replaced with the transistor 500. Thus, differences of the transistor 500B from the transistor 500 will be mainly described to avoid repeated description.

The conductor 560 functioning as a first gate electrode includes the conductor 560a and the conductor 560b over the conductor 560a. For the conductor 560a, a conductive material that has a function of inhibiting diffusion of impurities such as a hydrogen atom, a hydrogen molecule, a water molecule, and a copper atom is preferably used. Alternatively, it is preferable to use a conductive material having a function of inhibiting diffusion of oxygen (e.g., at least one of an oxygen atom, an oxygen molecule, and the like).

When the conductor 560a has a function of inhibiting oxygen diffusion, the range of choices for the material of the conductor 560b can be extended. That is, the conductor 560a inhibits oxidation of the conductor 560b, thereby preventing the decrease in conductivity.

The insulator 544 is preferably provided to cover the top surface and the side surface of the conductor 560 and a side surface of the insulator 545. For the insulator 544, an insulating material having a function of inhibiting diffusion of oxygen and impurities such as water or hydrogen is preferably used. For example, aluminum oxide or hafnium oxide is preferably used. Moreover, it is possible to use, for example, a metal oxide such as magnesium oxide, gallium oxide, germanium oxide, yttrium oxide, zirconium oxide, lanthanum oxide, neodymium oxide, or tantalum oxide or silicon nitride oxide, silicon nitride, or the like.

The insulator 544 can inhibit oxidation of the conductor 560. Moreover, the insulator 544 can inhibit diffusion of impurities such as water and hydrogen contained in the insulator 580 into the transistor 500B.

The transistor 500B has the conductor 560 overlapping with part of the conductor 542a and part of the conductor 542b, and thus tends to have larger parasitic capacitance than the transistor 500. Consequently, the transistor 500B tends to have a lower operating frequency than the transistor 500. However, the transistor 500B does not require steps of providing an opening in the insulator 580 and the like and embedding the conductor 560, the insulator 545, and the like in the opening; hence, the productivity of the transistor 500B is higher than that of the transistor 500.

The composition, structure, method, and the like described in this embodiment can be used in combination as appropriate with the compositions, structures, methods, and the like described in the other embodiments, the example, and the like.

### Embodiment 6

In this embodiment, an oxide semiconductor which is a kind of metal oxides will be described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

### <Classification of Crystal Structure>

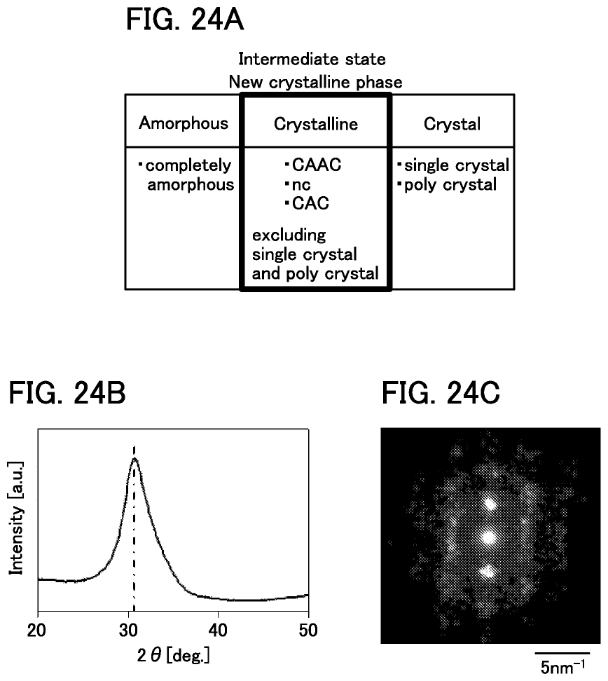

First, classifications of the crystal structures of an oxide semiconductor will be described with reference to FIG. 24A. FIG. 24A is a diagram showing the classification of crystal structures of an oxide semiconductor, typically IGZO (a metal oxide containing In, Ga, and Zn).

As shown in FIG. 24A, an oxide semiconductor is roughly classified into “Amorphous”, “Crystalline”, and “Crystal”. The term “Amorphous” includes completely amorphous. The term “Crystalline” includes CAAC (c-axis-aligned crystalline), nc (nanocrystalline), and CAC (cloud-aligned composite). Note that the term “Crystalline” excludes single crystal, poly crystal, and completely amorphous. The term “Crystal” includes single crystal and poly crystal.

Note that the structures in the thick frame in FIG. 24A are in an intermediate state between “Amorphous” and “Crystal”, and belong to a new crystalline phase. That is, these structures are completely different from “Amorphous”, which is energetically unstable, and “Crystal”.

A crystal structure of a film or a substrate can be analyzed with an X-ray diffraction (XRD) spectrum. FIG. 24B shows an XRD spectrum, which is obtained by GIXD (Grazing-Incidence XRD) measurement, of a CAAC-IGZO film classified into “Crystalline”. Note that a GIXD method is also referred to as a thin film method or a Seemann-Bohlin method. The XRD spectrum that is shown in FIG. 24B and obtained by GIXD measurement is hereinafter simply referred to as an XRD spectrum. The CAAC-IGZO film in FIG. 24B has a composition in the vicinity of In:Ga:Zn=4:2:3 [atomic ratio]. The CAAC-IGZO film in FIG. 24B has a thickness of 500 nm.

As shown in FIG. 24B, a clear peak indicating crystallinity is detected in the XRD spectrum of the CAAC-IGZO film. Specifically, a peak indicating c-axis alignment is detected at 2θ of around 31° in the XRD spectrum of the CAAC-IGZO film. As shown in FIG. 24B, the peak at 2θ of around 31° is asymmetric with respect to the axis of the angle at which the peak intensity is detected.

A crystal structure of a film or a substrate can also be evaluated with a diffraction pattern obtained by a nanobeam electron diffraction method (NBED) (such a pattern is also referred to as a nanobeam electron diffraction pattern). FIG. 24C shows a diffraction pattern of the CAAC-IGZO film. FIG. 24C shows a diffraction pattern obtained by NBED in which an electron beam is incident in the direction parallel to the substrate. The composition of the CAAC-IGZO film in FIG. 24C is In:Ga:Zn=4:2:3 [atomic ratio] or the neighborhood thereof. In the nanobeam electron diffraction method, electron diffraction is performed with a probe diameter of 1 nm.

As shown in FIG. 24C, a plurality of spots indicating c-axis alignment are observed in the diffraction pattern of the CAAC-IGZO film.

### <<Structure of Oxide Semiconductor>>

Oxide semiconductors might be classified in a manner different from that in FIG. 24A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element Mmay be contained in the In layer. Note that Zn may be contained in the In layer. Such a layered structure is observed as a lattice image in a high-resolution TEM image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis using out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., 1 nm or larger and 30 nm or smaller).

[a-Like OS]

The a-like OS is an oxide semiconductor having a structure between those of the nc-OS and the amorphous oxide semiconductor. The a-like OS includes a void or a low-density region. That is, the a-like OS has low crystallinity as compared with the nc-OS and the CAAC-OS. Moreover, the a-like OS has higher hydrogen concentration in the film than the nc-OS and the CAAC-OS.

### <<Composition of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted with [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. For example, the first region has higher [In] and lower [Ga] than the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In—Ga—Zn oxide can be found to have a structure in which the region containing In as its main component (the first region) and the region containing Ga as its main component (the second region) are unevenly distributed and mixed.

In the case where the CAC-OS is used for a transistor, a switching function (on/off switching function) can be given to the CAC-OS owing to the complementary action of the conductivity derived from the first region and the insulating property derived from the second region. A CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor with a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained using SIMS, is lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained using SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained using SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

The composition, structure, method, and the like described in this embodiment can be used in combination as appropriate with the compositions, structures, methods, and the like described in the other embodiments, the example, and the like.

### Embodiment 7

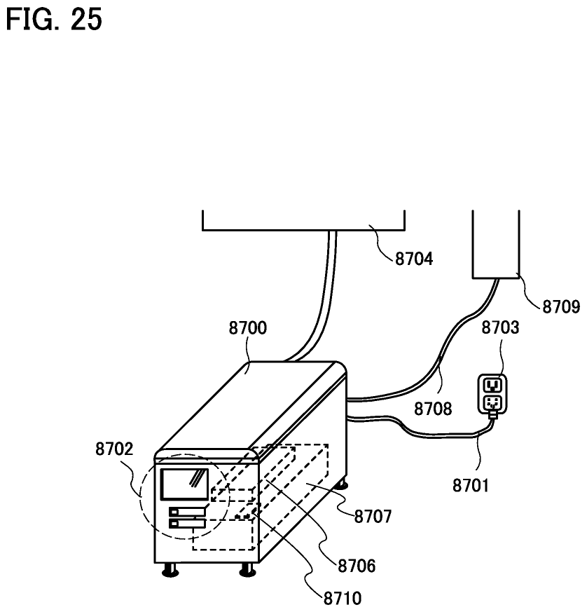

In this embodiment, an example of an uninterruptible power supply is described. An uninterruptible power supply 8700 illustrated in FIG. 25 includes a semiconductor device 8706, an assembled battery 8707, a temperature sensor 8710, and a display device 8702 therein. The temperature sensor 8710 is preferably provided in the vicinity of or in contact with the assembled battery 8707. The temperature sensor 8710 may include a plurality of sensor elements. As the semiconductor device 8706, the semiconductor device 101 included in the power storage device described in the above embodiment can be used. As the assembled battery 8707, the assembled battery 120 included in the power storage device described in the above embodiment can be used. As the display device 8702, the display device DP1 included in the power storage device described in the above embodiment can be used. As the temperature sensor 8710, the temperature sensor TS1 included in the power storage device described in the above embodiment can be used.

A power cord 8701 of the uninterruptible power supply 8700 is electrically connected to a system power supply 8703. The system power supply 8703 is supplied with power from a commercial power supply, for example. A power cord 8708 of the uninterruptible power supply 8700 is electrically connected to a power supply 8709. The power supply 8709 is supplied with power from a solar cell, for example. The solar cell is provided outdoors, e.g., on the roof of a house. The uninterruptible power supply 8700 is electrically connected to precision equipment 8704. The precision equipment 8704 indicates, for example, a server device that should be prevented from being shut down. In the assembled battery 8707 included in the uninterruptible power supply 8700, a plurality of secondary batteries are connected in series or in parallel to achieve a desired voltage (for example, 80 V or more, 100 V, or 200 V).

When the power storage device of one embodiment of the present invention is used for the uninterruptible power supply, the remaining capacity of the assembled battery can be efficiently measured, so that the duration of the uninterruptible power supply can be long. Moreover, the reliability of the uninterruptible power supply can be increased. Furthermore, the lifetime of the uninterruptible power supply can be extended. In addition, the power consumption of the semiconductor device included in the uninterruptible power supply can be reduced, so that the duration of the uninterruptible power supply can be long. The semiconductor device 8706 detects a phenomenon such as overcharging, overdischarging, or overcurrent of the assembled battery and controls charging, so that the highly safe uninterruptible power supply can be provided.

The uninterruptible power supply 8700 can be provided under the floor of a house, for example. In such a case, only the display device 8702 is provided over the floor, for example, on the wall of a room. The uninterruptible power supply 8700 is highly safe and thus is suitably provided under the floor.

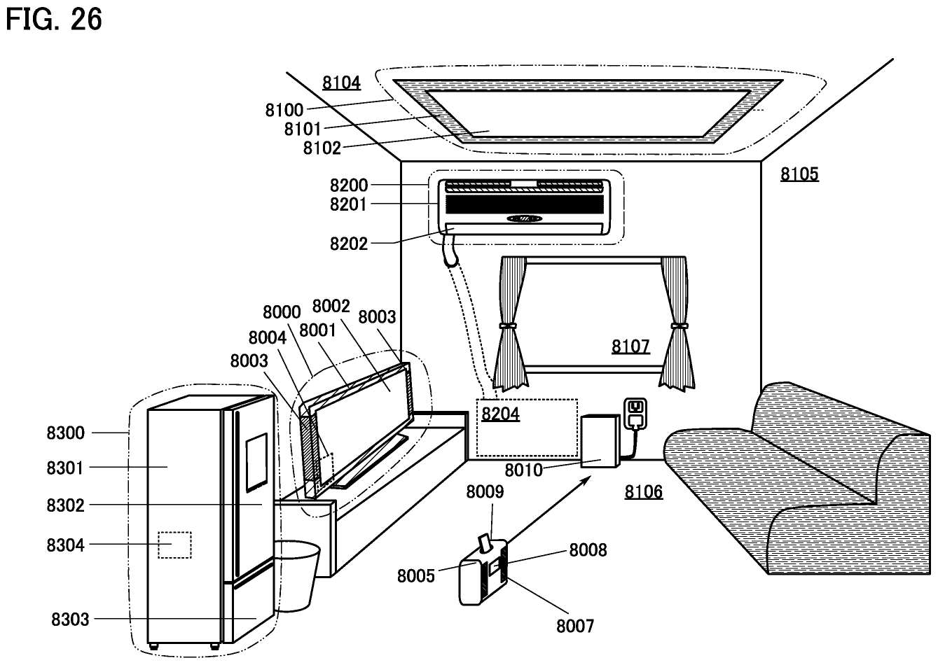

The uninterruptible power supply of one embodiment of the present invention can supply power to a variety of devices illustrated in FIG. 26.

An installation lighting device 8100 illustrated in FIG. 26 as an example includes a housing 8101 and a light source 8102. When the supply of power from a commercial power supply is stopped, the lighting device 8100 can use power stored in the uninterruptible power supply. Alternatively, the uninterruptible power supply may be used as an auxiliary power supply in combination with the supply of power from a small power supply.

As the light source 8102, an artificial light source that emits light artificially by using power can be used. Specific examples of the artificial light source include an incandescent lamp, a discharge lamp such as a fluorescent lamp, and light-emitting elements such as an LED and an organic EL element.

An air conditioner illustrated in FIG. 26 as an example includes an indoor unit 8200 and an outdoor unit 8204. The indoor unit 8200 includes a housing 8201 and an air outlet 8202. When the supply of power from a commercial power supply is stopped, the air conditioner can use power stored in the uninterruptible power supply. Alternatively, the uninterruptible power supply may be used as an auxiliary power supply in combination with the supply of power from a small power supply.

An electric refrigerator-freezer 8300 illustrated in FIG. 26 as an example includes a housing 8301, a refrigerator door 8302, and a freezer door 8303. When the supply of power from a commercial power supply is stopped, the electric refrigerator-freezer 8300 can use power stored in the uninterruptible power supply. Alternatively, the uninterruptible power supply may be used as an auxiliary power supply in combination with the supply of power from a small power supply.

In addition, in a time period when electronic devices are not used, particularly when the proportion of the amount of power which is actually used to the total amount of power which can be supplied from a commercial power supply source (such a proportion referred to as a usage rate of power) is low, power can be stored in the uninterruptible power supply, whereby the usage rate of power can be reduced in a time period when the electronic devices are used. For example, in the case of the electric refrigerator-freezer 8300, power is stored in the uninterruptible power supply in night time when the temperature is low and the refrigerator door 8302 and the freezer door 8303 are not opened or closed. On the other hand, in daytime when the temperature is high and the refrigerator door 8302 and the freezer door 8303 are opened and closed, the uninterruptible power supply is used as an auxiliary power supply; thus, the usage rate of power in daytime can be reduced.

This embodiment can be combined with the description of the other embodiments as appropriate.

### Embodiment 8

In this embodiment, examples of vehicles each including the power storage device of one embodiment of the present invention will be described. Examples of vehicles include automobiles, motorcycles, and bicycles.

The power storage device of one embodiment of the present invention has a long lifetime and excellent reliability. The use of the power storage device of one embodiment of the present invention can increase the safety of an electronic device, a vehicle, or the like.

Hereinafter, examples of vehicles including the power storage device of one embodiment of the present invention will be described.

The use of power storage devices in vehicles enables production of next-generation clean energy vehicles such as hybrid electric vehicles (HEVs), electric vehicles (EVs), and plug-in hybrid electric vehicles (PHEVs).

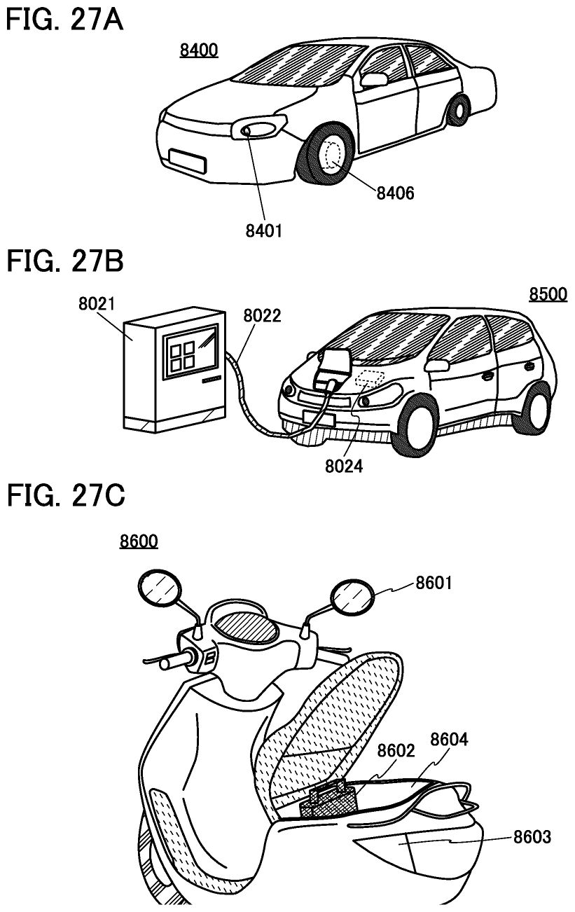

FIG. 27A, FIG. 27B, and FIG. 27C show examples of vehicles using the power storage device that is one embodiment of the present invention. An automobile 8400 illustrated in FIG. 27A is an electric vehicle that runs on the power of an electric motor. Alternatively, the automobile 8400 is a hybrid electric vehicle capable of driving using either an electric motor or an engine as appropriate. The use of one embodiment of the present invention can achieve a high-mileage vehicle. The automobile 8400 includes a power storage device. The power storage device is used not only for driving an electric motor 8406, but also for supplying power to a light-emitting device such as headlights 8401 or a room light (not illustrated).

The power storage device can also supply power to a display device of a speedometer, a tachometer, or the like included in the automobile 8400. Furthermore, the power storage device can supply power to a navigation system or the like included in the automobile 8400.

An automobile 8500 illustrated in FIG. 27B can be charged when a power storage device 8024 included in the automobile 8500 is supplied with power from external charging equipment by a plug-in system, a contactless power feeding system, or the like. FIG. 27B illustrates the state in which the power storage device 8024 included in the automobile 8500 is charged with a ground-based charging apparatus 8021 through a cable 8022. In charging, a given method such as CHAdeMO (registered trademark) or Combined Charging System may be employed as a charging method, the standard of a connector, or the like as appropriate. The charging apparatus 8021 may be a charging station provided in a commerce facility or a power supply in a house. With the use of a plug-in technique, the power storage device 8024 included in the automobile 8500 can be charged by being supplied with power from the outside, for example. Charging can be performed by converting AC power into DC power through a converter such as an ACDC converter.

Although not illustrated, the vehicle can include a power receiving device so as to be charged by being supplied with power from an above-ground power transmitting device in a contactless manner. In the case of the contactless power feeding system, by fitting a power transmitting device in a road or an exterior wall, charging can be performed not only when the vehicle is stopped but also when driven. In addition, this contactless power feeding system may be utilized to transmit and receive power between vehicles. A solar cell may be provided in the exterior of the vehicle to charge the power storage device when the vehicle stops or moves. To supply power in such a contactless manner, an electromagnetic induction method or a magnetic resonance method can be used.

FIG. 27C is an example of a motorcycle using the power storage device of one embodiment of the present invention. A motor scooter 8600 illustrated in FIG. 27C includes a power storage device 8602, side mirrors 8601, and indicator lights 8603. The power storage device 8602 can supply electricity to the indicator lights 8603.

In the motor scooter 8600 illustrated in FIG. 27C, the power storage device 8602 can be stored in a storage unit under seat 8604. The power storage device 8602 can be stored in the storage unit under seat 8604 even with a small size.

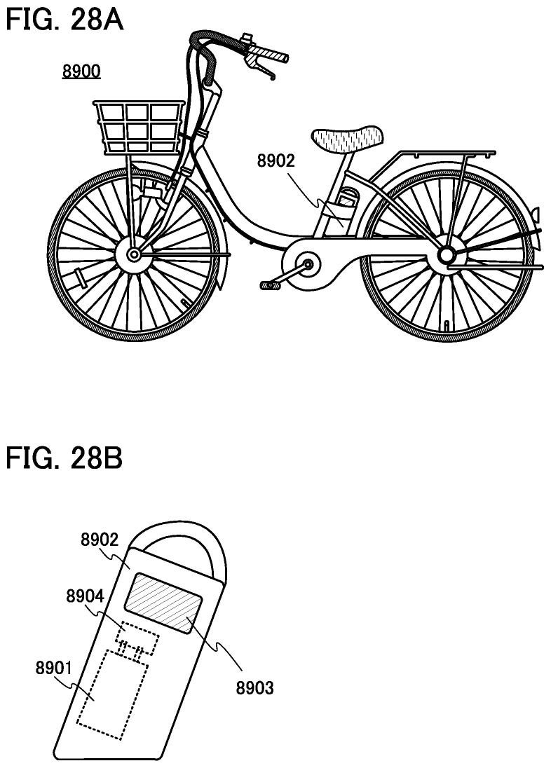

FIG. 28A is an example of an electric bicycle using the power storage device of one embodiment of the present invention. The power storage device of one embodiment of the present invention can be used for an electric bicycle 8900 illustrated in FIG. 28A.

The electric bicycle 8900 includes a power storage device 8902. The power storage device 8902 can supply electricity to a motor that assists a rider. The power storage device 8902 is portable, and FIG. 28B illustrates the state where the power storage device 8902 is detached from the bicycle. A plurality of assembled batteries 8901 included in the power storage device of one embodiment of the present invention are incorporated in the power storage device 8902, and the remaining battery capacity and the like can be displayed on a display portion 8903. The power storage device 8902 also includes a semiconductor device 8904 of one embodiment of the present invention. The semiconductor device 8904 is electrically connected to a positive electrode and a negative electrode of the assembled battery 8901. The semiconductor device 101 described in the above embodiment can be used as the semiconductor device 8904.

This embodiment can be combined with any of the other embodiments as appropriate.

(Notes on Description of this Specification and the Like)

The description of the above embodiments and each structure in the embodiments are noted below.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified by their functions and illustrated as independent blocks in block diagrams. However, in an actual circuit or the like, it is difficult to divide components according to their functions, and there are such a case where one circuit relates to a plurality of functions and a case where a plurality of circuits relate to one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, they are not limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included.

In this specification and the like, the expressions “one of a source and a drain” (or a first electrode or a first terminal) and “the other of the source and the drain” (or a second electrode or a second terminal), which is for the other of the source and the drain, are used to describe the connection relation of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the terms “electrode” and “wiring” do not functionally limit these components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, voltage and potential can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential supplied to a wiring or the like is sometimes changed depending on the reference potential.

Note that in this specification and the like, the terms such as “film” and “layer” can be interchanged with each other depending on the case or according to circumstances. For example, the term “conductive layer” can be changed into the term “conductive film” in some cases. As another example, the term “insulating film” can be changed into the term “insulating layer” in some cases.

In this specification and the like, a switch has a function of controlling whether current flows or not by being in a conduction state (an on state) or a non-conduction state (an off state). Alternatively, a switch has a function of selecting and changing a current path.

In this specification and the like, channel length refers to, for example, the distance between a source and a drain in a region where a semiconductor (or a portion where current flows in a semiconductor when a transistor is in an on state) and a gate overlap with each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap with each other or a region where a channel is formed.

In this specification and the like, when A and B are connected, it means the case where A and B are electrically connected to each other as well as the case where A and B are directly connected to each other. Here, when A and B are electrically connected, it means the case where electric signals can be sent and received between A and B when an object having any electric action exists between A and B.

### REFERENCE NUMERALS

AD1: converter circuit, AD2: analog-digital converter circuit, BGL2: wiring, BGL6: wiring, BKC1: circuit, BKC2: circuit, BKC10: circuit, BKC20: circuit, C1: capacitor, C3: capacitor, C6: capacitor, CB1: capacitor, CB2: capacitor, CB11: capacitor, CB12: capacitor, CR1: ammeter, DP1: display device, FN1: node, FN2: node, GCLK2: clock signal, INV11: inverter circuit, INV12: inverter circuit, IV1: inverter circuit, Ml: transistor, M2: transistor, M3: transistor, M4: transistor, M5: transistor, M6: transistor, M11: transistor, M12: transistor, MA1: transistor, MC1: transistor, MC2: transistor, ME1: memory, ME2: memory, MemC1: circuit, MemC2: circuit, MR1: transistor, MW1: transistor, MW2: transistor, MW11: transistor, MW12: transistor, NB1: node, NET1: node, NET2: node, NK1: node, NR1: node, OU1 : terminal, OU2: terminal, PCC10: circuit, PR1: protection circuit, PR2: control circuit, PS1: terminal, PSES: signal, PSE6: signal, RL1: relay circuit, RL2: relay circuit, RTC10: circuit, Si: terminal, SC1: terminal, SE7: switch, SH1: sample-and-hold circuit, SH2: sample-and-hold circuit, SMC20: circuit, SN1: node, SN2: node, SN3: node, SW1: control circuit, SW7: switch, TS1: temperature sensor, VC1: terminal, VH1: potential, VH2: potential, VH3: potential, WR1: circuit, 10: power supply circuit, 11: memory cell, 12: MW, 15: memory cell, 16: memory cell, 20: processing unit, 20a: processing unit, 20b: processing unit, 21: processing unit, 30: processor core, 31: memory circuit, 32: circuit, 35: power supply line, 40: cache, 41: memory array, 42: peripheral circuit, 43: control circuit, 45: memory cell, 51: processing unit, 52: converter circuit, 53: circuit, 55: control circuit, 60: PMU, 61: circuit, 65: clock control circuit, 70: PSW, 71: PSW, 80: terminal, 81: terminal, 82: terminal, 83: terminal, 100: power storage device, 101: semiconductor device, 110: FF, 120: assembled battery, 121: battery cell, 121a: amplifier circuit, 121b: amplifier circuit, 122: assembled battery, 122a: transistor, 122b: transistor, 123a: capacitor, 123b: capacitor, 126: resistor, 130: processor core, 131: control device, 132: program counter, 133: pipeline register, 134: pipeline register, 135: register file, 136: ALU, 137: data bus, 200: memory circuit, 202: cache memory device, 203: cache memory device, 220: memory cell, 240: NOSRAM, 242: power domain, 243: power domain, 245: power switch, 247: power switch, 250: memory cell array, 251: control circuit, 252: row circuit, 253: column circuit, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 351: DOSRAM, 352: insulator, 354: insulator, 356: conductor, 360: insulator, 361: memory cell array, 362: insulator, 364: insulator, 365: peripheral circuit, 366: conductor, 370: insulator, 371: power switch, 372: insulator, 373: power switch, 374: insulator, 376: conductor, 380: insulator, 382: insulator, 384: insulator, 386: conductor, 400: secondary battery, 401: positive electrode cap, 402: battery can, 404: insulator, 408: assembled battery, 413: conductive plate, 414: conductive plate, 415: power storage device, 416: wiring, 420: semiconductor device, 421: wiring, 422: wiring, 423: wiring, 424: conductor, 425: insulator, 426: wiring, 427: temperature sensor, 500: transistor, 500A: transistor, 500B: transistor, 503: conductor, 503a: conductor, 503b: conductor, 510: insulator, 512: insulator, 513: insulator, 514: insulator, 516: insulator, 518: conductor, 520: insulator, 522: insulator, 524: insulator, 530: oxide, 530a: oxide, 530b: oxide, 540a: conductor, 540b: conductor, 542: conductor, 542a: conductor, 542b: conductor, 543a: region, 543b: region, 544: insulator, 545: insulator, 546: conductor, 548: conductor, 550: transistor, 552: insulator, 560: conductor, 560a: conductor, 560b: conductor, 574: insulator, 580: insulator, 581: insulator, 582: insulator, 586: insulator, 600: capacitor, 601: positive electrode cap, 602: battery can, 603: positive electrode terminal, 604: positive electrode, 605: separator, 606: negative electrode, 607: negative electrode terminal, 608: insulating plate, 609: insulating plate, 610: conductor, 611: PTC element, 612: conductor, 613: safety valve mechanism, 620: conductor, 630: insulator, 640: insulator, 930: housing, 931: negative electrode, 932: positive electrode, 933: separator, 950: wound body, 951: terminal, 952: terminal, 8021: charging apparatus, 8022: cable, 8024: power storage device, 8100: lighting device, 8101: housing, 8102: light source, 8200: indoor unit, 8201: housing, 8202: air outlet, 8204: outdoor unit, 8300: refrigerator-freezer, 8301: housing, 8302: refrigerator door, 8303: freezer door, 8400: automobile, 8401: headlight, 8406: electric motor, 8500: automobile, 8600: motor scooter, 8601: side mirror, 8602: power storage device, 8603: indicator light, 8604: storage unit under seat, 8700: uninterruptible power supply, 8701: power cord, 8702: display device, 8703: system power supply, 8704: precision equipment, 8706: semiconductor device, 8707: assembled battery, 8708: power cord, 8709: power supply, 8710: temperature sensor, 8900: electric bicycle, 8901: assembled battery, 8902: power storage device, 8903: display portion, 8904: semiconductor device

1. A power storage device comprising a battery, a control circuit, and a converter circuit,
wherein the converter circuit is configured to select and convert a first voltage or a second voltage and supply the converted voltage to the battery,
wherein the first voltage is an AC voltage,
wherein the second voltage is a DC voltage,
wherein the control circuit comprises a transistor comprising an oxide semiconductor in a channel formation region, and
wherein the control circuit is configured to measure data of a voltage of the battery and retain the data of the voltage of the battery.

2. The power storage device according to claim 1,
wherein the control circuit comprises a processor core,
wherein the processor core is configured to supply a signal to a gate of the transistor, and
wherein power supply to the processor core is stopped in a period of retaining the data of the voltage.

3. The power storage device according to claim 1,
wherein the converter circuit is configured to convert one or more of a magnitude and a frequency of a voltage.

4. The power storage device according to claim 3, wherein the second voltage is a voltage generated by a solar cell.

5. A power storage device comprising a battery, a control circuit, and a converter circuit,
wherein the converter circuit is configured to select and convert a first voltage or a second voltage and supply the converted voltage to the battery,
wherein the first voltage is an AC voltage,
wherein the second voltage is a DC voltage,
wherein the control circuit comprises a first sample-and-hold circuit and a second sample-and-hold circuit,
wherein the first sample-and-hold circuit is configured to measure and retain data of a voltage of the battery,
wherein the second sample-and-hold circuit is configured to convert data of a current of the battery into a voltage, and measure and retain the voltage,
wherein the first sample-and-hold circuit comprises a first transistor,
wherein the second sample-and-hold circuit comprises a second transistor,
wherein the first sample-and-hold circuit is configured to measure the data of the voltage of the battery when the first transistor is in an on state, and retain the data of the voltage of the battery when the first transistor is in an off state, and
wherein the second sample-and-hold circuit is configured to measure the data of the current of the battery when the second transistor is in an on state, and retain the data of the current of the battery when the second transistor is in an off state.

6. The power storage device according to claim 5,
wherein the first transistor and the second transistor each comprise an oxide semiconductor in a channel formation region.

7. The power storage device according to claim 5, configured to calculate a remaining capacity of the battery with use of:
the data of the voltage of the battery retained in the first sample-and-hold circuit; and
the data of the current of the battery retained in the second sample-and-hold circuit.

8. The power storage device according to claim 5,
wherein the converter circuit is configured to convert one or more of a magnitude and a frequency of a voltage.

9. The power storage device according to claim 8, wherein the second voltage is a voltage generated by a solar cell.

10. An operation method of a power storage device comprising a battery, a control circuit, and a converter circuit,
wherein the control circuit comprises a processing unit comprising a processor core, and a first sample-and-hold circuit and a second sample-and-hold circuit,
wherein the first sample-and-hold circuit comprises a first transistor,
wherein the second sample-and-hold circuit comprises a second transistor,
wherein the processing unit is electrically connected to a gate of the first transistor and a gate of the second transistor,
wherein the processing unit supplies signals to the gate of the first transistor and the gate of the second transistor to turn on the first transistor and the second transistor,
wherein the converter circuit supplies a voltage to the battery,
wherein data of a voltage of the battery is supplied to one of a source and a drain of the first transistor, and data of a current of the battery is converted into a voltage and the voltage is supplied to one of a source and a drain of the second transistor, and
wherein the processing unit supplies signals to the gate of the first transistor and the gate of the second transistor to turn off the first transistor and the second transistor.

11. The operation method of the power storage device according to claim 10,
wherein a second processing unit is included,
wherein the data of the voltage of the battery and the data obtained by converting the data of the current of the battery into the voltage are converted from analog values into digital values and then supplied to the second processing unit,
wherein power supply to the processor core is stopped, and
wherein the second processing unit calculates a remaining capacity of the battery.

12. The operation method of the power storage device according to claim 10,
wherein the converter circuit is configured to convert one or more of magnitudes and frequencies of a first voltage and a second voltage,
wherein the first voltage is an AC voltage,
wherein the second voltage is a DC voltage, and
wherein the converter circuit selects and converts the first voltage or the second voltage and supplies the converted voltage to the battery.

13. The operation method of the power storage device according to claim 12, wherein the second voltage is a voltage generated by a solar cell.
